(19) United States
(12) Patent Application Publication
(10) Pub. No.: US 2023/0107659 A1
(43) Pub. Date: Apr. 6, 2023

(54) COMPOSITION, LIGHT SHIELDING FILM, SOLID-STATE IMAGING ELEMENT, IMAGE DISPLAY DEVICE, AND METHOD FOR MANUFACTURING CURED FILM

(71) Applicant: FUJIFILM Corporation, Tokyo (JP)

(72) Inventors: Hiroaki IDEI, Shizuoka (JP); Misaho ADACHI, Shizuoka (JP); Teppei ABE, Shizuoka (JP)

(73) Assignee: FUJIFILM Corporation, Tokyo (JP)

(21) Appl. No.: 17/954,344

(22) Filed: Sep. 28, 2022

(30) Foreign Application Priority Data
Sep. 29, 2021 (JP) 2021-159863

(51) Int. Cl. G03F 7/004

(52) U.S. Cl. CPC G03F 7/0042; G03F 7/0045

(57) ABSTRACT

Provide are a composition with which a pattern (patterned cured film) with excellent light shielding properties and suppressed undercut can be formed; a light shielding film; a solid-state imaging element; an image display device; and a method for manufacturing a cured film.

The composition includes carbon black, barium sulfate, one or more kinds selected from the group consisting of copper phthalocyanine and a copper phthalocyanine derivative, an acid generator, and a crosslinking agent having a crosslinkable group which is crosslinked by an acid.

### CROSS-REFERENCE TO RELATED APPLICATIONS

The present application claims priority under 35 U.S.C. § 119 to Japanese Patent Application No. 2021-159863, filed on Sep. 29, 2021. The above application is hereby expressly incorporated by reference, in its entirety, into the present application.

### BACKGROUND OF THE INVENTION

### 1. Field of the Invention

The present invention relates to a composition, a light shielding film, a solid-state imaging element, an image display device, and a method for manufacturing a cured film.

### 2. Description of the Related Art

A composition including black powder has been used for various purposes in the related art, and for example, the composition is used in the production of a light shielding film to be disposed in a liquid crystal display device and a solid-state imaging device such as a charge coupled device (CCD) image sensor and a complementary metal-oxide semiconductor (CMOS) image sensor. For example, a color filter used in the liquid crystal display device includes a light shielding film which is called a black matrix, for the purpose of shielding colored pixels from light, enhancing contrast, and the like. In addition, the solid-state imaging element is also provided with a light shielding film at a predetermined position for the purpose of preventing generation of noise, improving image quality, and the like.

For example, WO2018/074539A discloses a method for manufacturing a patterned cured film adopted to a color filter, a black matrix, a CMOS image sensor, a CCD image sensor, or the like as a display element, and discloses a curable composition for forming a patterned cured film in the column of Examples, which includes, for example, a polymerizable compound, a photopolymerization initiator, and an additive such as a colorant.

### SUMMARY OF THE INVENTION

As a result of studying the curable composition disclosed in WO2018/074539A, the present inventors have clarified that an undercut may occur in a pattern (patterned cured film) to be formed. Specifically, it is clarified that a cross-sectional shape of the pattern is to be a reverse taper (in other words, in a convex portion (exposed portion) of the pattern, a length of an upper end part is larger than a length of a lower end part).

In view of applicability to the light shielding film, high light shielding properties are also required as a basic performance in the curable composition.

Therefore, an object of the present invention is to provide a composition with which a pattern (patterned cured film) with excellent light shielding properties and suppressed undercut can be formed.

Another object of the present invention is to provide a light shielding film, a solid-state imaging element, an image display device, and a method for manufacturing a cured film.

As a result of conducting an extensive investigation to achieve the objects, the present inventors have found that the objects can be achieved by the following constitution.

[1] A composition comprising:
carbon black;
barium sulfate;
one or more kinds selected from the group consisting of copper phthalocyanine and a copper phthalocyanine derivative;
an acid generator; and
a crosslinking agent having a crosslinkable group which is crosslinked by an acid.
[2] The composition according to [1], further comprising:
a resin.
[3] The composition according to [1] or [2],
in which the crosslinking agent includes a triazine structure.
[4] The composition according to any one of [1] to [3],
in which the crosslinkable group includes an alkoxymethyl group.
[5] The composition according to any one of [1] to [4], further comprising:
one or more kinds of particles A selected from the group consisting of organic particles different from the carbon black and metal oxide particles.
[6] The composition according to [5],
in which an average particle diameter of the particles A is in a range of 0.1 to 10 μm.
[7] The composition according to [5] or [6],
in which the organic particles include one or more kinds of phenol resin particles and acrylic resin particles.
[8] The composition according to any one of [5] to [7],
in which the metal oxide particles include silica particles.
[9] The composition according to any one of [1] to [8],
in which the composition includes the copper phthalocyanine derivative, and
the copper phthalocyanine derivative is a salt composed of copper phthalocyanine having a sulfonic acid group and dimethyldioctadecylammonium.
[10] The composition according to any one of [1] to [9],
in which a content of the carbon black is 15% to 55% by mass with respect to a total solid content of the composition.
[11] The composition according to any one of [1] to [10], further comprising:
one or more kinds of particles B selected from the group consisting of metal nitride particles and metal oxynitride particles.
[12] The composition according to [11],
in which the particles B are a nitride or an oxynitride of one or more kinds of metals selected from the group consisting of titanium, zirconium, vanadium, and niobium.
[13] The composition according to any one of [1] to [12], further comprising:
a fluorine-based surfactant.
[14] The composition according to any one of [1] to [13],
in which a content of a solid content is 10% to 45% by mass.
[15] The composition according to any one of [1] to [14],
in which the composition includes two or more kinds of the acid generators.
[16] The composition according to any one of [1] to [15],
in which the acid generator includes a sulfonium salt compound and a halomethylated triazine compound.
[17] The composition according to any one of [1] to [16],
in which, in a case where a film is formed by performing the following film forming method on a composition layer formed from the composition, a maximum reflectivity of the film in a wavelength range of 400 to 1100 nm is less than 5%, <<film forming method>> the composition is applied to a substrate so that a thickness after an exposure is 2.0 μm to form a coating film, the coating film is heated under conditions of at 100° C. for 120 seconds to form a composition layer, and using a high-pressure mercury lamp, the composition layer is exposed to an exposure amount of 1000 mJ/cm², and then the exposed composition layer is heated under conditions of 220° C. for 300 seconds.
[18] A light shielding film comprising:
a cured film formed from the composition according to any one of [1] to [17].
[19] A solid-state imaging element comprising:
a cured film formed from the composition according to any one of [1] to [17].
[20] An image display device comprising:
a cured film formed from the composition according to any one of [1] to [17].
[21] A method for manufacturing a cured film, comprising:
a composition layer forming step of forming a composition layer consisting of the composition according to any one of [1] to [17] on a support;
an exposure step of exposing the composition layer in a patterned manner by irradiating the composition layer with an actinic ray or a radiation; and
a development step of performing a development treatment on the composition layer after the exposure.

According to the present invention, it is possible to provide a composition with which a pattern (patterned cured film) with excellent light shielding properties and suppressed undercut can be formed.

In addition, according to the present invention, it is possible to provide a light shielding film, a solid-state imaging element, an image display device, and a method for manufacturing a cured film.

### BRIEF DESCRIPTION OF THE DRAWINGS

FIG. 1 is a schematic cross-sectional view showing an example of the configuration of a solid-state imaging device.

FIG. 2 is a schematic cross-sectional view showing an imaging part in FIG. 1 in an enlarged manner.

FIG. 3 is a schematic cross-sectional view showing an example of the constitution of an infrared sensor.

### DESCRIPTION OF THE PREFERRED EMBODIMENTS

Hereinafter, the present invention will be described in detail.

The description of the following configuration requirements is made based on typical embodiments of the present invention in some cases, but the present invention is not limited to the embodiments.

Furthermore, in the present specification, a numerical range expressed using “to” means a range including numerical values described before and after “to” as a lower limit value and an upper limit value.

In the present specification, regarding the description of a group (atomic group), in a case where whether the group is substituted or unsubstituted is not described, the group includes a group which has a substituent as well as a group which does not have a substituent. For example, an “alkyl group” includes not only an alkyl group (unsubstituted alkyl group) which does not have a substituent but also an alkyl group (substituted alkyl group) which has a substituent.

In addition, in the present specification, “actinic rays” or “radiations” refers to, for example, far ultraviolet rays, extreme ultraviolet rays (EUV: extreme ultraviolet lithography), X-rays, electron beams, and the like. In addition, in the present specification, light refers to actinic rays and radiations. In the present specification, unless otherwise specified, “exposure” includes not only exposure with far ultraviolet rays, X-rays, EUV light, or the like but also drawing by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, a weight-average molecular weight (Mw) is a value in terms of polystyrene, as measured by a gel permeation chromatography (GPC) method.

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID×15 cm) are used as columns, and tetrahydrofuran (THF) is used as an eluent.

In the present specification, a solid content in a composition means a composition layer formed of the composition, and in a case where the composition includes a solvent, the solid content means all components except the solvent. In addition, in a case where the components are components which form a composition layer, the components are considered to be solid contents even in a case where the components are liquid components.

Composition

A composition according to an embodiment of the present invention includes carbon black, barium sulfate, one or more kinds selected from the group consisting of copper phthalocyanine and a copper phthalocyanine derivative (hereinafter, also referred to as “copper phthalocyanines”), an acid generator, and a crosslinking agent having a crosslinkable group which is crosslinked by an acid (hereinafter, also referred to as a “specific crosslinking agent”).

A pattern (patterned cured film) formed of the composition according to the embodiment of the present invention has excellent light shielding properties (high optical density (OD) value at a wavelength of 400 to 1100 nm), and an undercut is suppressed. A mechanism by which the objects of the present invention can be achieved with the composition according to the embodiment of the present invention having such a configuration is not always clear, but is presumed to be as follows by the present inventors.

In the above-described composition, it is considered that the barium sulfate and the copper phthalocyanines serve as surface modifiers which adjust a state of charge on a surface of the carbon black. Due to this, in a case where energy such as heat and light is applied to a composition layer formed from the above-described composition, it is presumed that an acid generated from the acid generator is more likely to diffuse into a deep portion of the layer, and as a result, the undercut of the pattern is suppressed.

In addition, since the composition according to the embodiment of the present invention mainly includes the carbon black, excellent light shielding properties are exhibited.

In the following, in a case where a pattern formed of a composition is simply referred to as a “pattern”, unless otherwise specified, the “pattern” is intended to be a patterned cured film.

In addition, in the following, the fact that the pattern formed of the composition has more excellent light shielding properties (higher OD value at a wavelength of 400 to 1100 nm), the fact that the pattern formed of the composition has more excellent undercut suppression performance, the fact that the pattern formed of the composition has more excellent low reflection properties (lower maximum reflectivity at a wavelength of 400 to 1100 nm), the fact that the composition has more excellent viscosity stability over time, the fact that the composition has more excellent sensitivity (smaller minimum exposure amount), and/or the fact that the pattern formed of the composition has more excellent peeling resistance is also referred to that “the effects of the present invention are more excellent”.

Carbon Black

The composition includes carbon black.

The carbon black may be neutral, acidic, or basic, but from the viewpoint that the effects of the present invention are more excellent, the carbon black is preferably acidic.

Examples of the acidic carbon black include those having a pH of less than 6.5. The pH of the acidic carbon black is preferably 2.0 to 6.0 and more preferably 2.0 to 4.0.

Specific examples of the acidic carbon black include Raven1080 (average primary particle diameter: 28 nm, pH: 2.4) and Raven1100 (average primary particle diameter: 32 nm, pH: 2.9) manufactured by Columbia Chemical; MA8 (average primary particle diameter: 24 nm, pH: 3.0), MA100 (average primary particle diameter: 24 nm, pH: 3.5), MA7 (average primary particle diameter: 24 nm, pH: 3.0), MA77 (average primary particle diameter: 23 nm, pH: 2.5), MA220 (average primary particle diameter: 55 nm, pH: 3.0), #2350 (average primary particle diameter: 15 nm, pH: 2.5, manufactured by Mitsubishi Chemical Corporation) manufactured by Mitsubishi Chemical Corporation; and SPECIAL BLACK 250 (average primary particle diameter: 56 nm, pH: 3.0), SPECIAL BLACK 350 (average primary particle diameter: 31 nm, pH: 3.0), SPECIAL BLACK 550 (average primary particle diameter: 25 nm, pH: 4), NEROX2500 (average primary particle diameter: 56 nm, pH: 3.0), and NEROX 3500 (average primary particle diameter: 31 nm, pH: 3.0) manufactured by Orion Engineered Carbons S.A.

Examples of the neutral and basic carbon black include those having a pH of 6.5 or more.

Specific examples of the neutral and basic carbon black include PRINTEX 25 (average primary particle diameter: 56 nm, pH: 9.5), PRINTEX 35 (average primary particle diameter: 31 nm, pH: 9.5), and PRINTEX 65 (average primary particle diameter: 21 nm, pH: 9.5) manufactured by Orion Engineered Carbons S.A.; and #30 (average primary particle diameter: 30 nm, pH: 8.0) and #2600 (average primary particle diameter: 13 nm, pH: 6.5) manufactured by Mitsubishi Chemical Corporation.

An average primary particle diameter of the carbon black is preferably, for example, 10 to 60 nm, and from the viewpoint that the effects of the present invention are more excellent, more preferably 10 to 30 nm.

The above-described pH of the carbon black is a catalog value, or is a value obtained by the following measuring method in a case where there is no catalog value.

pH Measuring Method

1 g of carbon black is added to 20 ml of distilled water (pH: 7.0) from which carbonic acid has been removed, and is mixed with a magnetic stirrer to prepare an aqueous suspension, and then a value is measured at 25° C. using a glass electrode (German Industrial Standard DIN ISO 787/9).

In addition, the above-described average primary particle diameter of the carbon black is a catalog value, or is a value of an arithmetic mean diameter by electron microscope observation in a case where there is no catalog value.

A content of the carbon black is preferably 5.0% by mass or more, more preferably 10% by mass or more, still more preferably 15% by mass or more, and particularly preferably 27% by mass or more with respect to the total solid content of the composition. Moreover, the upper limit value thereof is preferably 60% by mass or less, more preferably 55% by mass or less, still more preferably 45% by mass or less, and particularly preferably 35% by mass or less.

The carbon black may be used singly or in combination of two or more kinds thereof. In a case where two or more kinds of the carbon blacks are used in combination, the total content thereof is preferably within the above-described range.

Barium Sulfate

The composition includes barium sulfate.

From the viewpoint that the effects of the present invention are more excellent and/or dispersion stability is more excellent, an average particle diameter and an average primary particle diameter of the barium sulfate are preferably 0.01 to 0.08 μm.

From the viewpoint that the effects of the present invention are more excellent, a mass-based formulating ratio (carbon black/barium sulfate) of the carbon black and the barium sulfate is preferably 99.5/0.5 to 65/35, more preferably 96/4 to 65/35, and still more preferably 96/4 to 75/25.

Examples of a suitable aspect of the barium sulfate include a precipitated barium sulfate.

Examples of a commercially available product of the barium sulfate include BF-20, BF-10, BF-21, BF-1, and BF-40 (all manufactured by SAKAI CHEMICAL INDUSTRY CO., LTD.); TS-3, SC-201, and HC-A (all manufactured by Takehara Chemical); and TS-2 (manufactured by TOSHIN CHEMICALS CO., LTD.).

A content of the barium sulfate is, for example, 0.1% by mass or more, preferably 1.0% by mass or more, more preferably 1.5% by mass or more, and still more preferably 2.0% by mass or more with respect to the total solid content of the composition. Moreover, the upper limit value thereof is preferably 10% by mass or less, more preferably 8.0% by mass or less, and still more preferably 6.0% by mass or less.

Copper Phthalocyanine and Copper Phthalocyanine Derivative (Copper Phthalocyanines)

The composition includes one or more kinds selected from the group consisting of copper phthalocyanine and a copper phthalocyanine derivative (copper phthalocyanines).

The copper phthalocyanine is intended to be a copper complex of phthalocyanine. The copper phthalocyanine derivative is intended to be a copper complex of phthalocyanine having a substituent (in a case where the substituent includes a polar group such as an acid group and a basic group, the copper complex may have a salt structure), and examples thereof include a copper complex of phthalocyanine having a substituent including a polar group such as an acid group and a basic group, and a salt thereof.

Examples of the acid group include a sulfonic acid group, a carboxylic acid group, and a phosphoric acid group, and from the viewpoint that the effects of the present invention are more excellent, a sulfonic acid group is preferable. The presence of the sulfonic acid group increases an interaction between the pigment, the copper phthalocyanine derivative, and the dispersant, respectively, and improves a temporal stability.

Examples of the basic group include a primary amino group, a secondary amino group, a tertiary amino group, a hetero ring including an N atom, and an amide group.

The salt is not particularly limited, and examples thereof include a halide salt, an alkali metal salt, and a quaternary ammonium salt.

Examples of a halide ion constituting the halide salt include a fluoride ion, a chloride ion, a bromide ion, and an iodide ion.

Examples of an alkali metal ion constituting the alkali metal salt include a lithium ion, a sodium ion, and a potassium ion.

Examples of a quaternary ammonium ion constituting the quaternary ammonium salt include a quaternary ammonium ion represented by Formula (NA).

Formula (NA): N⁺(R_{A})(R_{B})(R_{C})(R_{D})

R_{A} to R_{D} each independently represent a hydrogen atom, an alkyl group, an alkenyl group, or an alkynyl group, which may have a substituent. Among them, R_{A} to R_{D} are preferably an alkyl group which may have a substituent. The substituent is not particularly limited, and examples thereof include a hydroxyl group.

The alkyl group, alkenyl group, and alkynyl group are preferably linear or branched.

The number of carbon atoms in the alkyl group is preferably 1 to 30 and more preferably 1 to 25.

The number of carbon atoms in the alkenyl group and alkynyl group is preferably 2 to 30 and more preferably 2 to 25.

Examples of a suitable aspect of the quaternary ammonium ion represented by Formula (NA) include an aspect in which R_{A} and R_{B} are long chains (for example, the numbers of carbon atoms in R_{A} and R_{B} are each independently preferably 12 to 30 and more preferably 12 to 25), and R_{C} and R_{D} are short chains (for example, the numbers of carbon atoms in R_{C} and R_{D} are each independently preferably 1 to 10, more preferably 1 to 6, and it is still more preferable to be a methyl group).

From the viewpoint that the effects of the present invention are more excellent, the quaternary ammonium ion represented by Formula (NA) is preferable dimethyldioctadecylammonium.

As the copper phthalocyanines, from the viewpoint that the effects of the present invention are more excellent, a copper complex of phthalocyanine having a substituent including a sulfonic acid group or a salt thereof is preferable, a quaternary ammonium salt of a copper complex of phthalocyanine having a substituent including a sulfonic acid group is more preferable, and a salt composed of a copper complex of phthalocyanine having a substituent including a sulfonic acid group and dimethyldioctadecylammonium is still more preferable.

The substituent including a sulfonic acid group may be a sulfonic acid group or a group represented by *-L^{A}-sulfonic acid group (L^{A} represents a divalent linking group and * represents a bonding position). The divalent linking group represented by L^{A} is not particularly limited, and examples thereof include an alkylene group, an alkenylene group, an alkynylene group, —O—, —S—, —NR^{A}—, —CO—, and a group of a combination of these groups. R^{A} represents a hydrogen atom or an alkyl group having 1 to 6 carbon atoms. The above-described alkylene group, alkenylene group, and alkynylene group may further have a substituent.

Examples of the copper phthalocyanines include C. I. Pigment Blue 15:3.

In addition, examples of a commercially available product of the copper phthalocyanines include “5000” of “SOLSPERSE” series (manufactured by Lubrizol Japan Limited), and a copper phthalocyanine-3,4′,4″,4′″-tetrasulfonic acid tetrasodium salt available from Sigma-Aldrich Co., LLC.

A content of the copper phthalocyanines is preferably 1.0% by mass or more and more preferably 1.5% by mass or more with respect to the total solid content of the composition. Moreover, the upper limit value thereof is preferably 10% by mass or less, more preferably 8.0% by mass or less, still more preferably 6.0% by mass or less, and particularly preferably 4.0% by mass or less.

Furthermore, in the composition, a mass ratio of the content of the barium sulfate to the content of the copper phthalocyanines (content of barium sulfate/content of copper phthalocyanines) is, for example, preferably 0.1 to 5.0 and more preferably 0.1 to 3.0.

The copper phthalocyanines may be used singly or in combination of two or more thereof. In a case where two or more copper phthalocyanines are used in combination, the total content thereof is preferably within the above-described range.

Acid Generator

The composition includes an acid generator.

The acid generator is not particularly limited, and examples thereof include a thermal acid generator and a photoacid generator. Among these, from the viewpoint that the effects of the present invention are more excellent, a photoacid generator is preferable.

The photoacid generator is preferably a compound which generates an organic acid by irradiation with actinic ray or radiation, and a known compound can be used. A sensitive wavelength of the photoacid generator is preferably, for example, a wavelength of 300 to 450 nm. In other words, the photoacid generator is preferably a compound which generates an acid in response to actinic ray in the above-described wavelength range. In addition, a pKa of the acid generated from the photoacid generator is preferably 4.0 or less and more preferably 3.0 or less.

As the photoacid generator, a known photoacid generator can be used. Specific examples of the photoacid generator include an onium salt compound (for example, a sulfonium salt compound, an iodonium salt compound, a diazonium salt compound, a phosphonium salt compound, and the like), a triazine compound (preferably a halomethylated triazine compound and more preferably a trichloromethyl-s-triazine compound), an oxime sulfonate compound, a bissulfonyldiazomethane compound, an imide sulfonate compound, a diazodisulfone compound, an disulfone compound, and a nitrobenzylsulfonate compound (preferably a o-nitrobenzylsulfonate compound).

Among these, as the photoacid generator, from the viewpoint that the effects of the present invention are more excellent, it is preferable to include one or more kinds selected from the group consisting of a sulfonium salt compound, an iodonium salt compound, a triazine compound (preferably a halomethylated triazine compound and more preferably a trichloromethyl-s-triazine compound), a diazomethane compound, an imide sulfonate compound, and an oxime sulfonate compound, more preferable to include one or more kinds selected from the group consisting of a sulfonium salt compound, a halomethylated triazine compound (preferably a trichloromethyl-s-triazine compound), and an oxime sulfonate compound, and still more preferable to include any of a sulfonium salt compound or a halomethylated triazine compound (preferably a trichloromethyl-s-triazine compound).

Examples of the sulfonium salt compound include a compound represented by Formula (P-1). Examples of the iodonium salt compound include a compound represented by Formula (P-2). Examples of the oxime sulfonate compound include a compound represented by Formula (P-3). Examples of the triazine compound include a compound represented by Formula (P-4). Examples of the diazomethane compound include a compound represented by Formula (P-5). Examples of the imide sulfonate compound include a compound represented by Formula (P-6).

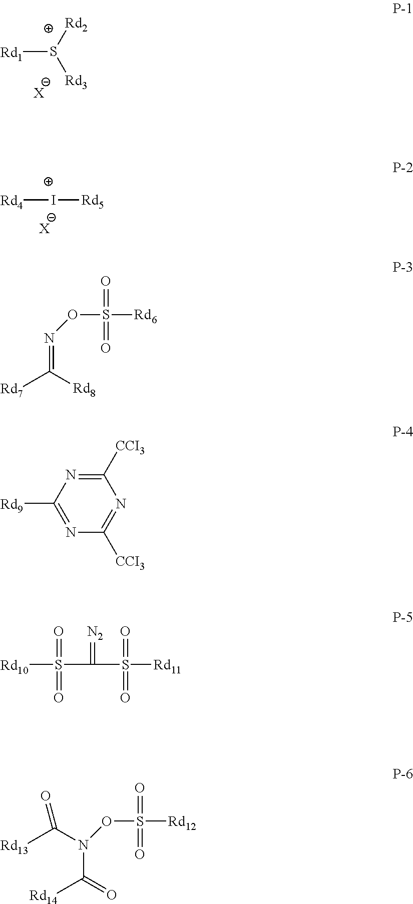

Rd₁ to Rd₁₄ each independently represent an organic group. X⁻ represents a counter anion.

In Formula (P-1), Rd₁ to Rd₃ each are each independently preferably an aryl group or an alkyl group (may be linear, branched, or cyclic). Moreover, two or more of Rd₁ to Rd₃ may be bonded to each other to form a ring.

The aryl group may be monocyclic or polycyclic. The aryl group is preferably a phenyl group or a naphthyl group, and more preferably a phenyl group.

The aryl group may have a substituent. Examples of the substituent include an alkyl group (for example, having 1 to 15 carbon atoms), a cycloalkyl group (for example, having 3 to 15 carbon atoms), an aryl group, an alkoxy group (for example, having 1 to 15 carbon atoms), an alkylthio group (for example, having 1 to 15 carbon atoms), an arylthio group, a thiol group, a halogen atom, a hydroxyl group, and —S⁺(R_{A})(R_{B}). These groups which are a substituent may further have a substituent.

The aryl group and arylthio group as the substituent may be monocyclic or polycyclic. As an aryl group in the aryl group and the arylthio group, a phenyl group or a naphthyl group is preferable, and a phenyl group is more preferable. Moreover, the aryl group in the awl group and the arylthio group may further have a substituent, and example of the substituent include an alkyl group (for example, having 1 to 6 carbon atoms).

R_{A} and R_{B} have the same definitions as Rd₁ to Rd₃, and suitable ranges thereof are also the same.

The alkyl group may be linear, branched, or cyclic, and examples thereof include a linear alkyl group having 1 to 15 carbon atoms, a branched alkyl group having 3 to 15 carbon atoms, and a cycloalkyl group having 3 to 15 carbon atoms. Specific examples thereof include a methyl group, an ethyl group, a propyl group, an n-butyl group, a sec-butyl group, a t-butyl group, a cyclopropyl group, a cyclobutyl group, and a cyclohexyl group. CH₂ in the alkyl group may be substituted with a heteroatom such as an oxygen atom or a heteroatom group such as a carbonyl group.

The alkyl group may have a substituent. Examples of the substituent include an awl group (for example, having 6 to 14 carbon atoms), an alkoxy group (for example, having 1 to 15 carbon atoms), a halogen atom, a hydroxyl group, and an arylthio group (for example, having 6 to 14 carbon atoms).

In addition, the ring formed by bonding two or more of Rd₁ to Rd₃ to each other may be any of an aromatic ring or alicyclic ring, and may be monocyclic or polycyclic. The number of ring members is, for example, 3 to 10, preferably 4 to 8 and more preferably 5 or 6. Moreover, the above-described ring may include an oxygen atom, a nitrogen atom, a sulfur atom, a ketone group, an ether bond, an ester bond, or an amide bond.

X⁻ is not particularly limited, and examples thereof include BF₄⁻, PF₆⁻, ClO₄⁻, AsF₆⁻, substituted or unsubstituted alkane sulfonic acid anions (for example, CF₃SO₃⁻, C₃F₇SO₃⁻, C₄F₉SO₃⁻, a camphorsulfonic acid anion, and the like), substituted benzene sulfonate anions (for example, a p-toluene sulfonic acid anion, a mesitylene sulfonic acid anion, and the like), bissulfonylimide anions (for example, a bis(trifluoromethanesulfonyl)imide anion, a cyclohexafluoropropane-1,3-bis(sulfonyl)imide anion, and the like), and substituted or unsubstituted alkane carboxylic acid anions (for example, CF₃CO₂⁻ and the like).

Specific examples of the triarylsulfonium compound represented by Formula (P-1) include triphenylsulfonium trifluoromethanesulfonate, triphenylsulfonium trifluoroacetate, 4-methoxyphenyldiphenylsulfonium trifluoromethanesulfonate, 4-methoxyphenyldiphenylsulfonium trifluoroacetate, 4-phenylthiophenyldiphenylsulfonium trifluoromethanesulfonate, and 4-phenylthiophenyldiphenylsulfonium trifluoroacetate.

In Formula (P-2), Rd₄ and Rd₅ have the same definitions as Rd₁ to Rd₃, and suitable ranges thereof are also the same. Among these, as Rd₄ and Rd₅, a substituted or unsubstituted aryl group is preferable, and a substituted or unsubstituted phenyl group is more preferable.

Specific examples of the iodonium salt compound represented by Formula (P-2) include diphenyliodonium trifluoroacetate, diphenyliodonium trifluoromethanesulfonate, 4-methoxyphenylphenyliodonium trifluoromethanesulfonate, 4-methoxyphenylphenyliodonium trifluoroacetate, phenyl-4-(2′-hydroxy-1′-tetradecaoxy)phenyliodonium trifluoromethanesulfonate, 4-(2′-hydroxy-1′-tetradecaoxy)phenyliodonium hexafluoroantimonate, and phenyl-4-(2′-hydroxy-1′-tetradecaoxy)phenyliodonium p-toluenesulfonate.

In Formula (P-3), Rd₆ has the same definitions as Rd₁ to Rd₃ described above, and a suitable range thereof is also the same.

Rd₇ is preferably an aryl group or a heteroaryl group.

The aryl group represented by Rd₇ may be monocyclic or polycyclic, and the number of ring-membered atoms is preferably 6 to 20 and more preferably 6 to 15. Specific examples of the aryl group include a phenyl group, a naphthyl group, an anthranil group, and a fluorenyl group.

The heteroaryl group represented by Rd₇ may be monocyclic or polycyclic, and the number of ring-membered atoms is preferably 5 to 20 and more preferably 5 to 15. Examples of a heteroatom in the heteroaryl group include a sulfur atom and an oxygen atom. Moreover, the number of heteroatoms in the heteroaryl group is, for example, 1 to 4. Specific examples of the heteroaryl group include a thiophene group and a furyl group.

The aryl group and heteroaryl group may have a substituent. Examples of the substituent include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, and a hydroxyl group.

Rd₈ is preferably an aryl group, a heteroaryl group, an alkyl group, or a cyano group.

Examples of the aryl group and heteroaryl group represented by Rd₈ include those same as the aryl group and heteroaryl group represented by Rd₇.

The alkyl group represented by Rd₈ may be linear, branched, or cyclic, and examples thereof include a linear alkyl group having 1 to 15 carbon atoms, a branched alkyl group having 3 to 15 carbon atoms, and a cycloalkyl group having 3 to 15 carbon atoms. Specific examples thereof include a methyl group, an ethyl group, a propyl group, an n-butyl group, a sec-butyl group, a t-butyl group, a cyclopropyl group, a cyclobutyl group, and a cyclohexyl group. CH₂ in the alkyl group may be substituted with a heteroatom such as an oxygen atom or a heteroatom group such as a carbonyl group.

The alkyl group may have a substituent. Examples of the substituent include an aryl group (for example, having 6 to 14 carbon atoms), an alkoxy group (for example, having 1 to 15 carbon atoms), a halogen atom (preferably, a fluorine atom), and a hydroxyl group. The alkyl group is also preferably a perfluoroalkyl group.

Moreover, Rd₇ and Rd₈ may be bonded to each other to form a ring. The ring formed by bonding Rd₇ and Rd₈ to each other may be any of an aromatic ring or alicyclic ring, and may be monocyclic or polycyclic. The number of ring members is, for example, 3 to 20, preferably 4 to 15 and more preferably 5 or 15. Moreover, the above-described ring may include an oxygen atom, a nitrogen atom, a sulfur atom, a ketone group, an ether bond, an ester bond, or an amide bond.

Examples of one aspect of the ring formed by bonding Rd₇ and Rd₈ to each other include a 5- or 6-membered aromatic heterocyclic ring including 1 or 2 heteroatoms (preferably, sulfur atoms or oxygen atoms) as ring-membered atoms.

Moreover, the ring formed by bonding Rd₇ and Rd₈ to each other may further have a substituent. The substituent is not particularly limited, and examples thereof include the substituents which are exemplified in the upper part as the substituent which can be included in the aryl group represented by Rd₁ to Rd₃.

Furthermore, the ring formed by bonding Rd₇ and Rd₈ to each other may form a conjugated bond with the substituent substituting the above-described ring.

Specific examples of the oxime sulfonate compound include IRGACURE PAG103, PAG108, PAG121, PAG203, CGI725, CGI1907, and CGI1397 (all manufactured by BASF SE, product names).

In Formula (P-4), Rd₉ is preferably a group represented by *-L_{X1}-Rd_{X1}. L_{X1} represents a single bond or a divalent linking group. Examples of Rd_{X1} include an aryl group or a heteroaryl group.

Examples of the divalent linking group represented by Lₓᵢ include —CO—, —O—, —SO—, —SO₂—, —NR^{A}—, an alkylene group (preferably having 1 to 6 carbon atoms; may be linear or branched), an alkenylene group (preferably having 2 to 6 carbon atoms; may be linear or branched), an alkynylene group (preferably having 2 to 6 carbon atoms; may be linear or branched), and a divalent linking group formed by a combination of a plurality of these groups. Moreover, the above-described alkylene group, alkenylene group, and alkynylene group may have a substituent. Examples of the substituent include a halogen atom (preferably, a fluorine atom) and a hydroxyl group. Examples of R^{A} include a hydrogen atom and an alkyl group having 1 to 6 carbon atoms.

Among these, Lₓᵢ is preferably a single bond or an alkenylene group, and more preferably a single bond or an alkenylene group having 2 to 4 carbon atoms.

The aryl group represented by Rd_{X1} may be monocyclic or polycyclic, and examples thereof include a phenyl group and a naphthalene group.

The heteroarylene group represented by Rd_{X1} may be monocyclic or polycyclic, and examples thereof include a pyrrole ring group, a furan ring group, a thiophene ring group, a benzofuran ring group, and a piperonyl group.

The aryl group and heteroarylene group represented by Rd_{X1} may further have a substituent. Examples of the substituent include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a substituted or unsubstituted amino group (examples of a substituent include an alkyl group having 1 to 10 carbon atoms), an alkylthio group (for example, having 1 to 15 carbon atoms), an arylthio group (for example, having 6 to 14 carbon atoms), a thiol group, a halogen atom, and a hydroxyl group.

Specific examples of the triazine compound represented by Formula (P-4) include 2-(3-chlorophenyl)-bis(4,6-trichloromethyl)-s-triazine, 2-(4-methoxyphenyl)-bis(4,6-trichloromethyl)-s-triazine, 2-(4-methylthiophenyl)-bis (4,6-trichloromethyl)-s-triazine, 2-(4-methoxy-β-styryl)-bis(4,6-trichloromethyl)-s-triazine, 2-piperonyl-bis (4,6-trichloromethyl)-s-triazine, 2-[2-(furan-2-yl)ethenyl]-bis (4,6-trichloromethyl)-s-triazine, 2-[2-(5-methyl)furan-2-yl)ethenyl]-his (4,6-trichloromethyl)-s-triazine, 2-[2-(4-diethylamino-2-methylphenyl)ethenyl]-bis(4,6-trichloromethyl)-s-triazine, and 2-(4-methoxynaphthyl)-bis(4,6-trichloromethyl)-s-triazine.

In Formula (P-5), Rd₁₀ and Rd₁₁ are preferably an alkyl group or an aryl group. The alkyl group and aryl group represented by Rd₁₀ and Rd₁₁ are the same as the alkyl group and aryl group represented by Rd₆, and suitable aspects thereof are also the same.

Specific examples of the diazomethane compound include bis(cyclohexylsulfonyl)diazomethane, bis(t-butylsulfonyl)diazomethane, and bis(p-toluenesulfonyl)diazomethane.

In Formula (P-6), Rd₁₂ has the same definitions as R_{d1} to Rd₃ described above, and a suitable range thereof is also the same.

Rd₁₃ and Rd₁₄ are preferably an alkyl group.

Examples of the alkyl group represented by Rd₁₃ and Rd₁₄ include the same alkyl groups represented by Rd₈ described above, and a suitable aspect thereof is also the same.

Moreover, Rd₁₃ and Rd₁₄ may be bonded to each other to form a ring. The ring formed by bonding Rd₁₃ and Rd₁₄ to each other is preferably an alicyclic ring, and may be monocyclic or polycyclic. The number of ring members is, for example, 3 to 20, preferably 4 to 15 and more preferably 5 or 15. Moreover, the above-described ring may include an oxygen atom, a nitrogen atom, a sulfur atom, a ketone group, an ether bond, an ester bond, or an amide bond.

Moreover, the ring formed by bonding Rd₁₃ and Rd₁₄ to each other may further have a substituent. The substituent is not particularly limited, and examples thereof include the substituents which are exemplified in the upper part as the substituent which can be included in the aryl group and alkyl group represented by R_{d1} to Rd₃.

Specific examples of the imide sulfonate compound represented by Formula (P-6) include trifluoromethylsulfonyloxybicyclo[2.2.1]-hept-5-en-dicarboxyimide, succinimide trifluoromethylsulfonate, phthalimidetrifluoromethylsulfonate, N-hydroxynaphthalimidemethanesulfonate, and N-hydroxy-5-norbornene-2,3-dicarboxyimide propanesulfonate.

Examples of X⁻ in Formulae (P-2) to (P-6) include those same as X⁻ in Formula (P-1).

The acid generator may be used alone or in combination of two or more thereof, and from the viewpoint that the effects of the present invention are more excellent, it is preferable to use two or more kinds thereof in combination. Among these, it is more preferable to use the sulfonium salt compound and the halomethylated triazine compound (preferably a trichloromethyl-s-triazine compound) in combination.

A content of the acid generator is preferably 1.0% by mass or more and more preferably 2.0% by mass or more with respect to the total solid content of the composition. The upper limit thereof is preferably 30% by mass or less, more preferably 25% by mass or less, and still more preferably 20% by mass or less with respect to the total solid content of the composition.

Crosslinking Agent

The composition include a crosslinking agent having a crosslinkable group which is crosslinked by an acid (specific crosslinking agent).

Examples of the crosslinkable group which is crosslinked by an acid include an epoxy group, an oxetanyl group, an alkoxymethyl group, and a methylol group (—CH₂—OH), and from the viewpoint that the effects of the present invention are more excellent, an epoxy group, an oxetanyl group, or an alkoxymethyl group is preferable, and an alkoxymethyl group is more preferable.

The number of crosslinkable groups in the specific crosslinking agent is not particularly limited, but for example, is preferably 2 to 20 and more preferably 2 to 10.

In the specific crosslinking agent, an equivalent of the crosslinkable group (molecular weight of the specific crosslinking group/number of crosslinkable groups) is, for example, 50 to 2000 g/equivalent, more preferably 60 to 1000 g/equivalent, and still more preferably 75 to 1000 g/equivalent.

A molecular weight of the specific crosslinking agent is not particularly limited, but for example, preferably 100 to 2,000, more preferably 150 to 1,000, still more preferably 180 to 800, and particularly preferably 200 to 500.

Specific examples of a compound having an epoxy group or an oxetanyl group include a bisphenol A-type epoxy resin, a bisphenol F-type epoxy resin, a phenol novolac-type epoxy resin, a cresol novolac-type epoxy resin, and an aliphatic epoxy resin.

Examples of a commercially available product of the compound having an epoxy group or an oxetanyl group include JER (registered trademark) 152, JER157S70, JER157S65, JER806, JER828, and JER1007 (all manufactured by Mitsubishi Chemical Holdings Corporation); commercially available products described in paragraph 0189 of JP2011-221494A; ADEKA RESIN EP-4000S, EP-40035, EP-4010S, and EP-4011S (all manufactured by ADEKA Corporation); NC-2000, NC-3000, NC-7300, XD-1000, EPPN-501, and EPPN-502 (all manufactured by ADEKA Corporation); DENACOL (registered trademark) EX-611, EX-612, EX-614, EX-614B, EX-622, EX-512, EX-521, EX-411, EX-421, EX-313, EX-314, EX-321, EX-211, EX-212, EX-810, EX-811, EX-850, EX-851, EX-821, EX-830, EX-832, EX-841, EX-911, EX-941, EX-920, EX-931, EX-212L, EX-214L, EX-216L, EX-321L, EX-850L, DLC-201, DLC-203, DLC-204, DLC-205, DLC-206, DLC-301, and DLC-402 (all manufactured by Nagase ChemteX Corporation); and YH-300, YH-301, YH-302, YH-315, YH-324, and YH-325 (all manufactured by NIPPON STEEL Chemical & Material Co., Ltd.).

In addition, examples of a commercially available product of the compound having an oxetane group include ARON OXETANE (registered trademark), OXT-121, OXT-221, OX-SQ, and PNOX (all manufactured by Toagosei Co., Ltd.).

A compound having an alkoxymethyl group is not particularly limited, and examples thereof include alkoxymethylated melamine, alkoxymethylated benzoguanamine, alkoxymethylated glycoluril, and alkoxymethylated urea. Each of these compounds is obtained by converting a methylol group of methylolated melamine, methylolated benzoguanamine, methylolated glycoluril, or methylolated urea to an alkoxymethyl group. In each compound, the methylol group is substituted with amine nitrogen in the compound.

The number of carbon atoms of the alkoxy group in the alkoxymethyl group is not particularly limited, but is preferably 1 to 10, more preferably 1 to 6, still more preferably 1 to 4, and particularly preferably 1. Specific examples of the alkoxymethyl group include a methoxymethyl group, an ethoxymethyl group, a propoxymethyl group, and a butoxymethyl group.

Examples of a commercially available product of the compound having an alkoxymethyl group include CYMEL 300, 301, 303, 370, 325, 327, 701, 266, 267, 238, 1141, 272, 202, 1156, 1158, 1123, 1170, 1174, UFR 65, and 300 (all manufactured by Mitsubishi Cyanamid); NIKALAC MX-750, MX-750LM, MX-032, MX-706, MX-708, MX-40, MX-31, MX-270, MX-280, and MX-290 (all manufactured by Sanwa Chemical Co., Ltd.); NIKARAC MS-11 (manufactured by Sanwa Chemical Co., Ltd.); and NIKARAC MW-30HM, MW-100LM, and MW-390 (all manufactured by Sanwa Chemical Co., Ltd.).

The compound having a methylol group is not particularly limited, and examples thereof include methylolated melamine, methylolated benzoguanamine, methylolated glycoluril, and methylolated urea.

Among these, as the specific crosslinking agent, from the viewpoint that the effects of the present invention are more excellent, a compound having a triazine structure is preferable, and a compound having a 1,3,5-triazine structure is more preferable. By the triazine compound, it is considered that the effect of increasing the interaction with various substrates can be expected and the adhesiveness can be improved.

A content of the specific crosslinking agent is preferably 5.0% by mass or more and more preferably 10% by mass or more with respect to the total solid content of the composition. The upper limit thereof is preferably 50% by mass or less, more preferably 40% by mass or less, and still more preferably 30% by mass or less with respect to the total solid content of the composition.

One kind of the specific crosslinking agent may be used singly, or two or more kinds thereof may be used. In a case where two or more specific crosslinking agents are used in combination, the total content thereof is preferably within the above-described range.

Moreover, a mass ratio (content of the specific crosslinking agent/content of the acid generator) of the content of the specific crosslinking agent to the content of the acid generator is, for example, 0.5 to 10, and from the viewpoint that the effects of the present invention are more excellent, is preferably more than 1.5 and less than 6.0 and more preferably 2.0 to 5.0.

Resin

The composition according to the embodiment of the present invention includes a resin. Examples of the resin include a dispersant and an alkali-soluble resin.

A content of the resin in the composition is not particularly limited, but is preferably 3.0% to 60% by mass, more preferably 5.0% to 40% by mass, and still more preferably 12% to 35% by mass with respect to the total solid content of the composition.

Moreover, in a case where the composition according to the embodiment of the present invention includes particles A described later as one aspect, the content of the resin in the composition is also preferably 12% by mass or less with respect to the total solid content of the composition. In this case, the content of the particles A is preferably 5% by mass or more with respect to the total solid content of the composition. The upper limit value of the content of the particles A in this aspect is preferably 40% by mass or less and more preferably 30% by mass or less with respect to the total solid content of the composition.

The resin may be used alone or in combination of two or more thereof. In a case where two or more resins are used in combination, the total content thereof is preferably within the above-described range.

A molecular weight of the resin is more than 2000. In a case where the molecular weight of the resin is polydisperse, a weight-average molecular weight thereof is preferably more than 2000.

Dispersant

The composition preferably includes a dispersant. In the present specification, a dispersant means a compound different from the alkali-soluble resin which will be described later.

A content of the dispersant in the composition is not particularly limited, but is preferably 2.0% to 40% by mass, more preferably 5.0% to 30% by mass, still more preferably 5.0% to 25% by mass, and particularly preferably 5.0% to 20% by mass with respect to the total solid content of the composition.

The dispersant may be used alone or in combination of two or more thereof. In a case where two or more dispersants are used in combination, the total content thereof is preferably within the above-described range.

Moreover, in the composition, a mass ratio of the content of the dispersant to the content of the carbon black (content of the dispersant/content of the carbon black) is preferably 0.05 to 1.00, more preferably 0.10 to 0.80, and still more preferably 0.20 to 0.80.

As the dispersant, for example, known dispersants can be appropriately selected and used. Among them, a polymer compound is preferable.

Examples of the dispersant include a polymer dispersant [for example, polyamidoamine and a salt thereof, polycarboxylic acid and a salt thereof, high-molecular-weight unsaturated acid ester, modified polyurethane, modified polyester, modified poly(meth)acrylate, a (meth)acrylic copolymer, and a naphthalenesulfonic acid-formalin condensate], polyoxyethylene alkyl phosphoric acid ester, polyoxyethylene alkylamine, and a pigment derivative.

The polymer compound can be further classified into a linear polymer, a terminal-modified polymer, a graft polymer, and a block polymer based on the structure.

Polymer Compound

The polymer compound acts to prevent the reaggregation of a substance to be dispersed by being adsorbed onto a surface of the substance to be dispersed, such as the carbon black and another pigment (hereinafter, the carbon black and the other pigment are collectively and simply referred to as a “pigment” as well) used in combination as desired. Therefore, a terminal-modified polymer, a graft (including a polymer chain) polymer, or a block polymer is preferable which includes a moiety anchored to the pigment surface.

The above-described polymer compound may include a curable group.

Examples of the curable group include an ethylenically unsaturated group (for example, a (meth)acryloyl group, a vinyl group, a styryl group, and the like), and a cyclic ether group (for example, an epoxy group, an oxetanyl group, and the like), but the present invention is not limited thereto.

The resin including a curable group preferably includes one or more kinds selected from the group consisting of a polyester structure and a polyether structure. In this case, the polyester structure and/or the polyether structure may be included in a main chain, and as will be described later, in a case where the above-described resin has a structural unit including a graft chain, the above-described polymer chain may have a polyester structure and/or a polyether structure.

As the resin, a resin in which the polymer chain has a polyester structure is more preferable.

The polymer compound preferably has a structural unit including a graft chain. In the present specification, the “structural unit” has the same definition as a “repeating unit”.

Such a polymer compound having the structural unit including a graft chain has an affinity with a solvent due to the graft chain, and thus is excellent in dispersibility of a pigment or the like and dispersion stability after the lapse of time. Moreover, due to the presence of the graft chain, the polymer compound having the structural unit including a graft chain has an affinity with a polymerizable compound or other resins which can be used in combination. As a result, residues are less likely to be generated in alkali development.

In a case where the graft chain is prolonged, a steric repulsion effect is enhanced, and thus the dispersibility of the pigment or the like is improved. Meanwhile, in a case where the graft chain is too long, adsorptive power to the pigment or the like is reduced, and thus the dispersibility of the pigment or the like tends to be reduced. Therefore, the number of atoms excluding a hydrogen atom in the graft chain is preferably 40 to 10000, more preferably 50 to 2000, and still more preferably 60 to 500.

Herein, the graft chain refers to a portion from the base (in a group which is branched off from the main chain, an atom bonded to the main chain) of a main chain of the copolymer to the terminal of a group branched off from the main chain.

The graft chain preferably includes a polymer structure, and examples of such a polymer structure include a poly(meth)acrylate structure (for example, a poly(meth)acryl structure), a polyester structure, a polyurethane structure, a polyurea structure, a polyamide structure, and a polyether structure.

In order to improve interactive properties between the graft chain and the solvent, and thus enhance the dispersibility of the pigment or the like, the graft chain is preferably a graft chain having one or more kinds selected from the group consisting of a polyester structure, a polyether structure, and a poly(meth)acrylate structure, and more preferably a graft chain having at least one of a polyester structure or a polyether structure.

A macromonomer (a monomer which has a polymer structure and constitutes a graft chain by being bonded to the main chain of a copolymer) including such a graft chain is not particularly limited, but a macromonomer including a reactive double bond group can be suitably used.

As a commercial macromonomer, which corresponds to the structural unit including a graft chain included in the polymer compound and is suitably used for synthesizing the polymer compound, AA-6 (trade name, manufactured by TOAGOSEI CO., LTD.), AA-10 (trade name, manufactured by TOAGOSEI CO., LTD.), AB-6 (trade name, manufactured by TOAGOSEI CO., LTD.), AS-6 (trade name, manufactured by TOAGOSEI CO., LTD.), AN-6 (trade name, manufactured by TOAGOSEI CO., LTD.), AW-6 (trade name, manufactured by TOAGOSEI CO., LTD.), AA-714 (trade name, manufactured by TOAGOSEI CO., LTD.), AY-707 (trade name, manufactured by TOAGOSEI CO., LTD.), AY-714 (trade name, manufactured by TOAGOSEI CO., LTD.), AK-5 (trade name, manufactured by TOAGOSEI CO., LTD.), AK-30 (trade name, manufactured by TOAGOSEI CO., LTD.), AK-32 (trade name, manufactured by TOAGOSEI CO., LTD.), BLEMMER PP-100 (trade name, manufactured by NOF CORPORATION), BLEMMER PP-500 (trade name, manufactured by NOF CORPORATION), BLEMMER PP-800 (trade name, manufactured by NOF CORPORATION), BLEMMER PP-1000 (trade name, manufactured by NOF CORPORATION), BLEMMER 55-PET-800 (trade name, manufactured by NOF CORPORATION), BLEMMER PME-4000 (trade name, manufactured by NOF CORPORATION), BLEMMER PSE-400 (trade name, manufactured by NOF CORPORATION), BLEMMER PSE-1300 (trade name, manufactured by NOF CORPORATION), BLEMMER 43PAPE-600B (trade name, manufactured by NOF CORPORATION), or the like is used. Among them, AA-6 (trade name, manufactured by TOAGOSEI CO., LTD.), AA-10 (trade name, manufactured by TOAGOSEI CO., LTD.), AB-6 (trade name, manufactured by TOAGOSEI CO., LTD.), AS-6 (trade name, manufactured by TOAGOSEI CO., LTD.), AN-6 (trade name, manufactured by TOAGOSEI CO., LTD.), or BLEMMER PME-4000 (trade name, manufactured by NOF CORPORATION) is preferable.

The dispersant preferably has one or more structures selected from the group consisting of polymethyl acrylate, polymethyl methacrylate, and cyclic or chain-like polyester, more preferably has one or more structures selected from the group consisting of polymethyl acrylate, polymethyl methacrylate, and chain-like polyester, and still more preferably has one or more structures selected from the group consisting of a polymethyl acrylate structure, a polymethyl methacrylate structure, a polycaprolactone structure, and a polyvalerolactone structure. The dispersant may be a dispersant having the above-described structure alone in one dispersant, or may be a dispersant having a plurality of these structures in one dispersant.

Herein, the polycaprolactone structure refers to a structure including a structure, which is obtained by ring opening of ε-caprolactone, as a repeating unit. The polyvalerolactone structure refers to a structure including a structure, which is obtained by ring opening of δ-valerolactone, as a repeating unit.

Specific examples of the dispersant having a polycaprolactone structure include dispersants in which j and k in Formula (1) and Formula (2) are each 5. Moreover, specific examples of the dispersant having a polyvalerolactone structure include dispersants in which j and k in Formula (1) and Formula (2) are each 4.

Specific examples of the dispersant having a polymethyl acrylate structure include dispersants in which in Formula (4), X⁵ is a hydrogen atom and R⁴ is a methyl group. Moreover, specific examples of the dispersant having a polymethyl methacrylate structure include dispersants in which in Formula (4), X⁵ is a methyl group and R⁴ is a methyl group.

Structural Unit Including Graft Chain

As the structural unit including a graft chain, the polymer compound preferably has a structural unit represented by any one of Formula (1), . . . , or Formula (4), and more preferably has a structural unit represented by any one of Formula (1A), Formula (2A), Formula (3A), Formula (3B), or Formula (4).

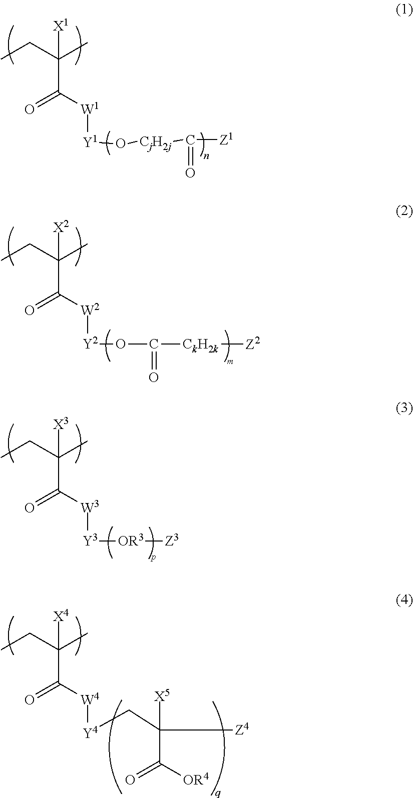

In Formulae (1) to (4), W¹, W², W³, and W⁴ each independently represent an oxygen atom or NH. W¹, W², W³, and W⁴ are each preferably an oxygen atom.

In Formulae (1) to (4), X¹, X², X³, X⁴, and X⁵ each independently represent a hydrogen atom or a monovalent organic group. From the viewpoint of the restriction on synthesis, X¹, X², X³, X⁴, and X⁵ are preferably each independently a hydrogen atom or an alkyl group having 1 to 12 carbon atoms (the number of carbon atoms), more preferably each independently a hydrogen atom or a methyl group, and still more preferably each independently a methyl group.

In Formulae (1) to (4), Y¹, Y², Y³, and Y⁴ each independently represent a divalent linking group, and the linking group has no particular restriction on a structure. Specific examples of the divalent linking groups represented by Y¹ and Y⁴ include linking, Y², Y³, groups represented by the following (Y-1) to (Y-21). In the following structures, A and B mean moieties bonded to the left terminal group and the right terminal group in Formulae (1) to (4), respectively. Among the following structures, from the viewpoint of simplicity of synthesis, (Y-2) or (Y-13) is more preferable.

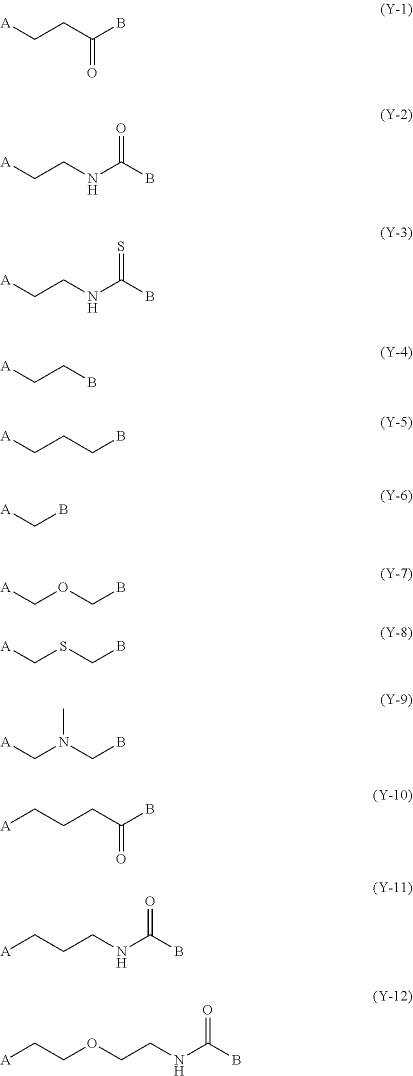

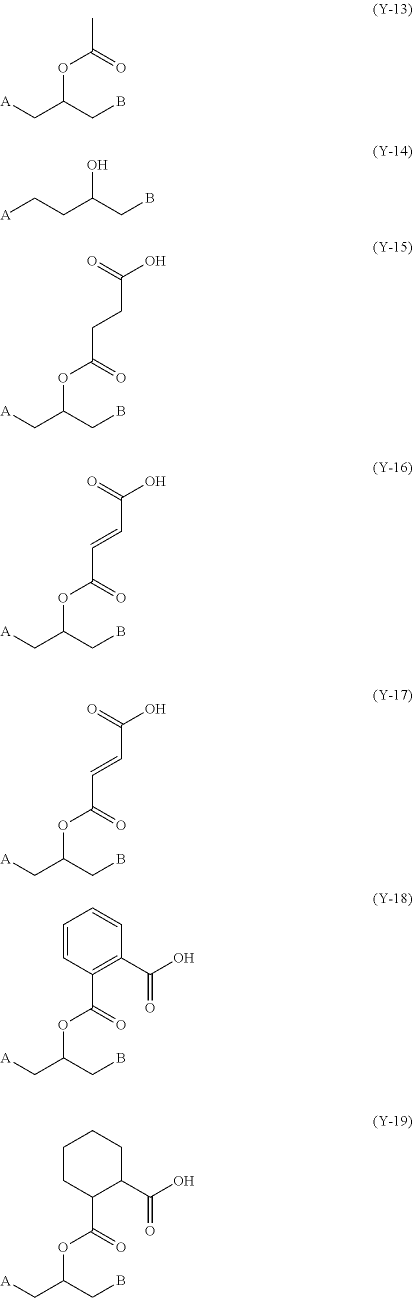

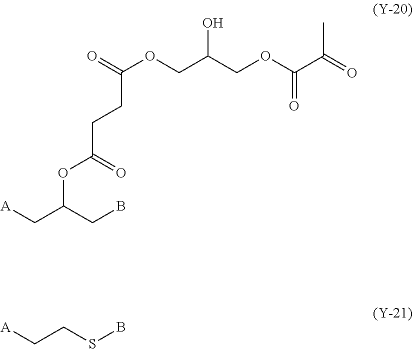

In Formulae (1) to (4), Z¹, Z², Z³, and Z⁴ each independently represent a monovalent organic group. The structure of the organic group is not particularly limited, but specific examples thereof include an alkyl group, a hydroxyl group, an alkoxy group, an aryloxy group, a heteroaryloxy group, an alkylthioether group, an arylthioether group, a heteroarylthioether group, and an amino group. Among them, particularly from the viewpoint of improvement in the dispersibility, the organic groups represented by Z¹, Z², Z³, and Z⁴ are each preferably a group exhibiting a steric repulsion effect, and more preferably each independently an alkyl group or alkoxy group having 5 to 24 carbon atoms, and, among them, in particular, still more preferably each independently a branched alkyl group having 5 to 24 carbon atoms, a cyclic alkyl group having 5 to 24 carbon atoms, or an alkoxy group having 5 to 24 carbon atoms. Furthermore, the alkyl group included in the alkoxy group may be any of linear, branched, or cyclic.

In Formulae (1) to (4), n, m, p, and q are each independently an integer of 1 to 500.

In addition, in Formulae (1) and (2), j and k each independently represent an integer of 2 to 8. From the viewpoints of the viscosity stability over time and developability of the composition, j and k in Formulae (1) and (2) are each preferably an integer of 4 to 6 and more preferably 5.

In Formulae (1) and (2), n and m are each preferably an integer of 10 or more and more preferably an integer of 20 or more. Moreover, in a case where the dispersant has a polycaprolactone structure and a polyvalerolactone structure, the sum of the repetition number of the polycaprolactone structure and the repetition number of the polyvalerolactone structure is preferably an integer 10 of more and more preferably an integer of 20 or more.

In Formula (3), R³ represents a branched or linear alkylene group, and is preferably an alkylene group having 1 to 10 carbon atoms and more preferably an alkylene group having 2 or 3 carbon atoms. In a case where p is 2 to 500, a plurality of R³'s may be the same as or different from each other.

In Formula (4), R⁴ represents a hydrogen atom or a monovalent organic group, and the monovalent organic group has no particular limitation on a structure. As R⁴, a hydrogen atom, an alkyl group, an aryl group, or a heteroaryl group is preferable, and a hydrogen atom or an alkyl group is more preferable. In a case where R⁴ is an alkyl group, as the alkyl group, a linear alkyl group having 1 to 20 carbon atoms, a branched alkyl group having 3 to 20 carbon atoms, or a cyclic alkyl group having 5 to 20 carbon atoms is preferable, a linear alkyl group having 1 to 20 carbon atoms is more preferable, and a linear alkyl group having 1 to 6 carbon atoms is still more preferable. In a case where q in Formula (4) is 2 to 500, a plurality of X⁵'s and a plurality of R⁴'s in the graft copolymer may be respectively the same as or different from each other.

In addition, the polymer compound may have a structural unit which includes two or more different structures and includes a graft chain. That is, the structural units which are represented by Formulae (1) to (4) and have structures different from one another may be included in a molecule of the polymer compound, and in a case where n, m, p, and q in Formulae (1) to (4) each represent an integer equal to or greater than 2, in Formulae (1) and (2), structures in which j and k are different from each other may be included in the side chain, and in Formulae (3) and (4), a plurality of R³'s, a plurality of R⁴'s, and a plurality of X⁵'s in the molecule may be respectively the same as or different from each other.

From the viewpoints of the viscosity stability over time and developability of the composition, the structural unit represented by Formula (1) is more preferably a structural unit represented by Formula (1A).

Furthermore, from the viewpoints of the viscosity stability over time and developability of the composition, the structural unit represented by Formula (2) is more preferably a structural unit represented by Formula (2A).

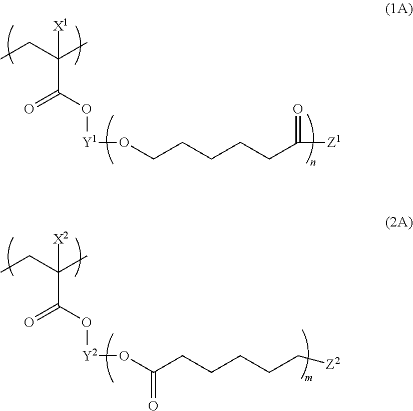

X¹, Y¹, Z¹, and n in Formula (1A) have the same definitions as X¹, Y¹, Z¹, and n in Formula (1), and preferred ranges thereof are also the same. X², Y², Z², and m in Formula (2A) have the same definitions as X², Y², Z², and m in Formula (2), and preferred ranges thereof are also the same.

In addition, from the viewpoints of the viscosity stability over time and developability of the composition, the structural unit represented by Formula (3) is more preferably a structural unit represented by Formula (3A) or (3B).

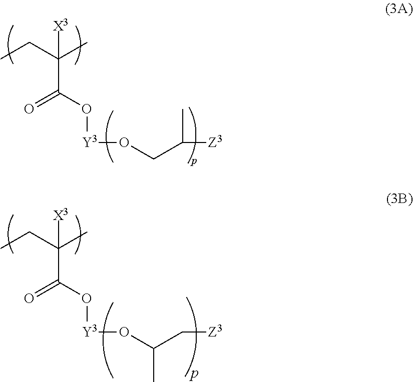

X³, Y³, Z³, and p in Formula (3A) or (3B) have the same definitions as X³, Y³, Z³, and p in Formula (3), and preferred ranges thereof are also the same.

The polymer compound more preferably has, as a structural unit including a graft chain, the structural unit represented by Formula (1A).

The content of the structural unit (for example, the structural units represented by Formulae (1) to (4)) including a graft chain in the polymer compound is preferably within a range of 2% to 90% by mass and more preferably within a range of 5% to 30% by mass, in terms of mass with respect to the total mass of the polymer compound. In a case where the structural unit including a graft chain is within the above-described range, the dispersibility of the pigment is high and the developability of the cured film after exposure is good.

Hydrophobic Structural Unit

The polymer compound preferably includes a hydrophobic structural unit which is different from the structural unit including a graft chain (that is, the structural unit does not correspond to the structural unit including a graft chain). Here, in the present specification, the hydrophobic structural unit is a structural unit which does not have an acid group (for example, a carboxylic acid group, a sulfonic acid group, a phosphoric acid group, a phenolic hydroxyl group, or the like).

As the hydrophobic structural unit, a structural unit derived from (corresponding to) a compound (monomer) having a Clog P value of 1.2 or more is preferable, and a structural unit derived from a compound having a Clog P value of 1.2 to 8 is more preferable. By doing so, the effects of the present invention can be more reliably exhibited.

The Clog P value is a value calculated by a program “CLOG P” available from Daylight Chemical Information System, Inc. This program provides a value of “calculated log P” calculated by the fragment approach (see the following documents) of Hansch and Leo. The fragment approach is based on a chemical structure of a compound, and the log P value of the compound is estimated by dividing the chemical structure into partial structures (fragments) and summing up degrees of contribution to log P which are assigned to the fragments. Details of the method are described in the following documents. In the present specification, a Clog P value calculated by a program CLOG P v4.82 is used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990, C. Hansch & A. J. Leo. Substituent Constants For Correlation Analysis in Chemistry and Biology. John Wiley & Sons. A. J. Leo. Calculating log Poct from structure. Chem. Rev., 93, 1281 to 1306, 1993.

The log P refers to a common logarithm of a partition coefficient P, is a physical property value that shows how a certain organic compound is partitioned in an equilibrium of a two-phase system consisting of oil (generally, 1-octanol) and water by using a quantitative numerical value, and is expressed by the following expression.

log P=log(Coil/Cwater)

In the expression, Coil represents a molar concentration of a compound in an oil phase, and Cwater represents a molar concentration of the compound in a water phase.

The greater the positive log P value based on 0, the higher the oil solubility, and the greater the absolute value of negative log P, the higher the water solubility. Accordingly, the value of log P has a negative correlation with the water solubility of an organic compound and is widely used as a parameter for estimating the hydrophilicity and hydrophobicity of an organic compound.

The polymer compound preferably includes, as the hydrophobic structural unit, one or more structural units selected from structural units derived from monomers represented by Formulae (i) to (iii).

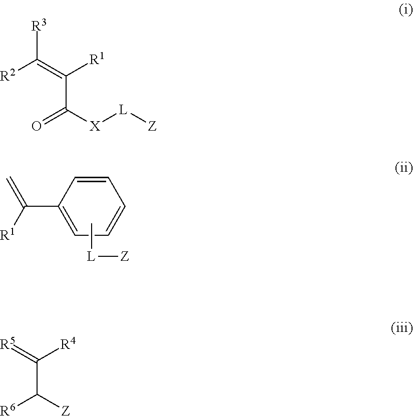

In Formulae (i) to (iii), R¹, R², and R³ each independently represent a hydrogen atom, a halogen atom (for example, a fluorine atom, a chlorine atom, a bromine atom, or the like), or an alkyl group (for example, a methyl group, an ethyl group, a propyl group, or the like) having 1 to 6 carbon atoms.

R¹, R², and R³ are each preferably a hydrogen atom or an alkyl group having 1 to 3 carbon atoms, and more preferably a hydrogen atom or a methyl group. R² and R³ are each still more preferably a hydrogen atom.

X represents an oxygen atom (—O—) or an imino group (—NH—), and is preferably an oxygen atom.

L is a single bond or a divalent linking group. Examples of the divalent linking group include a divalent aliphatic group (for example, an alkylene group, a substituted alkylene group, an alkenylene group, a substituted alkenylene group, an alkynylene group, or a substituted alkynylene group), a divalent aromatic group (for example, an arylene group or a substituted arylene group), a divalent heterocyclic group, an oxygen atom (—O—), a sulfur atom (—S—), an imino group (—NH—), a substituted imino group (—NR³¹—, where R³¹ is an aliphatic group, an aromatic group, or a heterocyclic group), a carbonyl group (—CO—), and a combination thereof.

The divalent aliphatic group may have a cyclic structure or a branched structure. The number of carbon atoms in the aliphatic group is preferably 1 to 20, more preferably 1 to 15, and still more preferably 1 to 10. The aliphatic group may be an unsaturated aliphatic group or a saturated aliphatic group, but is preferably a saturated aliphatic group. In addition, the aliphatic group may have a substituent. Examples of the substituent include a halogen atom, an aromatic group, and a heterocyclic group.

The number of carbon atoms in the divalent aromatic group is preferably 6 to 20, more preferably 6 to 15, and still more preferably 6 to 10. In addition, the aromatic group may have a substituent. Examples of the substituent include a halogen atom, an aliphatic group, an aromatic group, and a heterocyclic group.

The divalent heterocyclic group preferably includes a 5-membered ring or a 6-membered ring as a heterocyclic ring. The heterocyclic ring may be fused with another heterocyclic ring, an aliphatic ring, or an aromatic ring. In addition, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group.

L is preferably a single bond, an alkylene group, or a divalent linking group having an oxyalkylene structure. The oxyalkylene structure is more preferably an oxyethylene structure or an oxypropylene structure. Moreover, L may have a polyoxyalkylene structure which includes two or more repeating oxyalkylene structures. As the polyoxyalkylene structure, a polyoxyethylene structure or a polyoxypropylene structure is preferable. The polyoxyethylene structure is represented by —(OCH₂CH₂)ₙ—, and n is preferably an integer of 2 or more and more preferably an integer of 2 to 10.

Examples of Z include an aliphatic group (for example, an alkyl group, a substituted alkyl group, an unsaturated alkyl group, or a substituted unsaturated alkyl group), an aromatic group (for example, an aryl group, a substituted aryl group, an arylene group, or a substituted arylene group), a heterocyclic group, and a combination thereof. These groups may contain an oxygen atom (—O—), a sulfur atom (—S—), an imino group (—NH—), a substituted imino group (—NR³¹—, where R³¹ is an aliphatic group, an aromatic group, or a heterocyclic group), or a carbonyl group (—CO—).

The aliphatic group may have a cyclic structure or a branched structure. The number of carbon atoms in the aliphatic group is preferably 1 to 20, more preferably 1 to 15, and still more preferably 1 to 10. The aliphatic group further contains a ring assembly hydrocarbon group or a crosslinked cyclic hydrocarbon group, and examples of the ring assembly hydrocarbon group include a bicyclohexyl group, a perhydronaphthalenyl group, a biphenyl group, and a 4-cyclohexylphenyl group. Examples of a crosslinked cyclic hydrocarbon ring include a bicyclic hydrocarbon ring such as pinane, bornane, norpinane, norbornane, and bicyclooctane rings (a bicyclo[2.2.2]octane ring, a bicyclo[3.2.1]octane ring, or the like); a tricyclic hydrocarbon ring such as homobredane, adamantane, tricyclo[5.2.1.0^{2,6}]decane, and tricyclo[4.3.1.1^{2,5}]undecane rings; and a tetracyclic hydrocarbon ring such as tetracyclo [4.4.0.1^{2,5}.1^{7,10}]dodecane and perhydro-1,4-methano-5,8-methanonaphthalene rings. In addition, the crosslinked cyclic hydrocarbon ring also includes a fused cyclic hydrocarbon ring, for example, a fused ring in which a plurality of 5- to 8-membered cycloalkane rings, such as perhydronaphthalene (decalin), perhydroanthracene, perhydrophenanthrene, perhydroacenaphthene, perhydrofluorene, perhydroindene, and perhydrophenalene rings, are fused.

As the aliphatic group, a saturated aliphatic group is preferable to an unsaturated aliphatic group. In addition, the aliphatic group may have a substituent. Examples of the substituent include a halogen atom, an aromatic group, and a heterocyclic group. Here, the aliphatic group does not have an acid group as a substituent.

The number of carbon atoms in the aromatic group is preferably 6 to 20, more preferably 6 to 15, and still more preferably 6 to 10. In addition, the aromatic group may have a substituent. Examples of the substituent include a halogen atom, an aliphatic group, an aromatic group, and a heterocyclic group. Here, the aromatic group does not have an acid group as a substituent.

The heterocyclic group preferably includes a 5-membered ring or a 6-membered ring as a heterocyclic ring. The heterocyclic ring may be fused with another heterocyclic ring, an aliphatic ring, or an aromatic ring. In addition, the heterocyclic group may have a substituent. Examples of the substituent include a halogen atom, a hydroxyl group, an oxo group (═O), a thioxo group (═S), an imino group (═NH), a substituted imino group (═N—R³², where R³² is an aliphatic group, an aromatic group, or a heterocyclic group), an aliphatic group, an aromatic group, and a heterocyclic group. Here, the heterocyclic group does not have an acid group as a substituent.

In Formula (iii), R⁴, R⁵, and R⁶ each independently represent a hydrogen atom, a halogen atom (for example, a fluorine atom, a chlorine atom, a bromine atom, or the like), an alkyl group (for example, a methyl group, an ethyl group, a propyl group, or the like) having 1 to 6 carbon atoms, Z, or L-Z. Herein, L and Z have the same definitions as the groups described above. R⁴, R⁵, and R⁶ are each preferably a hydrogen atom or an alkyl group having 1 to 3 carbon atoms, and more preferably a hydrogen atom.

The monomer represented by Formula (i) is preferably a compound in which R′, R², and R³ are each a hydrogen atom or a methyl group, L is a single bond, an alkylene group, or a divalent linking group having an oxyalkylene structure, X is an oxygen atom or an imino group, and Z is an aliphatic group, a heterocyclic group, or an aromatic group.

The monomer represented by Formula (ii) is preferably a compound in which R¹ is a hydrogen atom or a methyl group, L is an alkylene group, and Z is an aliphatic group, a heterocyclic group, or an aromatic group. Moreover, the monomer represented by Formula (iii) is preferably a compound in which R⁴, R⁵, and R⁶ are each a hydrogen atom or a methyl group, and Z is an aliphatic group, a heterocyclic group, or an aromatic group.

Examples of typical compounds represented by Formulae (i) to (iii) include radically polymerizable compounds selected from acrylic acid esters, methacrylic acid esters, and styrenes.

Furthermore, regarding the examples of the typical compounds represented by Formulae (i) to (iii), reference can be made to the compounds described in paragraphs 0089 to 0093 of JP2013-249417A, the contents of which are incorporated into the present specification.

The content of the hydrophobic structural unit in the polymer compound is preferably within a range of 10% to 90% and more preferably within a range of 20% to 80%, in terms of mass with respect to the total mass of the polymer compound. In a case where the content is within the above-described range, sufficient pattern formability can be obtained.

Functional Group Capable of Forming Interaction with Pigment or the Like

A functional group capable of forming interaction with the pigment or the like (for example, a light shielding pigment) can be introduced into the polymer compound. Herein, it is preferable that the polymer compound further has a structural unit including a functional group capable of forming interaction with the pigment or the like.

Examples of the functional group capable of forming interaction with the pigment or the like include an acid group, a basic group, a coordinating group, and a reactive functional group.

In a case where the polymer compound includes an acid group, a basic group, a coordinating group, or a reactive functional group, it is preferable that the polymer compound has a structural unit including an acid group, a structural unit including a basic group, a structural unit including a coordinating group, or a structural unit including a reactive functional group.

In particular, in a case where the polymer compound further contains, as an acid group, an alkali-soluble group such as a carboxylic acid group, developability for pattern formation by alkali development can be imparted to the polymer compound.

That is, in a case where an alkali-soluble group is introduced into the polymer compound, in the composition, the polymer compound as a dispersant making a contribution to the dispersion of the pigment or the like has alkali solubility. The composition including such a polymer compound is excellent in light shielding properties of a cured film formed by exposure, and improves alkali developability of a non-exposed portion.

Furthermore, in a case where the polymer compound has a structural unit including an acid group, the polymer compound is easily compatible with the solvent, and coating properties also tend to be improved.

It is presumed that this is because the acid group in the structural unit including an acid group easily interacts with the pigment or the like, the polymer compound stably disperses the pigment or the like, the viscosity of the polymer compound dispersing the pigment or the like is reduced, and thus the polymer compound is also easily dispersed in a stable manner.

Here, the structural unit including an alkali-soluble group as an acid group may be the same as or different from the structural unit including a graft chain, but the structural unit including an alkali-soluble group as an acid group is a structural unit different from the hydrophobic structural unit (that is, the structural unit does not correspond to the hydrophobic structural unit).

Examples of the acid group, which is the functional group capable of forming interaction with the pigment or the like, include a carboxylic acid group, a sulfonic acid group, a phosphoric acid group, and a phenolic hydroxyl group, and one or more kinds of the group consisting of a carboxylic acid group, a sulfonic acid group, and a phosphoric acid group is preferable, and a carboxylic acid group is more preferable. The carboxylic acid group has favorable adsorptive power to the pigment or the like and high dispersibility.

That is, it is preferable that the polymer compound further has a structural unit including one or more kinds of the group consisting of a carboxylic acid group, a sulfonic acid group, and a phosphoric acid group.

The polymer compound may have one or more of the structural units including an acid group.

The polymer compound may or may not include the structural unit including an acid group, but in a case where the polymer compound includes the structural unit including an acid group, the content thereof, in terms of mass with respect to the total mass of the polymer compound is preferably 5% to 80% by mass, and more preferably 10% to 60% by mass from the viewpoint of suppressing damage of the image intensity by alkali development.

Examples of the basic group, which is the functional group capable of forming interaction with the pigment or the like, include a primary amino group, a secondary amino group, a tertiary amino group, a hetero ring including a N atom, and an amide group, and a preferred basic group is a tertiary amino group from the viewpoints of favorable adsorptive power to the pigment or the like and high dispersibility. The polymer compound may contain one or more of these basic groups.

The polymer compound may or may not include the structural unit including a basic group, but in a case where the polymer compound includes the structural unit including a basic group, the content thereof, in terms of mass with respect to the total mass of the polymer compound is preferably 0.01% to 50% by mass, and more preferably 0.01% to 30% by mass from the viewpoint of suppressing developability inhibition.

Examples of the coordinating group and the reactive functional group which are the functional groups capable of forming interaction with the pigment or the like include an acetyl acetoxy group, a trialkoxysilyl group, an isocyanate group, an acid anhydride, and an acid chloride. A preferred functional group is an acetyl acetoxy group from the viewpoints of favorable adsorptive power to the pigment or the like and high dispersibility of the pigment or the like. The polymer compound may have one or more of these groups.

The polymer compound may or may not include the structural unit including a coordinating group or the structural unit including a reactive functional group, but in a case where the polymer compound includes the structural unit including a coordinating group or the structural unit including a reactive functional group, the content thereof, in terms of mass with respect to the total mass of the polymer compound is preferably 10% to 80% by mass, and more preferably 20% to 60% by mass from the viewpoint of suppressing developability inhibition.

In a case where the polymer compound includes, other than the graft chain, the functional group capable of forming interaction with the pigment or the like, the functional groups capable of forming interaction with various pigments or the like may be contained, the way these functional groups are introduced is not particularly limited, but it is preferable that the polymer compound contains one or more structural units selected from structural units derived from monomers represented by Formulae (iv) to (vi).

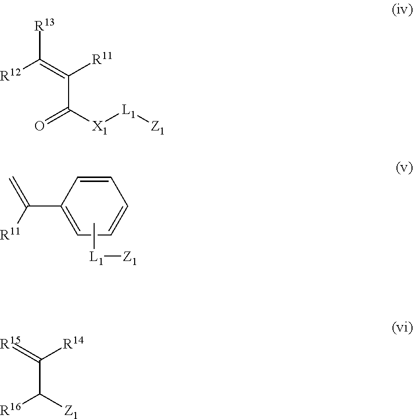

In Formulae (iv) to (vi), R¹¹, R¹², and R¹³ each independently represent a hydrogen atom, a halogen atom (for example, a fluorine atom, a chlorine atom, a bromine atom, or the like), or an alkyl group (for example, a methyl group, an ethyl group, a propyl group, or the like) having 1 to 6 carbon atoms.

In Formulae (iv) to (vi), R¹¹, R¹², and R¹³ are preferably each independently a hydrogen atom or an alkyl group having 1 to 3 carbon atoms, and more preferably each independently a hydrogen atom or a methyl group. In Formula (iv), R¹² and R¹³ are each still more preferably a hydrogen atom.

In Formula (iv), X₁ represents an oxygen atom (—O—) or an imino group (—NH—), and is preferably an oxygen atom.

In addition, in Formula (v), Y represents a methine group or a nitrogen atom.

In addition, in Formulae (iv) and (v), L₁ represents a single bond or a divalent linking group. The divalent linking group has the same definition as the divalent linking group represented by L in Formula (i).

L₁ is preferably a single bond, an alkylene group, or a divalent linking group having an oxyalkylene structure. The oxyalkylene structure is more preferably an oxyethylene structure or an oxypropylene structure. Moreover, L₁ may have a polyoxyalkylene structure which includes two or more repeating oxyalkylene structures. As the polyoxyalkylene structure, a polyoxyethylene structure or a polyoxypropylene structure is preferable. The polyoxyethylene structure is represented by —(OCH₂CH₂)ₙ—, and n is preferably an integer of 2 or more and more preferably an integer of 2 to 10.

In Formulae (iv) to (vi), Z₁ represents a functional group capable of forming interaction with the pigment or the like other than a graft chain, and is preferably a carboxylic acid group and a tertiary amino group and more preferably a carboxylic acid group.

In Formula (vi), R¹⁴, R¹⁵, and R¹⁶ each independently represent a hydrogen atom, a halogen atom (for example, a fluorine atom, a chlorine atom, a bromine atom, or the like), an alkyl group (for example, a methyl group, an ethyl group, a propyl group, or the like) having 1 to 6 carbon atoms, or Herein, L₁ and Z₁ have the same definitions as L₁ and Z₁ described above, and preferred examples thereof are also the same. R¹⁴, R¹⁵, and R¹⁶ are preferably each independently a hydrogen atom or an alkyl group having 1 to 3 carbon atoms, and more preferably each independently a hydrogen atom.

The monomer represented by Formula (iv) is preferably a compound in which R¹¹, R¹², and R¹³ are each independently a hydrogen atom or a methyl group, L₁ is an alkylene group or a divalent linking group having an oxyalkylene structure, X₁ is an oxygen atom or an imino group, and Z₁ is a carboxylic acid group.

In addition, the monomer represented by Formula (v) is preferably a compound in which R¹¹ is a hydrogen atom or a methyl group, L₁ is an alkylene group, Z₁ is a carboxylic acid group, and Y is a methine group.

Furthermore, the monomer represented by Formula (vi) is preferably a compound in which R¹⁴, R¹⁵, and R¹⁶ are each independently a hydrogen atom or a methyl group, and Z₁ is a carboxylic acid group.

Typical examples of the monomers (compounds) represented by Formulae (iv) to (vi) are shown below.

Examples of the monomers include methacrylic acid, crotonic acid, isocrotonic acid, a reaction product of a compound (for example, 2-hydroxyethyl methacrylate) including an addition polymerizable double bond and a hydroxyl group in a molecule with a succinic acid anhydride, a reaction product of a compound containing an addition polymerizable double bond and a hydroxyl group in a molecule with a phthalic acid anhydride, a reaction product of a compound containing an addition polymerizable double bond and a hydroxyl group in a molecule with a tetrahydroxyphthalic acid anhydride, a reaction product of a compound including an addition polymerizable double bond and a hydroxyl group in a molecule with trimellitic acid anhydride, a reaction product of a compound including an addition polymerizable double bond and a hydroxyl group in a molecule with a pyromellitic acid anhydride, acrylic acid, an acrylic acid dimer, an acrylic acid oligomer, maleic acid, itaconic acid, fumaric acid, 4-vinylbenzoic acid, vinyl phenol, and 4-hydroxyphenyl methacrylamide.

From the viewpoint of the interaction with the pigment or the like, the viscosity stability over time, and the permeability into a developer, the content of the structural unit including a functional group capable of forming interaction with the pigment or the like is preferably 0.05% to 90% by mass, more preferably 1.0% to 80% by mass, and still more preferably 10% to 70% by mass with respect to the total mass of the polymer compound.

Other Structural Units

In addition, for the purpose of improving various performances such as image intensity, as long as the effects of the present invention are not impaired, the polymer compound may further have other structural units (for example, a structural unit including a functional group or the like having an affinity with the solvent which will be described later) which have various functions and are different from the structural unit including a graft chain, the hydrophobic structural unit, and the structural unit including a functional group capable of forming interaction with the pigment or the like.

Examples of such other structural units include structural units derived from radically polymerizable compounds selected from acrylonitriles and methacrylonitriles.

The polymer compound may use one or more of these other structural units, and the content thereof is preferably 0% to 80% by mass and more preferably 10% to 60% by mass, in terms of mass with respect to the total mass of the polymer compound. In a case where the content is within the above-described range, sufficient pattern formability is maintained.

Physical Properties of Polymer Compound

An acid value of the polymer compound is preferably 0 to 250 mgKOH/g, more preferably 10 to 200 mgKOH/g, and still more preferably 30 to 180 mgKOH/g.

In a case where the acid value of the polymer compound is 160 mgKOH/g or less, pattern peeling during development of the cured film after exposure is more effectively suppressed. In addition, in a case where the acid value of the polymer compound is 10 mgKOH/g or more, the alkali developability is improved. Furthermore, in a case where the acid value of the polymer compound is 20 mgKOH/g or more, the precipitation of the pigment or the like can be further suppressed, the number of coarse particles can be further reduced, and the viscosity stability over time of the composition can be further improved.

In the present specification, the acid value can be calculated, for example, from the average content of acid groups in the compound. Moreover, a resin having a desired acid value can be obtained by changing the content of the structural unit including an acid group, which is a constituent component of the resin.

In addition, an amine value of the polymer compound is preferably 0 to 250 mgKOH/g, more preferably 10 to 200 mgKOH/g, and still more preferably 10 to 180 mgKOH/g.

In the present specification, the amine value can be calculated, for example, from the average content of substituted or unsubstituted amino groups in the compound. Moreover, a resin having a desired amine value can be obtained by changing the content of the structural unit including a substituted or unsubstituted amino group, which is a constituent component of the resin.

A weight-average molecular weight of the polymer compound is preferably 4,000 to 300,000, more preferably 5,000 to 200,000, still more preferably 6,000 to 100,000, and particularly preferably 10,000 to 50,000.

The polymer compound can be synthesized based on known methods.

Specific examples of the polymer compound include “DA-7301” manufactured by Kusumoto Chemicals, Ltd., “Disperbyk-101 (polyamidoamine phosphate), 107 (carboxylic acid ester), 110 (copolymer including an acid group), 111 (phosphoric acid-based dispersant), 130 (polyamide), 161, 162, 163, 164, 165, 166, 167, 170, and 190 (polymeric copolymer)” and “BYK-P104 and P105 (high-molecular-weight unsaturated polycarboxylic acid)” manufactured by BYK-Chemie GmbH, “EFKA 4047, 4050 to 4010 to 4165 (based on polyurethane), EFKA 4330 to 4340 (block copolymer), 4400 to 4402 (modified polyacrylate), 5010 (polyester amide), 5765 (high-molecular-weight polycarboxylate), 6220 (fatty acid polyester), and 6750 (azo pigment derivative)” manufactured by EFKA, “AJISPER PB821, PB822, PB880, and PB881” manufactured by Ajinomoto Fine-Techno Co., Inc., “FLOWLEN TG-710 (urethane oligomer)” and “POLYFLOW No. 50E and No. 300 (acrylic copolymer)” manufactured by KYOEISHA CHEMICAL Co., LTD., “DISPARLON KS-860, 873SN, 874, #2150 (aliphatic polyvalent carboxylic acid), #7004 (polyether ester), DA-703-50, DA-705, and DA-725” manufactured by Kusumoto Chemicals, Ltd., “DEMOL RN, N (naphthalenesulfonic acid-formalin polycondensate), MS, C, and SN-B (aromatic sulfonic acid-formalin polycondensate)”, “HOMOGENOL L-18 (polymeric polycarboxylic acid)”, “EMULGEN 920, 930, 935, and 985 (polyoxyethylene nonylphenyl ether)”, and “ACETAMIN 86 (stearylamine acetate)” manufactured by Kao Corporation, “22000 (azo pigment derivative), 13240 (polyester amine), 3000, 12000, 17000, 20000, 27000 (polymer including a functional portion on a terminal portion), 24000, 28000, 32000, and 38500 (graft copolymer)” manufactured by Lubrizol Japan Limited, “NIKKOL T106 (polyoxyethylene sorbitan monooleate), and MYS-IEX (polyoxyethylene monostearate)” manufactured by Nikko Chemicals Co., Ltd., HINOACT T-8000E and the like manufactured by Kawaken Fine Chemicals Co., Ltd., an organosiloxane polymer KP341 manufactured by Shin-Etsu Chemical Co., Ltd., “W001: cationic surfactant”, nonionic surfactants such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and a sorbitan fatty acid ester, and anionic surfactants such as “W004, W005, and W017” manufactured by Yusho Co., Ltd., “EFKA-46, EFKA-47, EFKA-47EA, EFKA POLYMER 100, EFKA POLYMER 400, EFKA POLYMER 401, and EFKA POLYMER 450” manufactured by MORISHITA & CO., LTD., polymer dispersants such as “DISPERSE AID 6, DISPERSE AID 8, DISPERSE AID 15, and DISPERSE AID 9100” manufactured by SAN NOPCO LIMITED, “ADEKA PLURONIC (registered trademark) L31, F38, L42, L44, L61, L64, F68, L72, P95, F77, P84, F87, P94, L101, P103, F108, L121, and P-123” manufactured by ADEKA CORPORATION, and “IONET (product name)S-20” manufactured by Sanyo Chemical Industries, Ltd. In addition, ACRYBASE FFS-6752 and ACRYBASE FFS-187 can also be used.

In addition, it is also preferable that an amphoteric resin including an acid group and a basic group is used. The amphoteric resin is preferably a resin having an acid value of 5 mgKOH/g or more and an amine value of 5 mgKOH/g or more.

Examples of a commercial product of the amphoteric resin include DISPERBYK-130, DISPERBYK-140, DISPERBYK-142, DISPERBYK-145, DISPERBYK-180, DISPERBYK-187, DISPERBYK-191, DISPERBYK-2001, DISPERBYK-2010, DISPERBYK-2012, DISPERBYK-2025, and BYK-9076 manufactured by BYK-Chemie GmbH, and AJISPER PB821, AJISPER PB822, and AJISPER PB881 manufactured by Ajinomoto Fine-Techno Co., Inc.

These polymer compounds may be used alone or in combination of two or more thereof.

Furthermore, regarding specific examples of the polymer compound, reference can be made to the polymer compound described in paragraphs 0127 to 0129 of JP2013-249417A, the contents of which are incorporated into the present specification.

In addition, as the dispersant, in addition to the above-described polymer compounds, the graft copolymer described in paragraphs 0037 to 0115 of JP2010-106268A (corresponding to paragraphs 0075 to 0133 of US2011/0124824A) can be used, the contents of which can be incorporated by reference into the present specification.

Moreover, in addition to the above-described dispersant, the polymer compound described in paragraphs 0028 to 0084 of JP2011-153283A (corresponding to paragraphs 0075 to 0133 of US2011/279759A) which includes a constituent component having a side chain structure formed by bonding of acid groups through a linking group can be used, the contents of which can be incorporated by reference into the present specification.

Furthermore, as the dispersant, the resin described in paragraphs 0033 to 0049 of JP2016-109763A can also be used, the contents of which are incorporated into the present specification.

In addition, as the dispersant, a resin having a repeating unit including a polyalkyleneimine structure and a polyester structure (hereinafter, also referred to as a “resin X1”) can also be suitably used. It is preferable that the repeating unit including a polyalkyleneimine structure and a polyester structure includes the polyalkyleneimine structure in a main chain and includes the polyester structure as a graft chain.

The above-described polyalkyleneimine structure is a polymerization structure including two or more identical or different alkyleneimine chains. Specific examples of the alkyleneimine chain include alkyleneimine chains represented by Formulae (4A) and (4B).

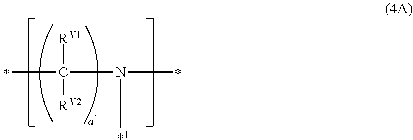

In Formula (4A), R^{X1} and R^{X2}each independently represent a hydrogen atom or an alkyl group. a¹ represents an integer of 2 or more. *¹ represents a bonding position with a polyester chain, an adjacent alkyleneimine chain, or with a hydrogen atom or a substituent.

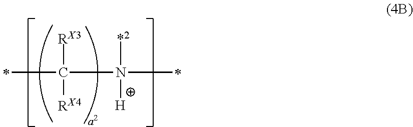

In Formula (4B), R^{X3} and R^{X4} each independently represent a hydrogen atom or an alkyl group. a² represents an integer of 2 or more. The alkyleneimine chain represented by Formula (4B) is bonded to a polyester chain having an anionic group by forming a salt-crosslinked group from N⁺ specified in Formula (4B) and the anionic group included in the polyester chain.

* in Formula (4A) and Formula (4B) and ^{*2} in Formula (4B) each independently represent a position where an adjacent alkyleneimine chain, or a hydrogen atom or a substituent is bonded.

Among them, * in Formula (4A) and Formula (4B) preferably represents a position where an adjacent alkyleneimine chain is bonded.

R^{X1} and R^{X2} in Formula (4A) and R^{X3} and R^{X4} in Formula (4B) each independently represent a hydrogen atom or an alkyl group.

The number of carbon atoms in the alkyl group is preferably 1 to 6 and more preferably 1 to 3.

In Formula (4A), both R^{X1} and R^{X2} are preferably a hydrogen atom.

In Formula (4B), both R^{X3} and R^{X4} are preferably a hydrogen atom.

a¹ in Formula (4A) and a² in Formula (4B) are not particularly limited as long as they are an integer of 2 or more. The upper limit value thereof is preferably 10 or less, more preferably 6 or less, still more preferably 4 or less, even more preferably 2 or 3, and particularly preferably 2.

In Formula (4A) and Formula (4B), * represents a bonding position with an adjacent alkyleneimine chain or with a hydrogen atom or a substituent.

Examples of the above-described substituent include an alkyl group (for example, an alkyl group having 1 to 6 carbon atoms), and a substituent such as an organic group represented by —CO—R^{T}. Examples of the R^{T} include an alkyl group (for example, having 1 to 6 carbon atoms) or alkenyl group (for example, having 2 to 6 carbon atoms) which may be substituted with an acid group (for example, a carboxy group, a sulfo group, a phosphoric acid group, or the like).

In addition, in Formula (4A) and Formula (4B), a polyester chain may be bonded as a substituent at the bonding position represented by *.

The alkyleneimine chain represented by Formula (4A) is preferably linked to the polyester chain at the position of *¹ described above. Specifically, it is preferable that a carbonyl carbon in the polyester chain is bonded at the position of *¹ described above.

Examples of the above-described polyester chain include a polyester chain represented by Formula (5A).

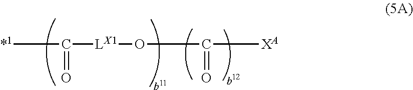

In a case where the alkyleneimine chain is the alkyleneimine chain represented by Formula (4B), it is preferable that the polyester chain includes an anionic group (preferably, oxygen anion O⁻), and this anionic group and N⁺ in Formula (4B) form a salt-crosslinked group.

Examples of such a polyester chain include a polyester chain represented by Formula (5B).

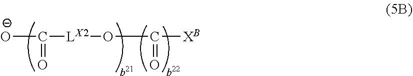

L^{X1} in Formula (5A) and L^{X2} in Formula (5B) each independently represent a divalent linking group. Preferred examples of the divalent linking group include an alkylene group having 3 to 30 carbon atoms.

b¹¹ in Formula (5A) and b²¹ in Formula (5B) each independently represent an integer of 2 or more, preferably an integer of 6 or more, and the upper limit thereof is, for example, 200 or less.

b¹² in Formula (5A) and b²² in Formula (5B) each independently represent 0 or 1.

X^{A} in Formula (5A) and X^{B} in Formula (5B) each independently represent a hydrogen atom or a substituent. Examples of the substituent include an alkyl group, an alkoxy group, a polyalkyleneoxyalkyl group, and an aryl group.

Examples of the number of carbon atoms in the above-described alkyl group (which may be linear, branched, or cyclic) and an alkyl group included in the above-described alkoxy group (which may be linear, branched, or cyclic) include 1 to 30, and 1 to 10 are preferable. In addition, the above-described alkyl group may further have a substituent, and examples of the substituent include a hydroxyl group and a halogen atom (including a fluorine atom, a chlorine atom, a bromine atom, an iodine atom, and the like).

The polyalkyleneoxyalkyl group is a substituent represented by R^{X6}(OR^{X7})ₚ(O)_{q}—. R^{X6} represents an alkyl group, R^{X7} represents an alkylene group, p represents an integer of 2 or more, and q represents 0 or 1.

The alkyl group represented by R^{X6} is synonymous with the alkyl group represented by X^{A}. In addition, examples of the alkylene group represented by R^{X7} include a group obtained by removing one hydrogen atom from the alkyl group represented by X^{A}.

p is an integer of 2 or more, and the upper limit value thereof is, for example, 10 or less, preferably 5 or less.

Examples of the aryl group include an aryl group having 6 to 24 carbon atoms (which may be monocyclic or polycyclic).

The above-described aryl group may further have a substituent, and examples of the substituent include an alkyl group, a halogen atom, and a cyano group.

The above-described polyester chain preferably has a decyclized structure of a lactone such as ε-caprolactone, δ-caprolactone, β-propiolactone, γ-butyrolactone, δ-valerolactone, γ-valerolactone, enantholactone, β-butyrolactone, γ-hexanolactone, γ-octanolactone, δ-hexanolactone, δ-octanolactone, δ-dodecanolactone, α-methyl-γ-butyrolactone, and lactide (which may be an L-form or a D-form), and more preferably has a decyclized structure of ε-caprolactone or δ-valerolactone.

The resin having a repeating unit including a polyalkyleneimine structure and a polyester structure can be synthesized according to the synthesis method described in JP5923557B.

As the resin having a repeating unit including a polyalkyleneimine structure and a polyester structure, reference can be made to a resin having a repeating unit including a polyalkyleneimine structure and a polyester structure, which is described in JP5923557B, the contents of which are incorporated into the present specification.

An acid value of the resin X1 is preferably 10 to 100 mgKOH/g and more preferably 20 to 80 mgKOH/g. An amine value of the resin X1 is preferably 5 mgKOH/g or more, more preferably 20 mgKOH/g or more, and still more preferably 30 mgKOH/g or more. The upper limit value thereof is preferably, for example, 100 mgKOH/g or less.

A weight-average molecular weight of the resin X1 is not particularly limited, but for example, 3,000 or more is preferable, 4,000 or more is more preferable, 5,000 or more is still more preferable, and 6,000 or more is particularly preferable. Moreover, the upper limit value thereof is, for example, preferably 300,000 or less, more preferably 200,000 or less, still more preferably 100,000 or less, and particularly preferably 50,000 or less.

Alkali-Soluble Resin

The composition preferably includes an alkali-soluble resin. In the present specification, the alkali-soluble resin means a resin including a group (an alkali-soluble group, for example, an acid group such as a carboxylic acid group) which promotes alkali solubility, and a resin different from the dispersant described above.

A content of the alkali-soluble resin in the composition is not particularly limited, but is preferably 1.0% to 30% by mass, more preferably 2.0% to 20% by mass, still more preferably 3.0% to 15% by mass, and particularly preferably 4.0% to 15% by mass with respect to the total solid content of the composition.

The alkali-soluble resin may be used singly or in combination of two or more thereof. In a case where two or more alkali-soluble resins are used in combination, the total content thereof is preferably within the above-described range.

As the alkali-soluble resin, a resin including at least one alkali-soluble group in a molecule is mentioned, and examples thereof include a polyhydroxystyrene resin, a polysiloxane resin, a (meth)acrylic resin, a (meth)acrylamide resin, a (meth)acryl/(meth)acrylamide copolymer resin, an epoxy-based resin, and a polyimide resin.

Specific examples of the alkali-soluble resin include a copolymer of an unsaturated carboxylic acid and an ethylenically unsaturated compound.

The unsaturated carboxylic acid is not particularly limited, but examples thereof include monocarboxylic acids such as (meth)acrylic acid, crotonic acid, and vinyl acetate; dicarboxylic acid such as itaconic acid, maleic acid, and fumaric acid or an acid anhydride thereof; and polyvalent carboxylic acid monoesters such as mono(2-(meth)acryloyloxyethyl)phthalate.

Examples of a copolymerizable ethylenically unsaturated compound include methyl (meth)acrylate. Moreover, the compounds described in paragraph 0027 of JP2010-097210A and paragraphs 0036 and 0037 of JP2015-068893A can also be used, the contents of which are incorporated into the present specification.

As the alkali-soluble resin, from the viewpoint that the effects of the present invention are more excellent, an alkali-soluble resin including a curable group is also preferable.

As the curable group, the curable groups which may be included in the above-described polymer compound are also mentioned, and preferred ranges thereof are also the same.

Examples of an aspect of the alkali-soluble resin including a curable group include an acrylic resin including an ethylenically unsaturated group in a side chain. An acrylic resin including an ethylenically unsaturated group in a side chain can be obtained, for example, by addition-reacting a carboxylic acid group of an acrylic resin including the carboxylic acid group with an ethylenically unsaturated compound including a glycidyl group or an alicyclic epoxy group.

The alkali-soluble resin including a curable group is preferably an alkali-soluble resin having a curable group in the side chain, or the like. Examples of the alkali-soluble resin including a curable group include DIANAL NR series (manufactured by Mitsubishi Rayon Co., Ltd.), Photomer 6173 (COOH-containing polyurethane acrylic oligomer, manufactured by Diamond Shamrock Co., Ltd.), VISCOAT R-264 and KS resist 106 (all manufactured by OSAKA ORGANIC CHEMICAL INDUSTRY LTD.), CYCLOMER P series (for example, ACA230AA) and PLACCEL CF200 series (all manufactured by DAICEL CORPORATION), Ebecryl 3800 (manufactured by DAICEL-ALLNEX LTD.), and ACRYCURE RD-F8 (manufactured by NIPPON SHOKUBAI CO., LTD.).

As the alkali-soluble resin, for example, the radical polymers which include a carboxylic acid group in a side chain and are described in JP1984-044615A (JP-S59-044615A), JP1979-34327B (JP-S54-34327B), JP1983-012577B (JP-558-012577B), JP1979-025957B (JP-554-025957B), JP1979-092723A (JP-S54-092723A), JP1984-053836A (JP-559-053836A), and JP1984-071048A (JP-559-071048A); the acetal-modified polyvinyl alcohol-based binder resins which include an alkali-soluble group and are described in EP993966B, EP1204000B, and JP2001-318463A; polyvinyl pyrrolidone; polyethylene oxide; polyether or the like which is a reaction product of alcohol-soluble nylon, 2,2-bis-(4-hydroxyphenyl)-propane, and epichlorohydrin; the polyimide resin described in WO2008/123097A; and the like can be used.

As the alkali-soluble resin, for example, the compound described in paragraphs 0225 to 0245 of JP2016-075845A can also be used, the contents of which are incorporated into the present specification.

As the alkali-soluble resin, a polyimide precursor can also be used. The polyimide precursor means a resin obtained by causing an addition polymerization reaction between a compound including an acid anhydride group and a diamine compound at a temperature of 40° C. to 100° C.

Examples of the polyimide precursor include a resin having a repeating unit represented by Formula (1). Examples of the structure of the polyimide precursor include polyimide precursors including an amic acid structure represented by Formula (2), and imide structures represented by Formula (3) obtained in a case where imide ring closure occurs in a portion of an amic acid structure and Formula (4) obtained in a case where imide ring closure occurs in the entirety of an amic acid structure.

Furthermore, in the present specification, the polyimide precursor having an amic acid structure is referred to as polyamic acid in some cases.

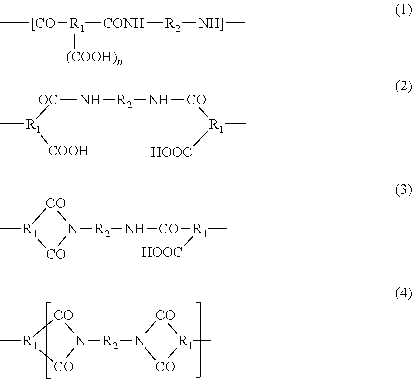

In Formulae (1) to (4), R₁ represents a tetravalent organic group having 2 to 22 carbon atoms, R₂ represents a divalent organic group having 1 to 22 carbon atoms, and n represents 1 or 2.

Specific examples of the polyimide precursor include the compound described in paragraphs 0011 to 0031 of JP2008-106250A, the compound described in paragraphs 0022 to 0039 of JP2016-122101A, and the compound described in paragraphs 0061 to 0092 of JP2016-068401A, the contents of which are incorporated into the present specification.

From the viewpoint that the shape of the pattern formed of the composition is more excellent, the alkali-soluble resin preferably includes one or more kinds selected from the group consisting of a polyimide resin and a polyimide precursor.

The polyimide resin including an alkali-soluble group is not particularly limited, and known polyimide resins including an alkali-soluble group can be used. Examples of the polyimide resin include the resin described in paragraph 0050 of JP2014-137523A, the resin described in paragraph 0058 of JP2015-187676A, and the resin described in paragraphs 0012 and 0013 of JP2014-106326A, the contents of which are incorporated into the present specification.

Organic Particles or Metal Oxide Particles Different from Carbon Black (Particles A)

The composition may further include, as particles other than the carbon black and barium sulfate described above, one or more kinds of particles selected from the group consisting of organic particles different from the carbon black and metal oxide particles (hereinafter, also referred to as “particles A”).

In a case where the composition includes the particles A, light scattering is likely to occur due to a formation of irregularities on a surface of the pattern formed from the composition, and as a result, the pattern may have lower reflection properties. Moreover, in a case where the composition includes the particles A, the undercut of the pattern can be more suppressed.

As the above-described organic particles, resin particles are preferable.

A resin constituting the resin particles is not particularly limited, and examples thereof include an acrylic resin, an epoxy resin, a melamine resin, a urea resin, an unsaturated polyester resin, an alkyd resin, a urethane resin, and an aramid resin. Among these, from the viewpoint that the effects of the present invention are more excellent, an acrylic resin or a phenol resin is preferable, and a phenol resin is more preferable. That is, the organic particles are preferably acrylic resin particles or phenol resin particles, and more preferably phenol resin particles.

In addition, a metal oxide constituting the metal oxide particles is not particularly limited, examples thereof include silica, titania, alumina, tin oxide, zirconia, zinc oxide, and antimony oxide, and silica is preferable. That is, the metal oxide particles are preferably silica particles.

Among these, from the viewpoint that the effects of the present invention are more excellent, it is preferable that the composition include, as the particles A, one or more particles selected from the group consisting of acrylic resin particles, phenol resin particles, and silica particles.

An average particle diameter of the particles A is preferably 0.1 to 10 more preferably 0.3 to 8 μm, and still more preferably 0.5 to 6 μm.

The average particle diameter of the particles A is a catalog value, or is a value of an arithmetic mean diameter by electron microscope observation in a case where there is no catalog value.

In a case where the composition includes the particles A, a content of the particles A is preferably 5.0% by mass or more, more preferably 8.0% by mass or more, and still more preferably 10% by mass or more with respect to the total solid content of the composition. The upper limit thereof is preferably 40% by mass or less, more preferably 30% by mass or less, and still more preferably 25% by mass or less with respect to the total solid content of the composition.

One kind of the particles A may be used singly, or two or more kinds thereof may be used. In a case where two or more particles A are used in combination, the total content thereof is preferably within the above-described range.

Pigment

The composition may further include a pigment other than the carbon black and the barium sulfate described above. The pigment referred to here is preferably different from the organic particles and the metal oxide particles, which correspond to the above-described particles A.

Black Pigment

Examples of the above-described pigment include black pigments other than the carbon black.

As the black pigment, various known black pigments can be used. The black pigment may be an inorganic pigment or an organic pigment.

Examples of the black inorganic pigment include a metal oxide, a metal nitride, and a metal oxynitride which include a metallic element of group 4 such as titanium (Ti) and zirconium (Zr), a metallic element of group 5 such as vanadium (V) and niobium (Nb), or one or more metallic elements selected from the group consisting of cobalt (Co), chromium (Cr), copper (Cu), manganese (Mn), ruthenium (Ru), iron (Fe), nickel (Ni), tin (Sn), and silver (Ag).

The inorganic pigment may be subjected to a surface modification treatment. For example, inorganic particles, which are subjected to a surface modification treatment with a surface-treating agent having both a silicone group and an alkyl group, are mentioned, and examples thereof include “KTP-09” series (manufactured by Shin-Etsu Chemical Co., Ltd.). Moreover, the metal oxide, the metal nitride, and the metal oxynitride may be used as particles in which other atoms are further mixed. For example, the metal oxide, the metal nitride, and the metal oxynitride may be used as a metal oxide, a metal nitride, and a metal oxynitride which further include an atom (preferably, a sulfur atom) selected from the group consisting of elements of groups 13 to 17 of the periodic table.

Among them, as the black pigment, it is preferable to include one or more kinds of particles (hereinafter, also referred to as “particles B”) selected from the group consisting of a metal nitride and a metal oxynitride.

The above-described particles B are preferably a nitride or oxynitride of a metallic element of group 4, or a nitride or oxynitride of a metallic element of group 5, and more preferably a nitride or oxynitride of titanium, a nitride or oxynitride of zirconium, a nitride or oxynitride of vanadium, or a nitride or oxynitride of niobium.

Furthermore, the nitride of titanium is titanium nitride, the nitride of zirconium is zirconium nitride, the nitride of vanadium is vanadium nitride, and the nitride of niobium is niobium nitride. In addition, the oxynitride of titanium is titanium oxynitride, the oxynitride of zirconium is zirconium oxynitride, the oxynitride of vanadium is vanadium oxynitride, and the oxynitride of niobium is niobium oxynitride.

In a case where the composition includes the particles B as the black pigment, a content of the particles B is, for example, preferably 0.1% to 30% by mass, more preferably 3.0% to 25% by mass, and particularly preferably 3.0% to 20% by mass with respect to the total solid content of the composition.

One kind of the particles B may be used singly, or two or more kinds thereof may be used. In a case where two or more particles B are used in combination, the total content thereof is preferably within the above-described range.

The black pigment is preferably a pigment as fine as possible. Even considering handleability, an average primary particle diameter of the black pigment is preferably 0.01 to 0.1 μm and more preferably 0.01 to 0.05 μm.

In addition, in the present specification, the titanium nitride means TiN, and may include an oxygen atom (for example, the surfaces of TiN particles are unintentionally oxidized, or the like) which is unavoidable in production.

In the present specification, the titanium nitride means a compound in which a diffraction angle 2θ of a peak derived from a (200) plane in a case where Cuka rays are used as an X-ray source is 42.5° to 42.8°.

In addition, in the present specification, the titanium oxynitride means a compound in which the diffraction angle 2θ of the peak derived from the (200) plane in a case where the Cuka rays are used as an X-ray source is more than 42.8°. The upper limit value of the diffraction angle 2θ of the titanium oxynitride is not particularly limited, but is preferably 43.5° or less.

Examples of the titanium oxynitride include titanium black, and more specifically, for example, an aspect in which lower titanium oxide represented by TiO₂ or TiₙO₂ₙ₋₁ (1≤n≤20) and/or a titanium oxynitride represented by TiNₓO_{y} (0<x<2.0 and 0.1<y<2.0) is included can be mentioned. In the following description, the titanium nitride (the diffraction angle 2θ is 42.5° to 42.8°) and the titanium oxynitride (the diffraction angle 2θ is greater than 42.8°) are collectively referred to as a titanium nitride, and an aspect thereof will be described.

Furthermore, the titanium nitride may be used as particles in which other atoms are further mixed. For example, the titanium nitride may be used as titanium nitride-containing particles which further include an atom (preferably, a sulfur atom) selected from the group consisting of elements of groups 13 to 17 of the periodic table. In addition, the same applies to other metal nitrides, and the metal nitride, which refers to both the metal nitride and the metal oxynitride, may be used as particles in which other atoms are further mixed. For example, the metal nitride may be used as a metal nitride which further includes an atom (preferably, a sulfur atom) selected from the group consisting of elements of groups 13 to 17 of the periodic table.

In a case where the X-ray diffraction spectrum of the titanium nitride is measured using the Cuka rays as an X-ray source, as a peak with the highest intensity, for TiN, a peak derived from the (200) plane is observed near 20 of 42.5°, and for TiO, a peak derived from the (200) plane is observed near 20 of 43.4°. Meanwhile, although the peak is not a peak with the highest intensity, for anatase-type TiO₂, a peak derived from the (200) plane is observed near 20 of 48.1°, and for rutile-type TiO₂, a peak derived from the (200) plane is observed near 2θ of 39.2°. Therefore, as the titanium oxynitride includes more oxygen atoms, the peak position shifts to a side of an angle of 42.5° or more.

In a case where the titanium nitride includes titanium oxide TiO₂, as a peak with the highest intensity, a peak derived from anatase-type TiO₂ (101) is found near 20 of 25.3°, and a peak derived from rutile-type TiO₂ (110) is found near 20 of 27.4°. However, TiO₂ is white and is a factor which causes deterioration of light shielding properties of a light shielding film formed of the composition, and thus it is preferable that TiO₂ is reduced to such an extent that TiO₂ is not observed as a peak.

A size of a crystallite constituting the titanium nitride can be determined from a half-width of the peak obtained by the measurement of the X-ray diffraction spectrum. The crystallite size can be calculated using the Scherrer equation.

The size of the crystallite constituting the titanium nitride is preferably 50 nm or less, and is preferably 20 nm or more. In a case where the crystallite size is 20 to 50 nm, it is likely to have a higher transmittance of an ultraviolet ray (particularly, an i-line (wavelength of 365 nm)), and a composition having higher photosensitivity can be obtained.

A specific surface area of the titanium nitride is not particularly limited, but is determined by the Brunauer-Emmett-Teller (BET) method. The specific surface area of the titanium nitride is preferably 5 to 100 m²/g and more preferably 10 to 60 m²/g.

A method for producing the black pigment is not particularly limited, known production methods can be used, and examples thereof include a gas-phase reaction method. Examples of the gas-phase reaction method include an electric furnace method and a thermal plasma method, but from the viewpoints that few impurities are mixed in, particle diameters are easily uniform, and productivity is high, a thermal plasma method is preferable.

In the thermal plasma method, the method for generating thermal plasma is not particularly limited, examples thereof include direct-current arc discharge, multi-layer arc discharge, radio-frequency (RF) plasma, and hybrid plasma, and a radio-frequency plasma in which few impurities are mixed in from an electrode is more preferable.

A specific method for producing the black pigment by the thermal plasma method is not particularly limited, but for example, as a method for producing the titanium nitride, a method (JP1990-022110A (JP-H2-022110A)) for reacting titanium tetrachloride with an ammonia gas in a plasma flame, a method (JP1986-011140A (JP-S61-011140A)) for performing synthesis by evaporating a titanium powder by radio-frequency thermal plasma, introducing nitrogen as a carrier gas, and performing nitriding in a cooling process, a method (JP1988-085007A (JP-S63-085007A)) for blowing an ammonia gas into a peripheral portion of plasma, and the like can be mentioned.

Here, the method for producing the black pigment is not limited to the above-described method, and the production method is not limited as long as a black pigment having desired physical properties is obtained.

The black pigment may include, on the surface thereof, a layer of a compound (hereinafter, referred to as a “silicon-containing compound”) including silicon. That is, the black pigment may be a black pigment obtained by coating the (oxy)nitride of the metallic atom with the silicon-containing compound.

A method for coating the (oxy)nitride of the metallic atom is not particularly limited, known methods can be used, and examples thereof include the method (the (oxy)nitride of the metallic atom is used instead of the titanium oxide) described on page 2, lower right to page 4, upper right in JP1978-033228A (JP-S53-033228A), the method (the (oxy)nitride of the metallic atom is used instead of the fine titanium dioxide particles) described in paragraphs 0015 to 0043 of JP2008-069193A, and the method (the (oxy)nitride of the metallic atom is used instead of the fine metal oxide particles) described in paragraphs 0020 and 0124 to 0138 of JP2016-074870A, the contents of which are incorporated into the present specification.

The black pigment may be used singly or in combination of two or more thereof.

Other Pigments

The pigment may be another pigment other than the black pigment, and the other pigment may be an inorganic pigment or an organic pigment. However, the pigment is a pigment other than the carbon black, the barium sulfate, the particles A, and the particles B described above.

Inorganic Pigment

The inorganic pigment is not particularly limited, and known inorganic pigments can be used.

Examples of the inorganic pigment include zinc oxide, white lead, lithopone, titanium oxide, chromium oxide, iron oxide, red lead, red iron oxide, chrome yellow, zinc yellow (zinc yellow type 1 and zinc yellow type 2), ultramarine blue, Prussian blue (potassium ferric ferrocyanide), zircon grey, Praseodymium yellow, chromium titanium yellow, chrome green, peacock, Victoria green, iron blue (irrelevant to Prussian blue), vanadium zirconium blue, chrome tin pink, manganese pink, and salmon pink.

The inorganic pigment may be subjected to a surface modification treatment. For example, an inorganic pigment, which is subjected to a surface modification treatment with a surface-treating agent having both a silicone group and an alkyl group, is mentioned, and examples thereof include “KTP-09” series (manufactured by Shin-Etsu Chemical Co., Ltd.).

A pigment having infrared-absorbing properties can also be used.

As the pigment having infrared-absorbing properties, a tungsten compound, a metal boride, and the like are preferable. Among them, from the viewpoint that light shielding properties at a wavelength in an infrared range are excellent, a tungsten compound is preferable.

These pigments may be used in combination of two or more thereof, and may be used in combination with a dye which will be described later. In order to adjust tint and to enhance light shielding properties in a desired wavelength range, for example, an aspect in which a dye described later or a pigment which has a chromatic color such as red, green, yellow, orange, violet, and blue is mixed with a pigment which is black or has infrared ray-shielding properties can be mentioned. It is preferable that a red pigment or dye or a violet pigment or dye is mixed with the pigment having infrared ray-shielding properties, and more preferable that a red pigment is mixed with a pigment having infrared ray-shielding properties.

Furthermore, an infrared absorber will be described later may be added.

(Organic Pigment)

Examples of organic pigments include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like;

C. I. Pigment Orange 2, 5, 13, 16, 17:1, 31, 34, 36, 38, 43, 46, 48, 49, 51, 52, 55, 59, 60, 61, 62, 64, 71, 73, and the like;

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and the like;

C. I. Pigment Green 10, 37, 58, 59, and the like;

C. I. Pigment Violet 1, 19, 23, 27, 32, 37, 42, and the like; and C. I. Pigment Blue 1, 2, 16, 22, 60, 64, 66, 79, 80, and the like. Furthermore, the pigment may be used singly or in combination of two or more thereof.

Dye

As a coloring dye, for example, the colorant described in paragraphs 0027 to 0200 of JP2014-042375A can also be used in addition to a dye (chromatic dye) having a chromatic color such as red (R), green (G), and blue (B). In addition, a black dye can be used.

As the dye, for example, the coloring agents disclosed in JP1989-090403A (JP-S64-090403A), JP1989-091102A (JP-S64-091102A), JP1989-094301A (JP-H01-094301A), JP1994-011614A (JP-H06-011614A), JP2592207B, U.S. Pat. No. 4,808,501A, US505950A, U.S. Pat. No. 5,667,920A, JP1993-333207A (JP-H5-333207A), JP1994-035183A (JP-H6-035183A), JP1994-051115A (JP-H06-051115A), JP1994-194828A (JP-H06-194828A), and the like can be used. In a case where the dyes are sorted based on the chemical structure, a pyrazole azo compound, a pyrromethene compound, an anilinoazo compound, a triphenylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, or the like can be used. In addition, a coloring agent multimer may be used as the dye. Examples of the coloring agent multimer include the compounds described in JP2011-213925A and JP2013-041097A. Furthermore, a polymerizable dye having a polymerizable group in a molecule may be used, and examples of a commercial product thereof include RDW series manufactured by FUJIFILM Wako Pure Chemical Corporation.

Ultraviolet Absorber

The composition may include an ultraviolet absorber. As a result, the shape of the pattern formed of the composition can be made into a more excellent (fine) shape.

As the ultraviolet absorber, salicylate-based, benzophenone-based, benzotriazole-based, substituted acrylonitrile-based, and triazine-based ultraviolet absorbers can be used. As specific examples thereof, the compound described in paragraphs 0137 to 0142 of JP2012-068418A (corresponding to paragraphs 0251 to 0254 of US2012/0068292A) can be used, the contents of which can be incorporated by reference into the present specification.

In addition to the above-described compounds, a diethylamino-phenylsulfonyl-based ultraviolet absorber (manufactured by DAITO CHEMICAL CO., LTD., trade name UV-503) or the like is also suitably used.

Examples of the ultraviolet absorber include the compounds exemplified in paragraphs 0134 to 0148 of JP2012-032556A.

In a case where the composition includes the ultraviolet absorber, a content of the ultraviolet absorber is preferably 0.001% to 15% by mass, more preferably 0.01% to 10% by mass, and still more preferably 0.1% to 5% by mass with respect to the total solid content of the composition.

Silane Coupling Agent (Adhesive Agent)

The composition may include a silane coupling agent.

The silane coupling agent functions as an adhesive agent which improves adhesiveness between a substrate and a cured film in a case where the cured film is formed on the substrate.

The silane coupling agent is a compound including a hydrolyzable group and other functional groups in a molecule. In addition, the hydrolyzable group such as an alkoxy group is bonded to the silicon atom.

The hydrolyzable group refers to a substituent which is directly bonded to a silicon atom and can form a siloxane bond by a hydrolysis reaction and/or a condensation reaction. Examples of the hydrolyzable group include a halogen atom, an alkoxy group, an acyloxy group, and an alkenyloxy group. In a case where the hydrolyzable group includes a carbon atom, the number of carbon atoms is preferably 6 or less and more preferably 4 or less. In particular, an alkoxy group having 4 or less carbon atoms or an alkenyloxy group having 4 or less carbon atoms is preferable.

Furthermore, in a case where a cured film is formed on a substrate, in order to improve adhesiveness between the substrate and the cured film, the silane coupling agent preferably does not include a fluorine atom and a silicon atom (here, a silicon atom to which a hydrolyzable group is bonded is excluded), and desirably does not include a fluorine atom, a silicon atom (here, a silicon atom to which a hydrolyzable group is bonded is excluded), an alkylene group substituted with a silicon atom, a linear alkyl group having 8 or more carbon atoms, and a branched alkyl group having 3 or more carbon atoms.

The silane coupling agent may include a ring-curable group such as an epoxy group and an oxetanyl group. In a case of including the ring-curable group such as an epoxy group and an oxetanyl group, the number thereof is preferably 1 to 10 and more preferably 1 to 4. The silane coupling agent including the ring-curable group such as an epoxy group and an oxetanyl group (for example, compound which includes a hydrolyzable group including a silicon atom and an epoxy group) does not correspond to the above-described specific crosslinking agent.

A content of the silane coupling agent in the composition is preferably 0.1% to 10% by mass, more preferably 0.5% to 8.0% by mass, and still more preferably 1.0% to 6.0% by mass with respect to the total solid content in the composition.

The composition may include one silane coupling agent singly or two or more silane coupling agents. In a case where the composition includes two or more silane coupling agents, the total amount thereof may be within the above-described range.

Examples of the silane coupling agent include 3-glycidoxypropyl trimethoxysilane, 3-glycidoxypropyl triethoxysilane, 3-glycidoxypropyl methyldimethoxysilane, and 3-glycidoxypropyl methyldiethoxysilane.

Surfactant

The composition may include a surfactant. The surfactant contributes to improvement in coating properties of the composition.

In a case where the composition includes a surfactant, a content of the surfactant is preferably 0.001% to 2.0% by mass, more preferably 0.005% to 0.5% by mass, and still more preferably 0.01% to 0.1% by mass with respect to the total solid content of the composition.

The surfactant may be used alone or in combination of two or more thereof. In a case where two or more surfactants are used in combination, the total amount thereof is preferably within the above-described range.

Examples of the surfactant include a fluorine-based surfactant, a silicone-based surfactant, a nonionic surfactant, a cationic surfactant, and an anionic surfactant.

From the viewpoint that the effects of the present invention are more excellent, the surfactant preferably includes a silicone-based surfactant or a fluorine-based surfactant, and more preferably includes a fluorine-based surfactant.

In a case where the composition includes a fluorine-based surfactant, liquid properties (particularly, fluidity) of the composition are further improved. That is, in a case of forming a film using the composition containing a fluorine-based surfactant, the interfacial tension between a coated surface and a coating liquid decreases, the wettability on the coated surface is improved, and applicability to the coated surface is improved. Therefore, even in a case where a thin film having a thickness of approximately several micrometers is formed with a small amount of a liquid, the fluorine-based surfactant is effective from the viewpoint that a film having a uniform thickness and small thickness unevenness is more suitably formed.

A fluorine content in the fluorine-based surfactant is preferably 3% to 40% by mass, more preferably 5% to 30% by mass, and still more preferably 7% to 25% by mass. The fluorine-based surfactant in which the fluorine content is within the above-described range is effective from the viewpoint of the uniformity in the thickness of the coating film and/or liquid saving properties, and the solubility in the composition is also excellent.

Moreover, as the fluorine-based surfactant, it is preferable to include a C₆F₁₃ group in terms of excellent coating uniformity.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, and MEGAFACE F780 (all manufactured by DIC Corporation), FLUORAD FC430, FLUORAD FC431, and FLUORAD FC171 (all manufactured by Sumitomo 3M Limited), SURFLON S-382, SURFLON SC-101, SURFLON SC-103, SURFLON SC-104, SURFLON SC-105, SURFLON SC1068, SURFLON SC-381, SURFLON SC-383, SURFLON 5393, and SURFLON KH-40 (all manufactured by ASAHI GLASS CO., LTD.), and PF636, PF656, PF6320, PF6520, and PF7002 (manufactured by OMNOVA Solutions Inc.).

As the fluorine-based surfactant, a block polymer can also be used, and specific examples thereof include the compound described in JP2011-089090A.

Solvent

The composition preferably includes a solvent.

The solvent is not particularly limited, and a known solvent can be used.

A solid content of the composition is preferably 10% to 90% by mass, more preferably 10% to 45% by mass, and still more preferably 15% to 35% by mass with respect to the total mass of the composition. That is, the content of the solvent in the composition is not particularly limited, but it is preferable that the solid content of the composition is adjusted to the above-described content.

The solvent may be used singly or in combination of two or more thereof. In a case where two or more kinds of solvents are used in combination, the content thereof is preferably adjusted so that the total solid content of the composition is within the above-described range.

Examples of the solvent include water and an organic solvent.

Organic Solvent

Specific examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxyethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, y-butyrolactone, butyl acetate, methyl lactate, N-methyl-2-pyrrolidone, and ethyl lactate, but the organic solvent is not limited thereto.

Water

In a case where the composition contains water, a content thereof is preferably 0.001% to 5.0% by mass, more preferably 0.01% to 3.0% by mass, and still more preferably 0.1% to 1.0% by mass with respect to the total mass of the composition. In particular, in a case where the content of the water is 3.0% by mass or less (more preferably 1.0% by mass or less) with respect to the total mass of the composition, deterioration of the viscosity stability over time due to hydrolysis or the like of the components in the composition is easily suppressed, and in a case where the content is 0.01% by mass or more (preferably 0.1% by mass or more), precipitation stability over time is easily improved.

Other Optional Components

The composition may further contain any component other than the above-described components. Examples thereof include a sensitizer, a co-sensitizer, a curing accelerator, a filler, a heat curing accelerator, a plasticizer, a diluent, and an oil sensitizing agent, and known additives such as an adhesion promoter to the surface of the substrate and other auxiliaries (for example, conductive particles, a filling agent, an anti-foaming agent, a flame retardant, a leveling agent, a peeling accelerator, an antioxidant, a fragrance, a surface tension adjuster, a chain transfer agent, and the like) may be added as necessary.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the specification of the present application.

Method for Producing Composition

The composition is preferably obtained by first producing a dispersion composition in which carbon black is dispersed, and further mixing the obtained dispersion composition with other components.

The dispersion composition is preferably prepared by mixing carbon black, barium sulfate, copper phthalocyanines, particles B, a resin (preferably, a dispersant), and a solvent.

The dispersion composition can be prepared by mixing the respective components described above by known mixing methods (for example, mixing methods using a stirrer, a homogenizer, a high-pressure emulsification device, a wet-type pulverizer, a wet-type disperser, or the like).

After preparing the dispersion composition, the composition can be prepared by mixing the above-described dispersion composition, the resin (preferably, an alkali-soluble resin), the photoacid generator, the specific crosslinking agent, the particles A, solvents, and the like.

In a case of preparing the composition, the respective components may be formulated at once, or each of the components may be dissolved or dispersed in a solvent and then sequentially formulated. In addition, the input order and the operation conditions during the formulation are not particularly limited.

For the purpose of removing foreign substances, reducing defects, and the like, the composition is preferably filtered with a filter. The filter can be used without particular limitation as long as the filter has been used in the related art in a filtration application or the like. Examples of the filter include filters made of a fluororesin such as polytetrafluoroethylene (PTFE), a polyamide-based resin such as nylon, a polyolefin-based resin (having a high density and an ultrahigh molecular weight) such as polyethylene and polypropylene (PP), or the like. Among these materials, polypropylene (including high-density polypropylene) and nylon are preferable.

A pore diameter of the filter is preferably 0.1 to 7.0 μm, more preferably 0.2 to 2.5 μm, still more preferably 0.2 to 1.5 μm, and particularly preferably 0.3 to 0.7 μm. In a case where the pore diameter is within the above-described range, it is possible to reliably remove fine foreign substances such as impurities and aggregates included in a pigment while suppressing filtration clogging of the pigment (including a light shielding pigment).

In a case of using a filter, different filters may be combined. In this case, filtering with a first filter may be performed only once, or may be performed twice or more times. In a case where filtering is performed twice or more times with a combination of different filters, the pore diameters of the filters used in the second and subsequent filtering are preferably the same as or larger than the pore diameter of the filter used in the first filtering. In addition, the first filters having different pore diameters within the above range may be combined. Regarding the pore diameter mentioned here, reference can be made to nominal values of filter manufacturers. A commercial filter can be selected from various filters provided by, for example, Nihon Pall Ltd., Advantec Toyo Kaisha, Ltd., Nihon Entegris K. K. (formerly Nippon Microlith Co., Ltd.), Kitz Micro Filter Corporation, and the like.

As a second filter, a filter formed of the same material as that of the first filter, or the like can be used. A pore diameter of the second filter is preferably 0.2 to 10.0 μm, more preferably 0.2 to 7.0 μm, and still more preferably 0.3 to 6.0 μm.

The composition preferably does not include impurities such as a metal, a halogen-containing metal salt, an acid, and an alkali. A content of impurities included in these materials is preferably 1 ppm or less, more preferably 1 ppb or less, still more preferably 100 ppt or less, and particularly preferably 10 ppt or less, and it is most preferable that the impurities are substantially not included (the content is equal to or less than the detection limit of the measuring device).

Furthermore, the impurities can be measured using an inductively coupled plasma mass spectrometer (manufactured by Agilent Technologies, Inc., Agilent 7500cs model).

Method for Manufacturing Cured Film

A method for manufacturing a cured film preferably includes the following steps. By going through the following steps, a patterned cured film can be formed.
Composition layer forming step
Exposure step
Development step Hereinafter, each of the steps will be described.

Composition Layer Forming Step

In the composition layer forming step, prior to exposure, the composition is applied on a support or the like to form a layer (composition layer) of the composition. As the support, for example, a substrate for a solid-state imaging element, in which an imaging element (light-receiving element) such as a charge coupled device (CCD) or a complementary metal-oxide semiconductor (CMOS) is provided on a substrate (for example, a silicon substrate), can be used. In addition, in order to improve adhesion with the upper layer, prevent the diffusion of substances, and planarize the surface of the substrate, an undercoat layer may be provided on the support, as needed.

As a method for applying the composition onto the support, various coating methods such as a slit coating method, an ink jet method, a spin coating method, a cast coating method, a roll coating method, and a screen printing method can be applied. The film thickness of the composition layer is preferably 0.1 to 10 μm, more preferably 0.2 to 5.0 μm, and still more preferably 0.2 to 3.0 μm. The composition layer applied on the support can be dried (pre-baked) at a temperature of 50° C. to 140° C. for 10 to 300 seconds using a hot plate, an oven, or the like.

Exposure Step

The exposure step is a step of exposing the composition layer formed in the composition layer forming step by irradiating the composition layer with actinic rays or radiations. Specifically, the exposure step is a step of exposing the composition layer formed in the composition layer forming step by irradiating the composition layer with actinic rays or radiations to cure a light irradiation region of the composition layer.

The method of light irradiation is not particularly limited, but light irradiation is preferably performed through a photo mask having a pattern-like opening portion.

The exposure is preferably performed by irradiation with radiation, ultraviolet rays such as a g-line, an h-line, and an i-line are particularly preferable as the radiations which can be used during the exposure, and a high-pressure mercury lamp is preferable as a light source. The irradiation intensity is preferably 5 to 1,500 mJ/cm² and more preferably 10 to 1000 mJ/cm².

In addition, it is also preferable to heat the composition layer in the above-described exposure step. A heating temperature is not particularly limited, but is preferably 80° C. to 250° C. A heating time is not particularly limited, but is preferably 30 to 300 seconds.

Furthermore, in a case where the composition layer is heated in the exposure step, the exposure step may serve as a post-heating step which will be described later. In other words, in a case where the composition layer is heated in the exposure step, the method for manufacturing a cured film may not include the post-heating step.

Development Step

The development step is a step of performing a development treatment on the composition layer after the exposure. By this step, the composition layer in the light exposed region in the exposure step is eluted, and only the photocured portion remains. For example, in a case where the light irradiation is performed through a photo mask having a pattern-like opening portion in the exposure step, a patterned cured film is obtained.

A type of a developer used in the development step is not particularly limited, but an alkaline developer which does not damage the underlying imaging element and circuit or the like is desirable.

The development temperature is 20° C. to 30° C., for example.

The development time is 20 to 90 seconds, for example. In order to further remove the residues, in recent years, the development may be performed for 120 to 180 seconds. Furthermore, in order to improve residue removability, a step of shaking off the developer every 60 seconds and further supplying a fresh developer may be repeated several times.

The alkaline developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, organic alkalis are preferable.).

Furthermore, in a case where the alkaline compound is used as an alkali developer, the alkaline compound is generally subjected to a washing treatment with water after development.

Post-Baking

A heating treatment (post-baking) is preferably performed after the exposure step. The post-baking is a heating treatment to complete the curing. The heating temperature is preferably 240° C. or lower and more preferably 220° C. or lower. The lower limit thereof is not particularly limited, but is preferably 50° C. or higher and more preferably 100° C. or higher, in consideration of an efficient and effective treatment.

The post-baking can be performed continuously or batchwise by using a heating unit such as a hot plate, a convection oven (hot-air circulating dryer), and a radio-frequency heater.

The post-baking is performed after the exposure step, and more preferably after the development treatment.

In addition, the curing may be completed by irradiation with ultraviolet rays (UV) instead of the post-baking by heating.

In this case, it is preferable that the above-described composition further includes a UV curing agent. The UV curing agent is preferably a UV curing agent which can be cured at a wavelength shorter than 365 nm that is an exposure wavelength of a polymerization initiator added for a lithography step by ordinary i-line exposure. Examples of the UV curing agent include CIBA IRGACURE 2959 (trade name). In a case where UV irradiation is performed, the composition layer is preferably a material which is cured at a wavelength of 340 nm or less. The lower limit value of the wavelength is not particularly limited, but is generally 220 nm or more. In addition, an exposure amount of the UV irradiation is preferably 100 to 5000 mJ, more preferably 300 to 4000 mJ, and still more preferably 800 to 3500 mJ. The UV curing step is preferably performed after the lithography step because low-temperature curing is more effectively performed. As an exposure light source, an ozoneless mercury lamp is preferably used.

Physical Properties of Cured Film and Application of Cured Film

Physical properties of cured film From the viewpoint that excellent light shielding properties are exhibited, in a cured film obtained by using the composition according to the embodiment of the present invention, the OD value per film thickness of 2.0 μm in a wavelength range of 400 to 1100 nm is preferably 3.0 or more and more preferably 3.5 or more. In addition, the upper limit value thereof is not particularly limited, but is preferably 10 or less, in general. The cured film can be preferably used as a light shielding film. The above-described OD value per film thickness of 2.0 μm in a wavelength range of 400 to 1100 nm is intended to be an OD value obtained based on a wavelength having the highest transmittance in the wavelength range of 400 to 1100 nm.

The film thickness of the cured film is, for example, preferably 0.1 to 4.0 μm and more preferably 1.0 to 2.5 μm. The cured film may be thinner or thicker than the above range depending on the application. In addition, in a case where the cured film is used as a light attenuating film, it is also preferable that the light shielding properties are adjusted by making the cured film thinner than the above-described range (for example, 0.1 to 0.5 μm).

In addition, it is also preferable that the above-described cured film has a rugged surface structure. As a result, it is possible to reduce the reflectivity of the cured film in a case where the cured film is used as a light shielding film. The surface of the cured film may have a rugged structure, or another layer may be provided on the cured film to impart the rugged structure. A shape of the rugged surface structure is not particularly limited, but for example, it is preferable that a surface roughness is within a range of 0.55∥m to 1.5 μM. Examples of a method for obtaining a cured film having a rugged surface structure include a method for introducing the particles A into the composition as described above.

As the reflectivity of the above-described cured film, in a case where a film is formed by performing the following film forming method on a composition layer formed from the composition, it is preferable that the maximum reflectivity of the film in a wavelength range of 400 to 1100 nm is less than 5%, more preferable to be less than 3%, and still more preferable to be less than 1%. The maximum reflectivity of the film in a wavelength range of 400 to 1100 nm is intended to be a reflectivity to light having a wavelength showing the maximum reflectivity in the wavelength range of 400 to 1100 nm.

Film Forming Method

The composition according to the embodiment of the present invention is applied to a substrate so that a thickness after an exposure is 2.0 μm to form a coating film, the obtained coating film is heated under conditions of at 100° C. for 120 seconds to form a composition layer, and using a high-pressure mercury lamp, the composition layer is exposed to an exposure amount of 1000 mJ/cm², and then the exposed composition layer is heated under conditions of 220° C. for 300 seconds.

Furthermore, examples of a method for reducing the reflectivity of the above-described cured film include, in addition to the above-described method, a method for providing a layer of low refractive index on the cured film, a method for further providing a plurality of layers (for example, layers of high refractive index) having different refractive indices, and a method which is for forming a low-optical-density layer and a high-optical-density layer and described in JP2015-1654A.

In addition, the above-described cured film is suitable for a light shielding member, a light shielding film, an antireflection member, and an antireflection film of optical filters and modules used in portable instruments such as a personal computer, a tablet PC, a mobile phone, a smartphone, and a digital camera; office automation (OA) instruments such as a printer composite machine and a scanner; industrial instruments such as surveillance camera, a barcode reader, an automated teller machine (ATM), a high-speed camera, an instrument having a personal authentication function using face image authentication; in-vehicle camera instruments; medical camera instruments such as an endoscope, a capsule endoscope, and a catheter; a biosensor, a military reconnaissance camera, a camera for a three-dimensional map, a camera for observing weather and sea, a camera for a land resource exploration, space instruments such as an exploration camera for the astronomy of the space and a deep space target; and the like.

The cured film can also be used in applications of a micro light emitting diode (LED), a micro organic light emitting diode (OLED), and the like. The cured film is suitable for an optical filter and an optical film used in the micro LED and the micro OLED and for a member which imparts a light shielding function or an antireflection function.

Examples of the micro LED and the micro OLED include the examples described in JP2015-500562A and JP2014-533890A.

The cured film is also suitable as an optical filter and an optical film used in a quantum dot sensor and a quantum dot solid-state imaging element. In addition, the cured film is suitable as a member which imparts a light shielding function or an antireflection function. Examples of the quantum dot sensor and the quantum dot solid-state imaging element include the examples described in US2012/37789A and WO2008/131313A.

Light Shielding Film, Solid-State Imaging Element, and Solid-State Imaging Device

It is also preferable that the cured film formed from the composition according to the embodiment of the present invention is used as a so-called light shielding film. It is also preferable that such a light shielding film is used in a solid-state imaging element.

The light shielding film is one of the preferred uses in the cured film according to the present invention, and the light shielding film according to the embodiment of the present invention can be similarly manufactured by a method described as the above-described method for manufacturing a cured film. Specifically, the light shielding film can be manufactured by applying the composition to a substrate to form a composition layer, and performing exposure and development on the composition layer.

In addition, the solid-state imaging element according to the embodiment of the present invention is a solid-state imaging element including the above-described cured film (light shielding film) An aspect in which the solid-state imaging element contains the cured film (light shielding film) is not particularly limited, and examples thereof include an aspect in which a plurality of photodiodes and light-receiving elements consisting of polysilicon or the like constituting a light-receiving area of a solid-state imaging element (a CCD image sensor, a CMOS image sensor, or the like) are provided on a substrate, and solid-state imaging element includes the cured film on a surface side (for example, a portion other than light receiving sections and/or pixels for adjusting color, and the like) of a support on which the light-receiving elements are formed or on a side opposite to the surface on which the light-receiving elements are formed.

In addition, in a case where the cured film (light shielding film) is used as a light attenuating film, for example, by disposing a light attenuating film so that a part of light passes through the light attenuating film and then is incident on a light-receiving element, the dynamic range of the solid-state imaging element can be improved.

The solid-state imaging device includes the above-described solid-state imaging element.

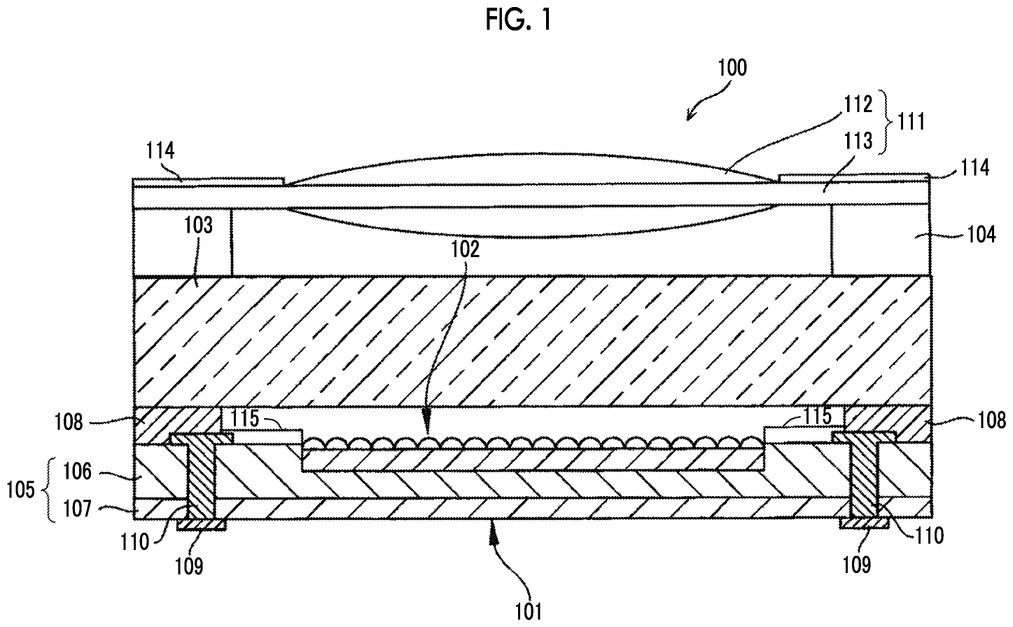

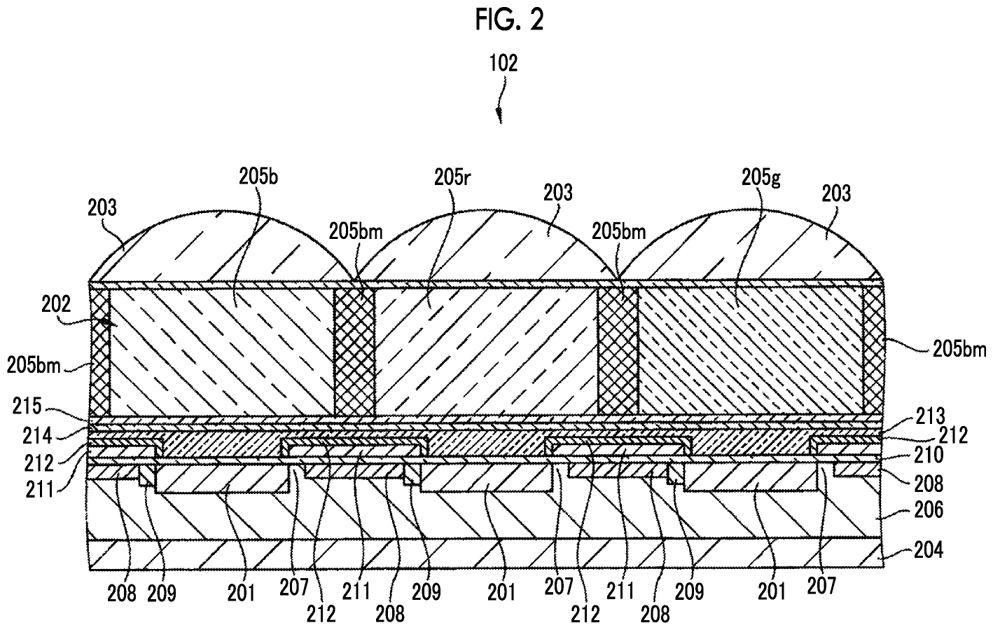

Examples of the constitutions of the solid-state imaging device and the solid-state imaging element will be described with reference to FIGS. 1 and 2. In FIGS. 1 and 2, in order that each portion is clearly seen, some portions are magnified in disregard of a thickness ratio and/or a width ratio between the portions.

As shown in FIG. 1, a solid-state imaging device 100 comprises a rectangular solid-state imaging element 101 and a transparent cover glass 103 which is held above the solid-state imaging element 101 and seals the solid-state imaging element 101. In addition, on the cover glass 103, a lens layer 111 is superposably provided through a spacer 104. The lens layer 111 includes a support 113 and a lens material 112. The lens layer 111 may have a configuration in which the support 113 and the lens material 112 are integrally formed. In a case where stray light is incident on the peripheral edge region of the lens layer 111, due to the diffusion of light, an effect of light condensation on the lens material 112 is weakened, and thus the light reaching an imaging part 102 is reduced. In addition, noise is also generated due to the stray light. Therefore, a light shielding film 114 is provided in the peripheral edge region of the lens layer 111 so that light is shielded. The cured film formed of the composition according to the embodiment of the present invention can also be used as the above-described light shielding film 114.

The solid-state imaging element 101 performs photoelectric conversion on an optical image formed on the imaging part 102 serving as a light-receiving surface of the solid-state imaging element 101, and outputs the converted optical image as an image signal. The solid-state imaging element 101 comprises a laminated substrate 105 obtained by laminating two sheets of substrates. The laminated substrate 105 consists of a chip substrate 106 and a circuit substrate 107 which have the same size and a rectangular shape, and the circuit substrate 107 is laminated on the rear surface of the chip substrate 106.

A material of the substrate used as the chip substrate 106 is not particularly limited, and known materials can be used.

The imaging part 102 is provided in the central part of the surface of the chip substrate 106. In addition, in a case where stray light is incident on the peripheral region of the imaging part 102, a dark current (noise) is generated from the circuit in the peripheral region, and thus a light shielding film 115 is provided in the peripheral region so that light is shielded. The cured film formed from the composition according to the embodiment of the present invention is preferably used as the light shielding film 115.

A plurality of electrode pads 108 are provided at an edge part of the surface of the chip substrate 106. The electrode pads 108 are electrically connected to the imaging part 102 through a signal line (a bonding wire can also be used) (not shown) provided on the surface of the chip substrate 106.

On the rear surface of the circuit substrate 107, external connection terminals 109 are provided at positions approximately below the electrode pads 108, respectively. The external connection terminals 109 are respectively connected to the electrode pads 108 through a through-electrode 110 vertically passing through the laminated substrate 105. In addition, the external connection terminals 109 are connected to a control circuit controlling the driving of the solid-state imaging element 101, an image processing circuit performing image processing on an imaging signal output from the solid-state imaging element 101, and the like through a wiring line (not shown).

As shown in FIG. 2, the imaging part 102 includes the parts, such as a light-receiving element 201, a color filter 202, and a microlens 203, provided on a substrate 204. The color filter 202 has a blue pixel 205b, a red pixel 205r, a green pixel 205g, and a black matrix 205bm. The cured film formed from the composition according to the embodiment of the present invention may be used as the black matrix 205bm.

As the material of the substrate 204, the same material as that of the chip substrate 106 can be used. On the surface layer of the substrate 204, a p-well layer 206 is formed. In the p-well layer 206, the light-receiving elements 201, which consist of an n-type layer and generate and accumulate signal charges by photoelectric conversion, are formed to be arranged in a square lattice form.

On one lateral side of each light-receiving element 201, through a reading gate part 207 on the surface layer of the p-well layer 206, a vertical electric charge transfer path 208 consisting of an n-type layer is formed. In addition, on the other lateral side of each light-receiving element 201, through an element separation region 209 consisting of a p-type layer, a vertical electric charge transfer path 208 belonging to the adjacent pixel is formed. The reading gate part 207 is a channel region for the signal charges accumulated in the light-receiving element 201 to be read out toward the vertical electric charge transfer path 208.

On the surface of the substrate 204, a gate insulating film 210 consisting of an oxide-nitride-oxide (ONO) film is formed. On the gate insulating film 210, vertical electric charge transfer electrodes 211 consisting of polysilicon or amorphous silicon are formed to cover the portions which are approximately immediately above the vertical electric charge transfer path 208, the reading gate part 207, and the element separation region 209. The vertical electric charge transfer electrodes 211 function as driving electrodes for driving the vertical electric charge transfer path 208 and performing charge transfer and as reading electrodes for driving the reading gate part 207 and reading out signal charges. The signal charges are transferred to a horizontal electric charge transfer path and an output part (floating diffusion amplifier), which are not shown in the drawing, in this order from the vertical electric charge transfer path 208, and then output as voltage signals.

On each of the vertical electric charge transfer electrodes 211, a light shielding film 212 is formed to cover the surface of the electrode. The light shielding film 212 has an opening portion at a position immediately above the light-receiving element 201 and shields a region other than the opening portion from light. The cured film formed from the composition according to the embodiment of the present invention may be used as the light shielding film 212.

On the light shielding film 212, a transparent interlayer, which consists of an insulating film 213 consisting of borophosphosilicate glass (BPSG), an insulating film (passivation film) 214 consisting of P-SiN, and a planarization film 215 consisting of a transparent resin or the like, is provided. The color filter 202 is formed on the interlayer.

Image Display Device

An image display device according to the embodiment of the present invention includes the cured film formed from the composition according to the embodiment of the present invention.

Examples of the aspect in which the image display device has a cured film include an aspect in which a cured film is contained in a black matrix and a color filter containing such a black matrix is used in an image display device.

Next, a black matrix and a color filter containing the black matrix will be described, and a liquid crystal display device containing such a color filter will be described as a specific example of the image display device.

Black Matrix

It is also preferable that the cured film formed from the composition according to the embodiment of the present invention is contained in a black matrix. The black matrix can be usually incorporated into a color filter, a solid-state imaging element, and an image display device such as a liquid crystal display device.

Examples of the black matrix include those described above; a black rim provided in the peripheral portion of an image display device such as a liquid crystal display device; a lattice-like and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast and to prevent image quality deterioration resulting from current leakage of light in a case of an active matrix driving-type liquid crystal display device using a thin film transistor (TFT), the black matrix preferably has high light shielding properties (preferably, the OD value is 3.0 or more).

The method for manufacturing the black matrix is not particularly limited, but the black matrix can be manufactured in the same manner as the method for manufacturing the cured film. Specifically, by applying the composition on a substrate to form a composition layer and performing exposure and development on the composition layer, a patterned cured film (black matrix) can be manufactured. The film thickness of the cured film used as the black matrix is preferably 0.1 to 4.0 μm.

The material of the substrate is not particularly limited, but preferably has a transmittance of 80% or more for visible light (wavelength of 400 to 800 nm). Specific examples of such a material include glass such as soda lime glass, alkali-free glass, quartz glass, and borosilicate glass, and plastic such as a polyester-based resin and a polyolefin-based resin, and from the viewpoints of chemical resistance and heat resistance, alkali-free glass, quartz glass, or the like is preferable.

Color Filter

It is also preferable that the cured film formed from the composition according to the embodiment of the present invention is included in a color filter.

The aspect in which the color filter includes the cured film is not particularly limited, but examples thereof include a color filter comprising a substrate and the above-described black matrix. That is, examples thereof include a color filter comprising colored pixels of red, green, and blue which are formed in the opening portion of the black matrix formed on a substrate.

The color filter containing a black matrix (cured film) can be manufactured, for example, by the following method.

First, in an opening portion of a patterned black matrix formed on a substrate, a coating film (composition layer) of a composition containing each of pigments corresponding to the respective colored pixels of the color filter is formed. The composition for each color is not particularly limited, known compositions can be used, but in the composition described in the present specification, it is preferable that a composition in which the light shielding pigment is replaced with a colorant corresponding to each pixel is used.

Subsequently, the composition layer is subjected to exposure through a photo mask having a pattern corresponding to the opening portion of the black matrix. Next, colored pixels can be formed in the opening portion of the black matrix by removing a non-exposed portion by a development treatment, and then performing baking. In a case where the series of operations are performed using, for example, a composition for each color containing red, green, and blue pigments, a color filter having red, green, and blue pixels can be manufactured.

Liquid Crystal Display Device

It is also preferable that the cured film formed from the composition according to the embodiment of the present invention is included in a liquid crystal display device. The aspect in which the liquid crystal display device includes the cured film is not particularly limited, and examples thereof include an aspect in which the liquid crystal display device includes a color filter including the black matrix (cured film) described above.

Examples of the liquid crystal display device according to the embodiment of the present invention include an aspect in which the liquid crystal display device comprises a pair of substrates disposed to face each other and a liquid crystal compound sealed into the space between the substrates. The substrates are as described above as the substrate for a black matrix.

Examples of a specific aspect of the liquid crystal display device include a laminate containing polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, the liquid crystal display device is not limited to the above-described liquid crystal display devices, and examples thereof include the liquid crystal display devices described in “Electronic display device (written by Akio SASAKI, Kogyo Chosakai Publishing Co., Ltd., published in 1990)”, “Display Device (written by Sumiaki IBUKI, Sangyo Tosho Publishing Co., Ltd., published in 1989)”, or the like. In addition, examples thereof include the liquid crystal display device described in “Next-Generation Liquid Crystal Display Technology (edited by Tatsuo UCHIDA, Kogyo Chosakai Publishing Co., Ltd., published in 1994)”.

Infrared Sensor

It is also preferable that the cured film formed from the composition according to the embodiment of the present invention is included in an infrared sensor.

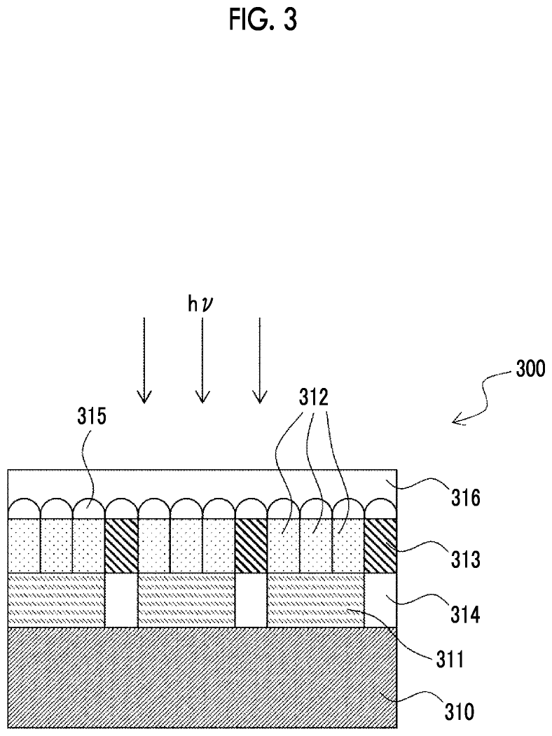

The infrared sensor according to the embodiment will be described with reference to FIG. 3. In an infrared sensor 300 shown in FIG. 3, a reference 310 represents a solid-state imaging element.

An imaging region provided on the solid-state imaging element 310 is configured by combining an infrared absorption filter 311 and a color filter 312 according to the embodiment of the present invention.

The infrared absorption filter 311 is a film which transmits light (for example, light having a wavelength of 400 to 700 nm) in the visible light range and shields light (for example, light having a wavelength of 800 to 1300 nm, preferably having a wavelength of 900 to 1200 nm, and more preferably having a wavelength of 900 to 1000 nm) in the infrared range, and a cured film including an infrared absorber (examples thereof include infrared absorbers already described as the infrared absorber) as a colorant can be used.

The color filter 312 is a color filter in which pixels transmitting or absorbing light having a specific wavelength in the visible light range are formed, for example, a color filter in which pixels of red (R), green (G), and blue (B) are formed, or the like is used, and the form thereof is as described above.

Between an infrared transmitting filter 313 and the solid-state imaging element 310, a resin film 314 (for example, a transparent resin film or the like), which transmits light having a wavelength transmitted through the infrared transmitting filter 313, is disposed.

The infrared transmitting filter 313 is a filter which has visible light shielding properties and transmits infrared rays of a specific wavelength, and the cured film formed from the composition according to the embodiment of the present invention, which includes a colorant (for example, a perylene compound and/or a bisbenzofuranone compound, and the like) absorbing light in the visible light region and an infrared absorber (for example, a pyrrolopyrrole compound, a phthalocyanine compound, a naphthalocyanine compound, a polymethine compound, and the like), can be used. It is preferable that the infrared transmitting filter 313 shields light having a wavelength of 400 to 830 nm and transmits light having a wavelength of 900 to 1300 nm, for example.

On an incidence ray hv side of the color filter 312 and the infrared transmitting filter 313, microlenses 315 are arranged. A planarization film 316 is formed to cover the microlenses 315.

In the form shown in FIG. 3, the resin film 314 is disposed, but the infrared transmitting filter 313 may be formed instead of the resin film 314. That is, on the solid-state imaging element 310, the infrared transmitting filter 313 may be formed.

In the form shown in FIG. 3, the film thickness of the color filter 312 is the same as the film thickness of the infrared transmitting filter 313, but both the film thicknesses may be different from each other.

In the form shown in FIG. 3, the color filter 312 is provided to be closer to the incidence ray hv side than the infrared absorption filter 311, but the order of the infrared absorption filter 311 and the color filter 312 may be switched so that the infrared absorption filter 311 is provided to be closer to the incidence ray hv side than the color filter 312.

In the form shown in FIG. 3, the infrared absorption filter 311 and the color filter 312 are laminated to be adjacent to each other, but both the filters are not necessarily adjacent to each other, and another layer may be provided between the filters. The cured film formed from the composition according to the embodiment of the present invention can be used as a light shielding film on an edge of the surface and/or a lateral surface of the infrared absorption filter 311, and, by being used as a device inner wall of an infrared sensor, can prevent internal reflection and/or unintended incidence of light on the light receiving section and can improve sensitivity.

According to the infrared sensor, image information can be simultaneously taken in, and thus motion sensing or the like by which a subject whose movement is to be detected is recognized can be carried out. Furthermore, because distance information can be obtained, images including 3D information and the like can be captured.

Next, a solid-state imaging device to which the above-described infrared sensor is applied will be described.

The above-described solid-state imaging device contains a lens optical system, a solid-state imaging element, an infrared emission diode, and the like. Furthermore, regarding each of the configurations of the solid-state imaging device, reference can be made to paragraphs 0032 to 0036 of JP2011-233983A, the contents of which are incorporated into the specification of the present application.

### EXAMPLES

Hereinafter, the present invention will be described in more detail with reference to Examples. The materials, the amounts of materials used, the proportions, the treatment details, the treatment procedure, and the like shown in Examples below may be appropriately modified as long as the modifications do not depart from the spirit of the present invention. Accordingly, the scope of the present invention is not limited to the following Examples.

Preparation of Coloring Material Dispersion Liquid

A coloring material dispersion liquid was prepared using raw materials shown below.

Raw Material for Coloring Material Dispersion Liquid

Carbon Black

The following CB-1 to CB-6 were used as carbon black.
CB-1: #2350 (average primary particle diameter: 15 nm, pH: 2.5, manufactured by Mitsubishi Chemical Corporation)
CB-2: MA77 (average primary particle diameter: 23 nm, pH: 2.5, manufactured by Mitsubishi Chemical Corporation)
CB-3: Raven1080 (average primary particle diameter: 28 nm, pH: 2.4, manufactured by Columbia Chemical)
CB-4: MA220 (average primary particle diameter: 55 nm, pH: 3.0, manufactured by Mitsubishi Chemical Corporation)
CB-5: #2600 (average primary particle diameter: 13 nm, pH: 6.5, manufactured by Mitsubishi Chemical Corporation)
CB-6: PRINTEX 45 (average primary particle diameter: 26 nm, pH: 9.5, manufactured by Orion Engineered Carbons S.A.)

Metal Nitride Particles and Metal Oxynitride Particles (Particles B)

The following P-1 to P-3 were used as metal nitride particles and metal oxynitride particles (particles B).
P-1: 13M-T (material: titanium oxynitride, manufactured by Mitsubishi Materials Corporation; average primary particle diameter: 0.05 μm)
P-2: titanium nitride particles (material: titanium nitride, manufactured by Hefei Kai′er Nanometer Technology and Development Co., Ltd; average primary particle diameter: 0.05 μm)
P-3: zirconium oxynitride particles (material: zirconium oxynitride, manufactured by Mitsubishi Materials Corporation; average primary particle diameter: 0.04 μm)

Barium Sulfate

The following BS-1 was used as barium sulfate.

BS-1: BF-20 (manufactured by SAKAI CHEMICAL INDUSTRY CO., LTD.) (average particle diameter: 0.03 μm, pH: 10)

Copper Phthalocyanine or Copper Phthalocyanine Derivative

The following CP-1 to CP-3 were used as copper phthalocyanine or a copper phthalocyanine derivative.

CP-1: Pigment Blue 15 (copper phthalocyanine, manufactured by Tokyo Chemical Industry Co., Ltd.)

CP-2: copper phthalocyanine-3,4′,4″,4′″-tetrasulfonic acid tetrasodium salt (copper phthalocyanine derivative, manufactured by Sigma-Aldrich Co., LLC) CP-3: Solsperse 5000 (copper phthalocyanine derivative, manufactured by Lubrizol Limited)

The “CP-3 (Solsperse 5000)” corresponds to a salt composed of copper phthalocyanine having a sulfonic acid group and dimethyldioctadecylammonium.

Dispersant

As a dispersant, dispersants H-1 to H-5 having the following structures were used.

In the dispersants H-1 to H-3, a numerical value described in each structural unit included in a main chain means % by mole of each structural unit with respect to all structural units. Moreover, a numerical value described in each structural unit included in a side chain indicates a repetition number.
H-1: dispersant having the following structure (acid value=103 mgKOH/g, amine value=103 mgKOH/g, weight-average molecular weight=13,000)

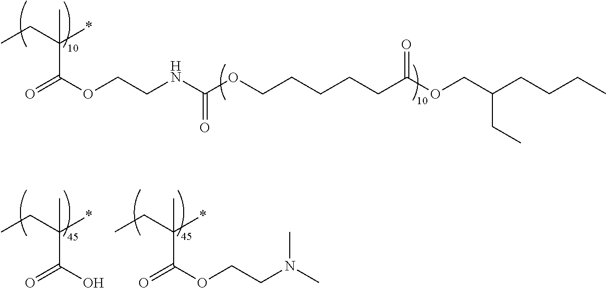

H-2: dispersant having the following structure (acid value=52 mgKOH/g, weight-average molecular weight=13,000)

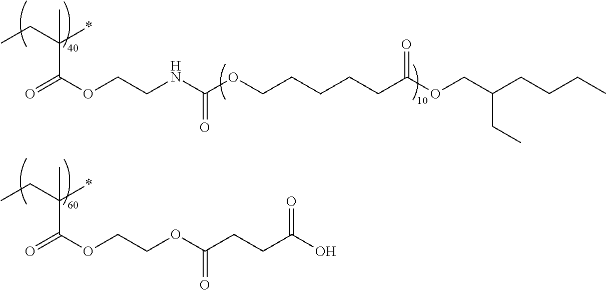

H-3: dispersant having the following structure (acid value=33 mgKOH/g, amine value=44 mgKOH/g, weight-average molecular weight=23,000)

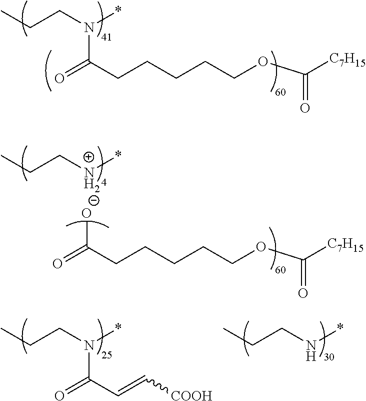

H-4: Disperbyk167 (amine value=13 mgKOH/g, manufactured by BYK-Chemie GmbH)
H-5: Disperbyk161 (amine value=11 mgKOH/g, manufactured by BYK-Chemie GmbH)

Solvent
Propylene glycol monomethyl ether acetate (PGMEA)
Butyl acetate
Cyclopentanone

Preparation of Coloring Material Dispersion Liquid

After mixing and stirring each component shown in Table 1, 230 parts by mass of zirconia beads having a diameter of 0.3 mm was further added to the obtained mixed solution, and a dispersion treatment was performed for 5 hours using a paint shaker. Next, the beads were separated from the obtained treated product by filtration to obtain each coloring material dispersion liquid (hereinafter, also referred to as a “dispersion liquid”) shown in Table 1.

The compositions of the coloring material dispersion liquids are shown in Table 1.

TABLE 1

| | Carbon black or | | Barium | | Copper | | Dispersant | | | |
|---|---|---|---|---|---|---|---|---|---|---|
| | particles B | | sulfate | | phthalocyanines | | (resin 1) | | Solvent | |
| | | Addition | | Addition | | Addition | | Addition | | Addition |
| | | amount(part | | amount (part | | amount (part by | | amount (part | | amount (part |
| | Type | by mass) | Type | by mass) | Type | mass) | Type | by mass) | Type | by mass) |
| Dispersion liquid 1 | CB-1 | 18.0 | BS-1 | 2.0 | CP-1 | 1.0 | H-1 | 5.0 | PGMEA | 74.0 |
| Dispersion liquid 2 | CB-1 | 18.0 | BS-1 | 2.0 | CP-2 | 1.0 | H-1 | 5.0 | PGMEA | 74.0 |
| Dispersion liquid 3 | CB-1 | 18.0 | BS-1 | 2.0 | CP-3 | 1.0 | H-1 | 5.0 | PGMEA | 74.0 |
| Dispersion liquid 4 | CB-1 | 18.0 | BS-1 | 2.0 | CP-3 | 1.0 | H-2 | 5.0 | PGMEA | 74.0 |
| Dispersion liquid 5 | CB-1 | 18.0 | BS-1 | 2.0 | CP-3 | 1.0 | H-3 | 5.0 | PGMEA | 74.0 |
| Dispersion liquid 6 | CB-1 | 18.0 | BS-1 | 2.0 | CP-3 | 1.0 | H-4 | 5.0 | PGMEA | 74.0 |
| Dispersion liquid 7 | CB-1 | 18.0 | BS-1 | 2.0 | CP-3 | 1.0 | H-5 | 5.0 | PGMEA | 74.0 |
| Dispersion liquid 8 | CB-1 | 19.5 | BS-1 | 0.5 | CP-3 | 1.0 | H-3 | 5.0 | PGMEA | 74.0 |
| Dispersion liquid 9 | CB-1 | 15.0 | BS-1 | 5.0 | CP-3 | 1.0 | H-3 | 5.0 | PGMEA | 74.0 |
| Dispersion liquid 10 | CB-2 | 18.0 | BS-1 | 2.0 | CP-3 | 1.0 | H-4 | 5.0 | PGMEA | 74.0 |
| Dispersion liquid 11 | CB-3 | 18.0 | BS-1 | 2.0 | CP-3 | 1.0 | H-4 | 5.0 | PGMEA | 74.0 |
| Dispersion liquid 12 | CB-4 | 18.0 | BS-1 | 2.0 | CP-3 | 1.0 | H-4 | 5.0 | PGMEA | 74.0 |
| Dispersion liquid 13 | CB-5 | 18.0 | BS-1 | 2.0 | CP-3 | 1.0 | H-4 | 5.0 | PGMEA | 74.0 |
| Dispersion liquid 14 | CB-6 | 18.0 | BS-1 | 2.0 | CP-3 | 1.0 | H-4 | 5.0 | PGMEA | 74.0 |
| Dispersion liquid 15 | CB-1 | 18.0 | BS-1 | 2.0 | CP-3 | 1.0 | H-3 | 5.0 | PGMEA | 60 |
| | | | | | | | | | Butyl acetate | 14 |
| Dispersion liquid 16 | CB-1 | 18.0 | BS-1 | 2.0 | CP-3 | 1.0 | H-3 | 5.0 | PGMEA | 37 |
| | | | | | | | | | Butyl acetate | 37 |
| Dispersion liquid 17 | CB-1 | 18.0 | BS-1 | 2.0 | CP-3 | 1.0 | H-3 | 5.0 | PGMEA | 60 |
| | | | | | | | | | Cyclopentanone | 14 |
| Dispersion liquid 18 | P-1 | 15.6 | — | 0.0 | — | 0.0 | H-3 | 9.7 | PGMEA | 74.7 |
| Dispersion liquid 19 | P-2 | 15.6 | — | 0.0 | — | 0.0 | H-3 | 9.7 | PGMEA | 74.7 |
| Dispersion liquid 20 | P-3 | 15.6 | — | 0.0 | — | 0.0 | H-3 | 9.7 | PGMEA | 74.7 |
| Comparative | CB-6 | 20.0 | — | 0.0 | CP-3 | 1.0 | H-5 | 5.0 | PGMEA | 74.0 |
| dispersion liquid 1 | | | | | | | | | | |
| Comparative | CB-3 | 20.0 | — | 0.0 | CP-3 | 1.0 | H-4 | 5.0 | PGMEA | 74.0 |
| dispersion liquid 2 | | | | | | | | | | |
| Comparative | CB-3 | 18.0 | BS-1 | 2.0 | — | 0.0 | H-4 | 6.0 | PGMEA | 74.0 |
| dispersion liquid 3 | | | | | | | | | | |

Preparation of Composition

A composition was prepared using raw materials shown below.

Raw Materials for Composition

Coloring Material Dispersion Liquid

As a coloring material dispersion liquid, the coloring material dispersion liquids (dispersion liquids 1 to 20 and comparative dispersion liquids 1 to 3) prepared in the above part were used.

Alkali-Soluble Resin

As an alkali-soluble resin, the following C-1 and C-2 were used. Structures of the resins C-1 and C-2 are shown below. A numerical value described in each structural unit means % by mole of each structural unit with respect to all structural units.
C-1: resin having the following structure (acid value=110 mgKOH/g, weight-average molecular weight=33,000)

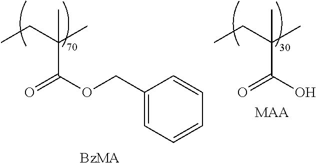

C-2: resin having the following structure (acid value=70 mgKOH/g, weight-average molecular weight=11,000)

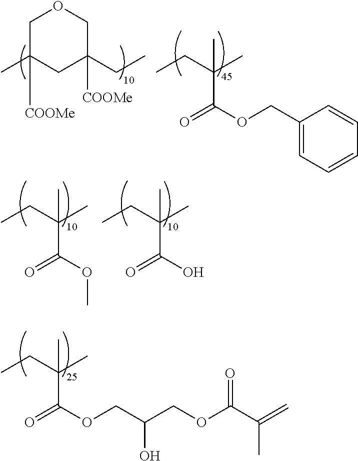

Crosslinking Agent

The following D-1 to D-3 were used as a crosslinking agent.
D-1: compound having the following structure (corresponding to an alkoxymethyl group-containing crosslinking agent)

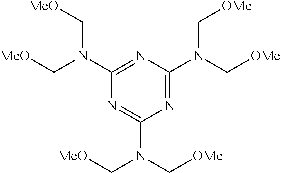 [SMILES: COCN(COC)c1nc(N(COC)COC)nc(N(COC)COC)n1]

D-2: jER828 (bisphenol A-type epoxy resin, manufactured by Mitsubishi Chemical Holdings Corporation (corresponding to an epoxy group-containing crosslinking agent))
D-3: OXT-221 (bis[1-ethyl(3-oxetanyl)]methyl ether, manufactured by Toagosei Co., Ltd. (corresponding to an oxetanyl group-containing crosslinking agent))

Acid Generator

As an acid generator, the following E-1 to E-5 were used.
E-1: compound having the following structure (corresponding to a sulfonium salt compound)

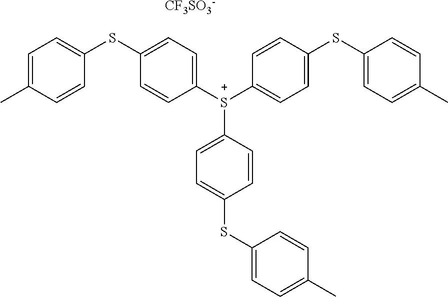

E-2: compound having the following structure (corresponding to a sulfonium salt compound)

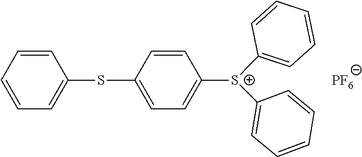

E-3: compound having the following structure (corresponding to a halomethylated triazine compound)

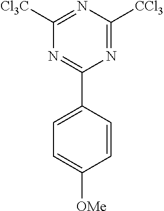

E-4: compound having the following structure (corresponding to a halomethylated triazine compound)

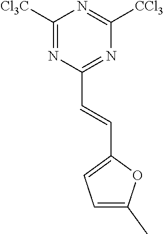

E-5: compound having the following structure (corresponding to a oxime sulfonate compound)

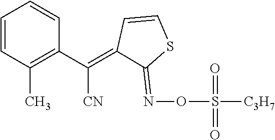

Organic Particles and Metal Oxide Particles Different from Carbon Black (Particles A)

The following H-1 to H-3 were used as organic particles different from the carbon black and metal oxide particles (particles A).
H-1: Bellpearl 8200 (phenol resin particles, average particle diameter: 6 manufactured by AIR WATER BELLPEARL INC.)
H-2: Bellpearl R100 (phenol resin particles, average particle diameter: 1.5 μm, manufactured by AIR WATER BELLPEARL INC.)
H-3: EPOSTAR MA1006 (acrylic resin particles, average particle diameter: 6 μm, manufactured by NIPPON SHOKUBAI CO., LTD.)
H-4: SOLIOSTAR R_{A} A type (silica particles, average particle diameter: 3.5 μm, manufactured by NIPPON SHOKUBAI CO., LTD.)

Solvent
Propylene glycol monomethyl ether acetate (PGMEA)

Adhesive

The following G-1 was used as an adhesive.
G-1: compound having the following structure

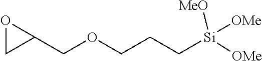 [SMILES: CO[Si](CCCOCC1CO1)(OC)OC]

Surfactant

The following W-1 to W-4 were used as a surfactant.

W-1: compound having the following structure (fluorine-based surfactant, weight-average molecular weight=15,000; in the following formula, contents of a left structural unit and a right structural unit are 62% by mass and 38% by mass, respectively)

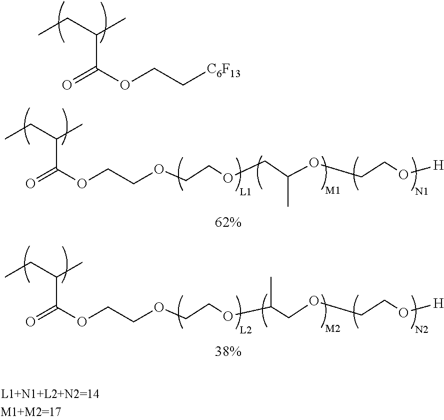

W-2: KF-6000 (silicone-based surfactant (carbinol-modified silicone; dimethyl type), manufactured by Shin-Etsu Chemical Co., Ltd.)
W-3: Dowsil SH-8400 Fluid (silicone-based surfactant (EO-modified silicone; dimethyl type), manufactured by Dow Chemical Company)
W-4: KP323 (silicone-based surfactant (phenyl-modified silicone), manufactured by Shin-Etsu Chemical Co., Ltd.)

Preparation of Example Compositions and Comparative Compositions 1 to 3

Each component shown in Table 2 was mixed in a formulation shown in Table 2 to obtain example compositions and comparative compositions 1 to 3. Compositions of the obtained compositions are shown in Table 2.

Preparation of Comparative Composition 4

54.1 parts by mass of the coloring material dispersion liquid 5, 6 parts by mass of the alkali-soluble resin C-1, 9 parts by mass of dipentaerythritol hexaacrylate as a radically polymerizable compound, 3 parts by mass of Irgacure OXE02 (manufactured by BASF SE) as a photoradical generator, 27.9 parts by mass of PGMEA, and 0.01 parts by mass of the surfactant W-1 were mixed to prepare a comparative composition 4.

Table 2 is shown below.

Table 2 (1)

| | Coloring material dispersion | | | | | | | | | | | | | | | |
|---|---|---|---|---|---|---|---|---|---|---|---|---|---|---|---|---|
| | liquid | | Alkali-soluble resin | | Crosslinking | | | | | | | | | | | |
| | | Formulation | (resin 2) | | agent | | Acid generator | | Particles A | | Solvent | | Adhesive | | Surfactant | |
| | | amount | | Formulation | | Formulation | | Formulation | | Formulation | | Formulation | | Formulation | | Formulation |
| | | (part by | | amount (part by | | amount (part by | | amount (part by | | amount (part by | | amount (part by | | amount (part by | | amount (part by |
| | Type | mass) | Type | mass) | Type | mass) | Type | mass) | Type | mass) | Type | mass) | Type | mass) | Type | mass) |
| Example | Dispersion | 54.1 | C-1 | 6 | D-1 | 9 | E-1 | 3 | — | | PGMEA | 27.9 | — | | W-1 | 0.01 |
| composition-1 | liquid 5 | | | | | | | | | | | | | | | |
| Example | Dispersion | 54.1 | C-1 | 6 | D-2 | 9 | E-1 | 3 | — | | PGMEA | 27.9 | — | | W-1 | 0.01 |
| composition-2 | liquid 5 | | | | | | | | | | | | | | | |
| Example | Dispersion | 54.1 | C-1 | 6 | D-3 | 9 | E-1 | 3 | — | | PGMEA | 27.9 | — | | W-1 | 0.01 |
| composition-3 | liquid 5 | | | | | | | | | | | | | | | |
| Example | Dispersion | 54.1 | C-1 | 6 | D-1 | 4.5 | E-1 | 3 | — | | PGMEA | 27.9 | — | | W-1 | 0.01 |
| composition-4 | liquid 5 | | | | D-2 | 4.5 | | | | | | | | | | |
| Example | Dispersion | 54.1 | C-1 | 6 | D-1 | 9 | E-2 | 3 | — | | PGMEA | 27.9 | — | | W-1 | 0.01 |
| composition-5 | liquid 5 | | | | | | | | | | | | | | | |
| Example | Dispersion | 54.1 | C-1 | 6 | D-1 | 9 | E-3 | 3 | — | | PGMEA | 27.9 | — | | W-1 | 0.01 |
| composition-6 | liquid 5 | | | | | | | | | | | | | | | |
| Example | Dispersion | 54.1 | C-1 | 6 | D-1 | 9 | E-4 | 3 | — | | PGMEA | 27.9 | — | | W-1 | 0.01 |
| composition-7 | liquid 5 | | | | | | | | | | | | | | | |
| Example | Dispersion | 54.1 | C-1 | 6 | D-1 | 9 | E-5 | 3 | — | | PGMEA | 27.9 | — | | W-1 | 0.01 |
| composition-8 | liquid 5 | | | | | | | | | | | | | | | |
| Example | Dispersion | 54.1 | C-1 | 6 | D-1 | 9 | E-1 | 1.5 | — | | PGMEA | 27.9 | — | | W-1 | 0.01 |
| composition-9 | liquid 5 | | | | | | E-3 | 1.5 | | | | | | | | |
| Example | Dispersion | 54.1 | C-1 | 6 | D-1 | 9 | E-1 | 1.5 | — | | PGMEA | 27.9 | — | | W-1 | 0.01 |
| composition-10 | liquid 5 | | | | | | E-5 | 1.5 | | | | | | | | |
| Example | Dispersion | 54.1 | C-1 | 6 | D-1 | 9 | E-1 | 1 | — | | PGMEA | 27.9 | — | | W-1 | 0.01 |
| composition-11 | liquid 5 | | | | | | E-3 | 1 | | | | | | | | |
| | | | | | | | E-4 | 1 | | | | | | | | |
| Example | Dispersion | 54.1 | C-1 | 4 | D-1 | 6 | E-1 | 1 | H-1 | 6 | PGMEA | 27.9 | — | | W-1 | 0.01 |
| composition-12 | liquid 5 | | | | | | E-3 | 1 | | | | | | | | |
| Example | Dispersion | 54.1 | C-1 | 4 | D-1 | 6 | E-1 | 1 | H-2 | 6 | PGMEA | 27.9 | — | | W-1 | 0.01 |
| composition-13 | liquid 5 | | | | | | E-3 | 1 | | | | | | | | |
| Example | Dispersion | 54.1 | C-1 | 4 | D-1 | 6 | E-1 | 1 | H-3 | 6 | PGMEA | 27.9 | — | | W-1 | 0.01 |
| composition-14 | liquid 5 | | | | | | E-3 | 1 | | | | | | | | |

Table 2 (2)

| | Coloring material dispersion | | | | | | | | | | | | | | | |
|---|---|---|---|---|---|---|---|---|---|---|---|---|---|---|---|---|
| | liquid | | Alkali-soluble resin | | Crosslinking | | | | | | | | | | | |
| | | Formulation | (resin 2) | | agent | | Acid generator | | Particles A | | Solvent | | Adhesive | | Surfactant | |
| | | amount | | Formulation | | Formulation | | Formulation | | Formulation | | Formulation | | Formulation | | Formulation |
| | | (part by | | amount (part by | | amount (part by | | amount (part by | | amount (part by | | amount (part by | | amount (part by | | amount (part by |
| | Type | mass) | Type | mass) | Type | mass) | Type | mass) | Type | mass) | Type | mass) | Type | mass) | Type | mass) |
| Example | Dispersion | 54.1 | C-1 | 4 | D-1 | 6 | E-1 | 2 | H-1 | 6 | PGMEA | 27.9 | — | | W-1 | 0.01 |
| composition-15 | liquid 1 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-16 | liquid 2 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-17 | liquid 3 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-18 | liquid 4 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-19 | liquid 5 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-20 | liquid 6 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-21 | liquid 7 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-22 | liquid 8 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-23 | liquid 9 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-24 | liquid 10 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-25 | liquid 11 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-26 | liquid 12 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-27 | liquid 13 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-28 | liquid 14 | | | | | | | | | | | | | | | |

Table 2 (3)

| | Coloring material disperison | | | | | | | | | | | | | | | |
|---|---|---|---|---|---|---|---|---|---|---|---|---|---|---|---|---|
| | liquid | | Alkali-soluble resin | | Crosslinking | | | | | | | | | | | |
| | | Formulation | (resin 2) | | agent | | Acid generator | | Particles A | | Solvent | | Adhesive | | Surfactant | |
| | | amount | | Formulation | | Formulation | | Formulation | | Formulation | | Formulation | | Formulation | | Formulation |
| | | (part by | | amount (part by | | amount (part by | | amount (part by | | amount (part by | | amount (part by | | amount (part by | | amount (part by |
| | Type | mass) | Type | mass) | Type | mass) | Type | mass) | Type | mass) | Type | mass) | Type | mass) | Type | mass) |
| Example | Dispersion | 54.1 | C-1 | 4 | D-1 | 6 | E-1 | 2 | H-1 | 6 | PGMEA | 27.9 | — | | W-1 | 0.01 |
| composition-29 | liquid 15 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-30 | liquid 16 | | | | | | | | | | | | | | | |
| Example | Dispersion | 54.1 | C-1 | 4 | D-1 | 6 | E-1 | 2 | H-1 | 6 | PGMEA | 27.9 | — | | W-1 | 0.01 |
| composition-31 | liquid 17 | | | | | | | | | | | | | | | |
| Example | Dispersion | 54.1 | C-2 | 4 | D-1 | 6 | E-1 | 2 | H-1 | 6 | PGMEA | 27.9 | — | | W-1 | 0.01 |
| composition-32 | liquid 5 | | | | | | | | | | | | | | | |
| Example | Dispersion | 54.1 | C-1 | 4 | D-1 | 6 | E-1 | 2 | H-1 | 6 | PGMEA | 27.9 | — | | W-2 | 0.01 |
| composition-33 | liquid 5 | | | | | | | | | | | | | | | |
| Example | Dispersion | 54.1 | C-1 | 4 | D-1 | 6 | E-1 | 2 | H-1 | 6 | PGMEA | 27.9 | — | | W-3 | 0.01 |
| composition-34 | liquid 5 | | | | | | | | | | | | | | | |
| Example | Dispersion | 54.1 | C-1 | 4 | D-1 | 6 | E-1 | 2 | H-1 | 6 | PGMEA | 27.9 | — | | W-4 | 0.01 |
| composition-35 | liquid 5 | | | | | | | | | | | | | | | |
| Example | Dispersion | 54.1 | C-1 | 4 | D-1 | 7 | E-2 | 0.5 | H-1 | 6 | PGMEA | 27.9 | — | | W-1 | 0.01 |
| composition-36 | liquid 11 | | | | | | E-3 | 0.5 | | | | | | | | |
| Example | Dispersion | 54.1 | C-1 | 4 | D-1 | 6.5 | E-2 | 0.75 | H-1 | 6 | PGMEA | 27.9 | — | | W-1 | 0.01 |
| composition-37 | liquid 11 | | | | | | E-3 | 0.75 | | | | | | | | |
| Example | Dispersion | 54.1 | C-1 | 4 | D-1 | 6 | E-2 | 1 | H-1 | 6 | PGMEA | 27.9 | — | | W-1 | 0.01 |
| composition-38 | liquid 11 | | | | | | E-3 | 1 | | | | | | | | |
| Example | Dispersion | 54.1 | C-1 | 4 | D-1 | 5 | E-2 | 1.5 | H-1 | 6 | PGMEA | 27.9 | — | | W-1 | 0.01 |
| composition-39 | liquid 11 | | | | | | E-3 | 1.5 | | | | | | | | |
| Example | Dispersion | 54.1 | C-1 | 4 | D-1 | 4 | E-2 | 2 | H-1 | 6 | PGMEA | 27.9 | — | | W-1 | 0.01 |
| composition-40 | liquid 11 | | | | | | E-3 | 2 | | | | | | | | |
| Example | Dispersion | 63.7 | C-1 | 1.5 | D-1 | 6 | E-2 | 1 | H-1 | 6 | PGMEA | 20.8 | — | | W-1 | 0.01 |
| composition-41 | liquid 11 | | | | | | E-3 | 1 | | | | | | | | |
| Example | Dispersion | 46.4 | C-1 | 6 | D-1 | 6 | E-2 | 1 | H-1 | 6 | PGMEA | 33.6 | — | | W-1 | 0.01 |
| composition-42 | liquid 11 | | | | | | E-3 | 1 | | | | | | | | |

Table 2 (4)

| | Coloring material disperison | | | | | | | | | | | | | | | |
|---|---|---|---|---|---|---|---|---|---|---|---|---|---|---|---|---|
| | liquid | | Alkali-soluble resin | | Crosslinking | | | | | | | | | | | |
| | | Formulation | (resin 2) | | agent | | Acid generator | | Particles A | | Solvent | | Adhesive | | Surfactant | |
| | | amount | | Formulation | | Formulation | | Formulation | | Formulation | | Formulation | | Formulation | | Formulation |
| | | (part by | | amount (part by | | amount (part by | | amount (part by | | amount (part by | | amount (part by | | amount (part by | | amount (part by |
| | Type | mass) | Type | mass) | Type | mass) | Type | mass) | Type | mass) | Type | mass) | Type | mass) | Type | mass) |
| Example | Dispersion | 54.6 | C-1 | 1.5 | D-1 | 6 | E-2 | 1 | H-1 | 6 | PGMEA | 20.8 | — | | W-1 | 0.01 |
| composition-43 | liquid 11 | | | | | | | | | | | | | | | |
| | Dispersion | 9.6 | | | | | E-3 | 1 | | | | | | | | |
| | liquid 18 | | | | | | | | | | | | | | | |
| Example | Dispersion | 32 | C-1 | 1.5 | D-1 | 6 | E-2 | 1 | H-1 | 6 | PGMEA | 20.8 | — | | W-1 | 0.01 |
| composition-44 | liquid 11 | | | | | | | | | | | | | | | |
| | Dispersion | 31.7 | | | | | E-3 | 1 | | | | | | | | |
| | liquid 18 | | | | | | | | | | | | | | | |
| Example | Dispersion | 54.1 | C-1 | 1.5 | D-1 | 6 | E-2 | 1 | H-1 | 6 | PGMEA | 20.8 | — | | W-1 | 0.01 |
| composition-45 | liquid 11 | | | | | | | | | | | | | | | |
| | Dispersion | 9.6 | | | | | E-3 | 1 | | | | | | | | |
| | liquid 19 | | | | | | | | | | | | | | | |
| Example | Dispersion | 54.1 | C-1 | 1.5 | D-1 | 6 | E-2 | 1 | H-1 | 6 | PGMEA | 20.8 | — | | W-1 | 0.01 |
| composition-46 | liquid 11 | | | | | | | | | | | | | | | |
| | Dispersion | 9.6 | | | | | E-3 | 1 | | | | | | | | |
| | liquid 20 | | | | | | | | | | | | | | | |
| Example | Dispersion | 54.1 | C-1 | 3 | D-1 | 6 | E-2 | 1 | H-1 | 6 | PGMEA | 27.9 | G-1 | 1 | W-1 | 0.01 |
| composition-47 | liquid 11 | | | | | | E-3 | 1 | | | | | | | | |
| Example | Dispersion | 54.1 | C-1 | 7 | D-1 | 6 | E-2 | 1 | H-1 | 3 | PGMEA | 27.9 | — | | W-1 | 0.01 |
| composition-48 | liquid 11 | | | | | | E-3 | 1 | | | | | | | | |
| Example | Dispersion | 54.1 | C-1 | 6.5 | D-1 | 6 | E-2 | 1 | H-1 | 3.5 | PGMEA | 27.9 | — | | W-1 | 0.01 |
| composition-49 | liquid 11 | | | | | | E-3 | 1 | | | | | | | | |
| Example | Dispersion | 54.1 | C-1 | 1 | D-1 | 6 | E-2 | 1 | H-1 | 9 | PGMEA | 27.9 | — | | W-1 | 0.01 |
| composition-50 | liquid 11 | | | | | | E-3 | 1 | | | | | | | | |
| Example | Dispersion | 54.1 | C-1 | 4 | D-1 | 6 | E-1 | 1 | H-4 | 6 | PGMEA | 27.9 | — | | W-1 | 0.01 |
| composition-51 | liquid 5 | | | | | | E-3 | 1 | | | | | | | | |
| Comparative | Comparative | 54.1 | C-1 | 6 | D-1 | 9 | E-1 | 3 | — | | PGMEA | 27.9 | — | | W-1 | 0.01 |
| composition-1 | dispersion | | | | | | | | | | | | | | | |
| | liquid 1 | | | | | | | | | | | | | | | |
| Comparative | Comparative | 54.1 | C-1 | 6 | D-1 | 9 | E-1 | 3 | — | | PGMEA | 27.9 | — | | W-1 | 0.01 |
| composition-2 | dispersion | | | | | | | | | | | | | | | |
| | liquid 2 | | | | | | | | | | | | | | | |
| Comparative | Comparative | 54.1 | C-1 | 6 | D-1 | 9 | E-1 | 3 | — | | PGMEA | 27.9 | — | | W-1 | 0.01 |
| composition-3 | dispersion | | | | | | | | | | | | | | | |
| | liquid 3 | | | | | | | | | | | | | | | |

Evaluation

The following evaluations were performed using the obtained composition. The evaluation results are shown in Table 3.

Evaluation of OD Value and Reflectivity

Production of Substrate with Cured Film

Each composition obtained above was applied to a glass substrate by a spin coating method to produce a coating film having a film thickness of 2.0 μm after exposure. Pre-baking was performed on the obtained coating film at 100° C. for 120 seconds, and then the entire surface of the substrate was exposed at an exposure amount of 1000 mJ/cm² with a high-pressure mercury lamp (lamp power of 50 mW/cm²) using UX-1000SM-EH04 (manufactured by Ushio Inc.). Next, the exposed substrate was post-baked at 220° C. for 300 seconds to obtain a substrate with a cured film.

Measurement of OD Value (Evaluation of Light Shielding Properties)

Regarding the substrate with a cured film, which was obtained in Production of substrate with cured film described above, a transmittance spectrum in a wavelength range of 400 to 1100 nm was measured with a spectrophotometer U-4100 (manufactured by Hitachi High-Technologies Corporation) and an integrating spherical light-receiving unit.

An OD value was calculated according to the following expression from a value of a transmittance (%) at a wavelength showing the maximum transmittance, and evaluated according to the following evaluation standard. It is judged that evaluations “A” and “B” have no problem in practical use.

OD=−log 10(transmittance/100)

Evaluation Standard
“A”: OD value was 3.5 or more.
“B”: OD value was 3.0 or more and less than 3.5.
“C”: OD value was less than 3.0.

Evaluation of Reflectivity

Regarding the substrate with a cured film, which was obtained in Production of substrate with cured film described above, light having a wavelength of 350 to 1200 nm was incident on the substrate at an incidence angle of 5° using a VAR unit of a spectrometer V7200 (product name) manufactured by JASCO Corporation, and a reflectivity of each wavelength was obtained from the obtained reflectivity spectrum. Specifically, the reflectivity of light having a wavelength which exhibits the maximum reflectivity in a wavelength range of 400 to 1100 nm was taken as the reflectivity of the cured film, and evaluated according to the following evaluation standard. It is judged that evaluations “A” to “C” have no problem in practical use.

Evaluation Standard
“A”: reflectivity was less than 1%.
“B”: reflectivity was 1% or more and less than 3%.
“C”: reflectivity was 3% or more and less than 5%.
“D”: reflectivity was 5% or more.

Evaluation of Storage Stability (Viscosity Stability Over Time)

In each composition, the viscosity (mPas) of the composition before a static treatment was measured using RE-85L (manufactured by TOKI SANGYO CO., LTD.) under the measurement conditions shown below. After the above-described measurement, the composition was allowed to stand at 7° C. under the condition of shading for 360 days (static treatment), and then the viscosity (mPas) of the composition after the static treatment was measured using RE-85L (manufactured by TOM SANGYO CO., LTD.) under the measurement conditions shown below.

Viscosity Measurement Conditions

The viscosities of the compositions before and after the above-described static treatment were all measured in a laboratory where the temperature was controlled to 22±5° C. and the humidity was controlled to 60+20% in a state in which the temperature of the composition was adjusted to 25° C.

A storage stability (viscosity stability over time) was evaluated according to the following evaluation standard based on a rate of change in viscosity before and after the above-described standing. As the numerical value of the rate of change in viscosity is smaller, the storage stability (viscosity stability over time) of the composition is better. It is judged that evaluations “A” to “C” have no problem in practical use.

Evaluation Standard
“A”: rate of change in viscosity was less than 3%.
“B”: rate of change in viscosity was 3% or more and less than 5%.
“C”: rate of change in viscosity was 5% or more and less than 10%.
“D”: rate of change in viscosity was 10% or more and less than 15%.
“E”: rate of change in viscosity was 15% or more.

Evaluation of Minimum Contact Exposure Amount, Evaluation of Adhesiveness (Tape Peeling Test), and Evaluation of Undercut Shape

Evaluation of Minimum Contact Exposure Amount

Each composition was applied to a glass substrate by a spin coating method so that a film thickness after film formation was 2.0 and the composition was heated using a hot plate at 90° C. for 2 minutes. Next, using UX-1000SM-EH04 (manufactured by Ushio Inc.), the glass substrate was exposed at an exposure amount of 50 to 2000 mJ/cm² with a high-pressure mercury lamp (lamp power of 50 mW/cm²) through a mask having a line-and-space pattern of 100 μm. Next, puddle development was performed at 23° C. for 60 seconds using a 0.3% by mass of tetramethylammonium hydroxide (TMAH) aqueous solution. Thereafter, the glass substrate was rinsed with a spin shower and then washed with pure water to form a line-and-space pattern.

By observing the pattern portion using an optical microscope, the minimum value of the exposure amount at which the line-and-space pattern was formed without the pattern being peeled off during the development was evaluated. As the value of the minimum exposure amount is smaller, the sensitivity is higher. It is judged that evaluations “A” to “C” have no problem in practical use.

Evaluation Standard
“A”: minimum contact exposure amount was 100 mJ/cm² or less.
“B”: minimum contact exposure amount was more than 100 mJ/cm² and 250 mJ/cm² or less.
“C” minimum contact exposure amount was more than 250 mJ/cm² and 500 mJ/cm² or less.
“D”: minimum contact exposure amount was a value more than 500 mJ/cm².

Evaluation of Adhesiveness (Tape Peeling Test)

The line-and-space pattern produced in Evaluation of minimum contact exposure amount described above with the minimum contact exposure amount was heated using a hot plate at 220° C. for 5 minutes. A cellophane tape was pressure-bonded to the obtained pattern using a pressure-bonding roller (2 kg) for a peeling test, and the tape was peeled off at a speed of 75 mm per second while tilting the end of the tape at an angle of 45°. A state of the pattern after peeling off the tape was observed using an optical microscope, and an adhesiveness was evaluated according to the following evaluation standard. It is judged that evaluations “A” and “B” have no problem in practical use.

Evaluation Standard
“A”: no peeling or chipping had occurred.
“B”: some parts were chipped, but there is no problem in practical use.
“C” peeling had occurred or many chips had occurred.

Evaluation of Undercut Shape

With the line-and-space pattern produced in Evaluation of minimum contact exposure amount described above, using a focused ion beam (FIB), a cross-sectional sample of the pattern of each composition at the minimum contact exposure amount was produced. Next, using a scanning electron microscope (SEM) (S-4800H, manufactured by Hitachi High-Technologies Corporation), the cross section of the pattern was observed, and a horizontal distance (undercut width) from the upper end of the cross section of the pattern to the end of a portion where the pattern was in contact with the substrate was measured. The evaluation was performed according to the following evaluation standard based on the obtained measured values. As the undercut width is smaller, the accuracy of the pattern shape is higher. It is judged that evaluations “A” to “C” have no problem in practical use.

Evaluation Standard
“A”: undercut width was 0 μm or more and less than 3 μm.
“B”: undercut width was 3 μm or more and less than 6 μm.
“C”: undercut width was 6 μm or more and less than 10 μm.
“D”: undercut width was 10 μm or more and less than 25 μm.
“E”: undercut width was 25 μm or more.

Table 3 is shown below.

TABLE 6

| | Evaluation result | | | | | | |
|---|---|---|---|---|---|---|---|
| | | | | Viscosity | Minimum | | |
| Table 3 | Light shielding resist | | | stability over | contact exposure | Adhesiveness | Undercut |
| (1) | component | OD value | Reflectivity | time | amount | tape peeling | evaluation |
| Example 1 | Example composition-1 | B | C | A | B | A | B |
| Example 2 | Example composition-2 | B | C | A | B | B | B |
| Example 3 | Example composition-3 | B | C | A | B | B | B |
| Example 4 | Example composition-4 | B | C | A | B | A | B |
| Example 5 | Example composition-5 | B | C | A | B | A | B |
| Example 6 | Example composition-6 | B | C | A | B | A | B |
| Example 7 | Example composition-7 | B | C | A | B | A | B |
| Example 8 | Example composition-8 | B | C | A | B | A | B |
| Example 9 | Example composition-9 | B | C | A | B | A | A |
| Example 10 | Example composition-10 | B | C | A | B | A | A |
| Example 11 | Example composition-11 | B | C | A | B | A | A |
| Example 12 | Example composition-12 | B | A | A | A | A | A |
| Example 13 | Example composition-13 | B | A | A | A | A | A |
| Example 14 | Example composition-14 | B | A | A | B | A | A |
| Example 15 | Example composition-15 | B | A | B | B | A | B |
| Example 16 | Example composition-16 | B | A | B | B | A | B |
| Example 17 | Example composition-17 | B | A | A | B | A | B |
| Example 18 | Example composition-18 | B | A | A | B | A | B |
| Example 19 | Example composition-19 | B | A | A | B | A | B |
| Example 20 | Example composition-20 | B | A | A | B | A | B |
| Example 21 | Example composition-21 | B | A | A | B | A | B |
| Example 22 | Example composition-22 | B | A | A | B | A | B |
| Example 23 | Example composition-23 | B | A | A | B | A | B |
| Example 24 | Example composition-24 | B | A | A | B | A | B |
| Example 25 | Example composition-25 | B | A | A | B | A | B |
| Example 26 | Example composition-26 | B | A | A | B | A | B |
| Example 27 | Example composition-27 | B | A | C | B | A | B |
| Example 28 | Example composition-28 | B | A | C | B | A | B |
| Example 29 | Example composition-29 | B | A | A | B | A | B |
| Example 30 | Example composition-30 | B | A | A | B | A | B |
| Example 31 | Example composition-31 | B | A | A | B | A | B |
| Example 32 | Example composition-32 | B | A | A | B | A | B |
| Example 33 | Example composition-33 | B | A | A | B | A | B |
| Example 34 | Example composition-34 | B | A | A | B | A | B |
| Example 35 | Example composition-35 | B | A | A | B | A | B |
| Example 36 | Example composition-36 | B | A | A | C | A | A |
| Example 37 | Example composition-37 | B | A | A | B | A | A |
| Example 38 | Example composition-38 | B | A | A | B | A | A |
| Example 39 | Example composition-39 | B | A | A | B | A | A |

From the results of Table 3, it was found that the pattern formed of the compositions of Examples had an excellent light shielding properties suitable for practical use, and the undercut was suppressed.

In addition, from the comparison of Examples 1 to 4, in a case where the compound having an alkoxymethyl group and having a triazine structure was used as the specific crosslinking agent, it was confirmed that the adhesiveness was more excellent.

Moreover, from the comparison of Examples 1, and 5 to 11, in a case where two or more kinds of acid generators were used, it was confirmed that the undercut suppression property of the formed pattern was more excellent. Although Example 10, Example 9, and Example 11 were all evaluated as “A”, Example 9 and Example 11 were more effective than Example 10. That is, in a case where the sulfonium salt compound and the halomethylated triazine compound were used in combination as the acid generator, it was confirmed that the undercut suppression property of the formed pattern was more excellent.

Moreover, from the comparison of Examples 1, 12 to 14, and 51, in a case where the composition included the particles A, it was confirmed that the formed pattern had lower reflection properties and the undercut suppression property was more excellent. In particular, in a case where the particles A included the phenolic resin particles, it was confirmed that the minimum contact exposure amount of the formed pattern could be further reduced (in other words, the sensitivity of the composition was more excellent).

In addition, from the comparison of Examples 15 to 17, in a case of including, as the copper phthalocyanines, a salt composed of copper phthalocyanine having a sulfonic acid group and dimethyldioctadecylammonium, it was confirmed that the viscosity stability over time of the composition was more excellent.

Moreover, from the results of Examples 20 and 24 to 28, in a case where the pH of the carbon black was 6.0 or less, it was confirmed that the viscosity stability over time of the composition was more excellent.

In addition, from the comparison of Examples 25 and 36 to 40, in a case where the sulfonium salt compound and the halomethylated triazine compound were used in combination as the acid generator, it was confirmed that the undercut suppression property of the formed pattern was more excellent. Moreover, in a case where the mass ratio (content of the specific crosslinking agent/content of the acid generator) of the content of the specific crosslinking agent to the content of the acid generator was more than 1.5 and less than 6.0, it was confirmed that the minimum contact exposure amount of the formed pattern could be further reduced (in other words, the sensitivity of the composition was more excellent).

In addition, from the comparison of Examples 25, 41, and 42, in a case where the content of the carbon black was 27.0% by mass or more with respect to the total solid content of the composition, it was confirmed that the light shielding properties of the formed pattern was more excellent. On the other hand, in a case where the content of the carbon black was 35.0% by mass or less with respect to the total solid content of the composition, it was confirmed that the undercut of the formed pattern was more suppressed and the adhesiveness was more excellent. Furthermore, from the comparison of Examples 25 and 43 to 46, in a case where the content of the carbon black was not increased too much as in Example 41, and instead, the particles B were introduced into the composition to increase the pigment concentration, it was confirmed that the undercut and adhesiveness of the formed pattern did not deteriorate and excellent light shielding properties could be exhibited.

In addition, from the comparison of Examples 25 and 47, in a case where the composition included the adhesive, it was confirmed that the undercut suppression property of the formed pattern was more excellent, and the minimum contact exposure amount of the formed pattern could be further reduced (in other words, the sensitivity of the composition was more excellent).

In addition, from the comparison of Examples 25, 48, and 49, in a case where the content of the particles A in the composition was 10% by mass or more with respect to the total solid content of the composition, it was confirmed that the formed pattern had lower reflection properties.

In addition, from the comparison of Examples 25 and 50, in a case where the composition included the particles A and the content of the resin in the composition was 12% by mass or less with respect to the total solid content of the composition, it was confirmed that the undercut of the formed pattern was more suppressed.

Furthermore, even in a case where the barium sulfate used above was changed to other commercially available products of the barium sulfate (BF-10, BF-21, BF-1, and BF-40 (all manufactured by SAKAI CHEMICAL INDUSTRY CO., LTD.); TS-3, SC-201, and HC-A (all manufactured by Takehara Chemical); and TS-2 (manufactured by TOSHIN CHEMICALS CO., LTD.)), the same effect was obtained.

### EXPLANATION OF REFERENCES

100: solid-state imaging device
101: solid-state imaging element
102: imaging part
103: cover glass
104: spacer
105: laminated substrate
106: chip substrate
107: circuit substrate
108: electrode pad
109: external connection terminal
110: through-electrode
111: lens layer
112: lens material
113: support
114, 115: cured film
201: light-receiving element
202: color filter
203: microlens
204: substrate
205b: blue pixel
205r: red pixel
205g: green pixel
205bm: black matrix
206: p-well layer
207: reading gate part
208: vertical electric charge transfer path
209: element separation region
210: gate insulating film
211: vertical electric charge transfer electrode
212: cured film
213, 214: insulating film
215: planarization film
300: infrared sensor
310: solid-state imaging element
311: infrared absorption filter
312: color filter
313: infrared transmitting filter
314: resin film
315: microlens
316: planarization film

What is claimed is:

1. A composition comprising:
carbon black;
barium sulfate;
one or more kinds selected from the group consisting of copper phthalocyanine and a copper phthalocyanine derivative;
an acid generator; and
a crosslinking agent having a crosslinkable group which is crosslinked by an acid.

2. The composition according to claim 1, further comprising:
a resin.

3. The composition according to claim 1,
wherein the crosslinking agent includes a triazine structure.

4. The composition according to claim 1,
wherein the crosslinkable group includes an alkoxymethyl group.

5. The composition according to claim 1, further comprising:
one or more kinds of particles A selected from the group consisting of organic particles different from the carbon black and metal oxide particles.

6. The composition according to claim 5,
wherein an average particle diameter of the particles A is in a range of 0.1 to 10 μm.

7. The composition according to claim 5,
wherein the organic particles include one or more kinds of phenol resin particles and acrylic resin particles.

8. The composition according to claim 5,
wherein the metal oxide particles include silica particles.

9. The composition according to claim 1,
wherein the composition includes the copper phthalocyanine derivative, and
the copper phthalocyanine derivative is a salt composed of copper phthalocyanine having a sulfonic acid group and dimethyldioctadecylammonium.

10. The composition according to claim 1,
wherein a content of the carbon black is 15% to 55% by mass with respect to a total solid content of the composition.

11. The composition according to claim 1, further comprising:
one or more kinds of particles B selected from the group consisting of metal nitride particles and metal oxynitride particles.

12. The composition according to claim 11,
wherein the particles B are a nitride or an oxynitride of one or more kinds of metals selected from the group consisting of titanium, zirconium, vanadium, and niobium.

13. The composition according to claim 1, further comprising:
a fluorine-based surfactant.

14. The composition according to claim 1,
wherein a content of a solid content is 10% to 45% by mass.

15. The composition according to claim 1,
wherein the composition includes two or more kinds of the acid generators.

16. The composition according to claim 1,
wherein the acid generator includes a sulfonium salt compound and a halomethylated triazine compound.

17. The composition according to claim 1,
wherein, in a case where a film is formed by performing the following film forming method on a composition layer formed from the composition, a maximum reflectivity of the film in a wavelength range of 400 to 1100 nm is less than 5%,
<<film forming method>>
the composition is applied to a substrate so that a thickness after an exposure is 2.0 μm to form a coating film, the coating film is heated under conditions of at 100° C. for 120 seconds to form a composition layer, and using a high-pressure mercury lamp, the composition layer is exposed to an exposure amount of 1000 mJ/cm², and then the exposed composition layer is heated under conditions of 220° C. for 300 seconds.

18. A light shielding film comprising:
a cured film formed from the composition according to claim 1.

19. A solid-state imaging element comprising:
a cured film formed from the composition according to claim 1.

20. An image display device comprising:
a cured film formed from the composition according to claim 1.

21. A method for manufacturing a cured film, comprising:
a composition layer forming step of forming a composition layer consisting of the composition according to claim 1 on a support;
an exposure step of exposing the composition layer in a patterned manner by irradiating the composition layer with an actinic ray or a radiation; and
a development step of performing a development treatment on the composition layer after the exposure.
